(19) United States
(12) Patent Application Publication
(10) Pub. No.: US 2026/0211326 A1
(43) Pub. Date: Jul. 23, 2026

(54) ACTINIC RAY-SENSITIVE OR RADIATION-SENSITIVE RESIN COMPOSITION, RESIST FILM, PATTERN FORMING METHOD, AND METHOD FOR PRODUCING ELECTRONIC DEVICE

(71) Applicant: FUJIFILM Corporation, Tokyo (JP)

(72) Inventors: Hironori Oka, Shizuoka (JP); Aina Shibuya, Shizuoka (JP); Yoichi Nishida, Shizuoka (JP); Masafumi Kojima, Shizuoka (JP); Satomi Takahashi, Shizuoka (JP); Hideaki Tsubaki, Shizuoka (JP); Keisuke Ushirogata, Shizuoka (JP)

(73) Assignee: FUJIFILM Corporation, Tokyo (JP)

(21) Appl. No.: 19/572,281

(22) Filed: Mar. 19, 2026

Related U.S. Application Data
(63) Continuation of application No. PCT/JP2024/031258, filed on Aug. 30, 2024.

(30) Foreign Application Priority Data
Sep. 29, 2023 (JP) 2023-170175

(51) Int. Cl. G03F 7/039; G03F 7/00; G03F 7/004; G03F 7/20

(52) U.S. Cl. CPC G03F 7/0395; G03F 7/0045; G03F 7/2022; G03F 7/70033

(57) ABSTRACT

An actinic ray-sensitive or radiation-sensitive resin composition contains a resin having a repeating unit and a solvent, the repeating unit includes a cation having a specified structure and an anion bonded to the molecular chain of the resin, and the content of the repeating unit relative to the total content of resins contained in the actinic ray-sensitive or radiation-sensitive resin composition is 40 mass % or more.

### CROSS REFERENCE TO RELATED APPLICATION

This is a continuation of International Application No. PCT/JP2024/031258 filed on Aug. 30, 2024, and claims priority from Japanese Patent Application No. 2023-170175 filed on Sep. 29, 2023, the entire disclosures of which are incorporated herein by reference.

### BACKGROUND OF THE INVENTION

### 1. Field of the Invention

The present invention relates to an actinic ray-sensitive or radiation-sensitive resin composition, a resist film, a pattern forming method, and a method for producing an electronic device. More specifically, the present invention relates to an actinic ray-sensitive or radiation-sensitive resin composition that can be suitably used in an ultramicrolithography process applicable to, for example, a process for producing ultra-LSIs (Large Scale Integrations) or high-capacity microchips, a process for creating nanoimprint molds, or a process for producing high-density information recording media, or another photofabrication process, and a resist film, a pattern forming method, and a method for producing an electronic device that use the actinic ray-sensitive or radiation-sensitive resin composition.

### 2. Description of the Related Art

In fabrication processes for semiconductor devices such as ICs (Integrated Circuits) or LSIs (Large Scale Integrations), microprocessing by lithography using resist compositions has been performed. In recent years, with an increase in the degree of integration of integrated circuits, formation of ultrafine patterns in the submicron range or the quarter micron range has come to be in demand. With this, there is a trend for exposure wavelengths toward shorter wavelengths from the g-line to the i-line further to the KrF excimer laser beam; currently, exposure apparatuses using, as light sources, the ArF excimer laser having a wavelength of 193 nm have been developed. In addition, as a technique of further increasing the resolving power, a technique in which the space between a projection lens and a sample is filled with a liquid having a high refractive index (hereafter, also referred to as “immersion liquid”), what is called, the immersion method is being developed.

Furthermore, currently, in addition to excimer laser beams, lithography using an electron beam (EB: electron Beam), X-rays, extreme ultraviolet rays (EUV: extreme Ultraviolet), or the like is also being developed. With this, resist compositions effectively sensitive to various actinic rays or radiations have been developed.

WO2018/074382A describes a composition including an onium salt having a specified structure.

JP2016-81053A describes a photoresist composition including a first polymer having a specified structure including 50 to 100 mol % of a photoacid-generating repeating unit based on 100 mol % of all the repeating units, and a second polymer that exhibits a change in the degree of solubility in an alkali developer under the action of an acid.

### SUMMARY OF THE INVENTION

There has recently been an increasing demand for higher performance for resist compositions. In particular, there has been a demand for further improvements in sensitivity, local critical dimension uniformity (LCDU: Local CDU), and resolution during formation of fine patterns (for example, contact hole patterns having diameters of 20 nm or less, or 1:1 line-and-space patterns having line widths of 20 nm or less).

An object of the present invention is to provide an actinic ray-sensitive or radiation-sensitive resin composition that provides high sensitivity, high LCDU, and high resolution.

Another object of the present invention is to provide a resist film, a pattern forming method, and a method for producing an electronic device that use the above-described actinic ray-sensitive or radiation-sensitive resin composition.

The inventors of the present invention have found that the following features can address the above-described objects.

[1]

An actinic ray-sensitive or radiation-sensitive resin composition including a resin (X) having a repeating unit (u1), and a solvent,
wherein the repeating unit (u1) includes at least one cation selected from the group consisting of a cation represented by a formula (CT-1) below and a cation represented by a formula (CT-2) below, and an anion bonded to a molecular chain of the resin (X),
a content of the repeating unit (u1) relative to a total resin content in the actinic ray-sensitive or radiation-sensitive resin composition is 40 mass % or more,

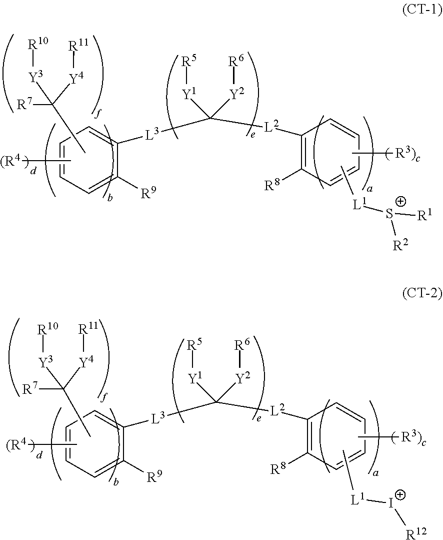

in the formula (CT-1) and the formula (CT-2),
R³ and R⁴ each independently represent an organic group, a hydroxy group, a mercapto group, an amino group, a nitro group, a phosphino group, a silyl group, or a halogen atom; when a plurality of R³ are present, the plurality of R³ may be bonded together directly by a single bond or via a linking group, to form a ring; when a plurality of R⁴ are present, the plurality of R⁴ may be bonded together directly by a single bond or via a linking group, to form a ring,
R⁵ and R⁶ each independently represent an alkyl group, a cycloalkyl group, an alkenyl group, a cycloalkenyl group, an aryl group, or a heteroaryl group; when R⁵ and R⁶ include a methylene group, at least one of the methylene group may be substituted with a divalent heteroatom-containing group; R⁵ and R⁶ may be bonded together directly by a single bond or via any one selected from the group consisting of an oxygen atom, a sulfur atom, and an alkylene group, to form a ring,
R⁷ represents a hydrogen atom, an alkyl group, a cycloalkyl group, an alkenyl group, a cycloalkenyl group, an aryl group, or a heteroaryl group,
R⁸ and R⁹ each independently represent a hydrogen atom, an organic group, a hydroxy group, a mercapto group, an amino group, a nitro group, a phosphino group, a silyl group, or a halogen atom, or R⁸ and R⁹ are bonded together to represent a single bond or a divalent linking group,
R¹⁰ and R¹¹ each independently represent an alkyl group, a cycloalkyl group, an alkenyl group, a cycloalkenyl group, an aryl group, or a heteroaryl group; when R¹⁰ and R¹¹ include a methylene group, at least one of the methylene group may be substituted with a divalent heteroatom-containing group; R¹⁰ and R¹¹ may be bonded together directly by a single bond or via any one selected from the group consisting of an oxygen atom, a sulfur atom, and an alkylene group, to form a ring,
Y¹, Y², Y³, and Y⁴ each independently represent an oxygen atom or a sulfur atom,
L¹ represents an alkylene group, a cycloalkylene group, an alkenylene group, a cycloalkenylene group, an arylene group, a heteroarylene group, a linking group in which at least two groups selected from the group consisting of an alkylene group, a cycloalkylene group, an alkenylene group, a cycloalkenylene group, an arylene group, and a heteroarylene group are bonded together via at least one selected from the group consisting of a single bond, an oxygen atom, a sulfur atom, and a nitrogen atom-containing group, or a single bond,
L² and L³ each independently represent a single bond, an alkenylene group having 2 carbon atoms, an alkynylene group having 2 carbon atoms, a carbonyl group, a sulfinyl group, or a sulfonyl group,
a and b each independently represent an integer of 1 to 3,
when a represents 1, c represents an integer of 0 to 3,
when a represents 2, c represents an integer of 0 to 5,
when a represents 3, c represents an integer of 0 to 7,
when b represents 1, d represents an integer of 0 to 4, provided that d+f is an integer of 0 to 4,
when b represents 2, d represents an integer of 0 to 6, provided that d+fis an integer of 0 to 6,
when b represents 3, d represents an integer of 0 to 8, provided that d+f is an integer of 0 to 8,
e represents 0 or 1, f represents an integer of 0 to 4, provided that e+f is an integer of 1 to 4,
in the formula (CT-1),
R¹ and R² each independently represent an alkyl group, a cycloalkyl group, an alkenyl group, a cycloalkenyl group, an aryl group, or a heteroaryl group; when R¹ and R² include a methylene group, at least one of the methylene group may be substituted with a divalent heteroatom-containing group,
at least two of R¹, R², and the aromatic ring to which L¹ is bonded may be bonded together directly by a single bond or via any one selected from the group consisting of an oxygen atom, a sulfur atom, a nitrogen atom-containing group, and a methylene group, to form a ring,
in the formula (CT-2),
R¹² represents an aryl group or a heteroaryl group, and
R¹² and the aromatic ring to which L¹ is bonded may be bonded together directly by a single bond or via any one selected from the group consisting of an oxygen atom, a sulfur atom, a nitrogen atom-containing group, and a methylene group, to form a ring.
   [2]

An actinic ray-sensitive or radiation-sensitive resin composition including a resin (X) having a repeating unit (u1), and a solvent,
wherein the repeating unit (u1) includes at least one cation and an anion that is bonded to a molecular chain of the resin (X),
the cation undergoes a structural change by action of an acid, and a post-change structure has a larger peak area in an absorption spectrum for light having wavelengths of 300 nm to 450 nm than a peak area in an absorption spectrum of a pre-change structure for light having wavelengths of 300 nm to 450 nm, and
a content of the repeating unit (u1) relative to a total resin content in the actinic ray-sensitive or radiation-sensitive resin composition is 40 mass % or more.
   [3]

An actinic ray-sensitive or radiation-sensitive resin composition including a resin (X) having a repeating unit (u1), and a solvent,
wherein the repeating unit (u1) includes at least one cation and an anion that is bonded to a molecular chain of the resin (X),
the cation undergoes a structural change by action of an acid to generate a ketone group, and
a content of the repeating unit (u1) relative to a total resin content in the actinic ray-sensitive or radiation-sensitive resin composition is 40 mass % or more.
   [4]

The actinic ray-sensitive or radiation-sensitive resin composition according to any one of [1] to [3], wherein the repeating unit (u1) is a repeating unit that generates an acid upon irradiation with an actinic ray or a radiation.

[5]

The actinic ray-sensitive or radiation-sensitive resin composition according to any one of [1] to [4], satisfying at least one of a condition (i) below or a condition (ii) below:
Condition (i): the actinic ray-sensitive or radiation-sensitive resin composition contains an acid diffusion control agent that is a compound different from the resin (X), and
Condition (ii): the resin (X) has a repeating unit having acid diffusion control ability.
   [6]

The actinic ray-sensitive or radiation-sensitive resin composition according to any one of [1] to [5], wherein the content of the repeating unit (u1) relative to the total resin content in the actinic ray-sensitive or radiation-sensitive resin composition is 60 mass % or more.

[7]

The actinic ray-sensitive or radiation-sensitive resin composition according to any one of [1] to [6], wherein the content of the repeating unit (u1) relative to the total resin content in the actinic ray-sensitive or radiation-sensitive resin composition is 80 mass % or more.

[8]

A resist film formed using the actinic ray-sensitive or radiation-sensitive resin composition according to any one of [1] to [7].

[9]

A pattern forming method including a step of using the actinic ray-sensitive or radiation-sensitive resin composition according to any one of [1] to [7] to form a resist film on a substrate; a step of irradiating the resist film with a first actinic ray or radiation; a step of irradiating, with a second actinic ray or radiation, the resist film after irradiation with the first actinic ray or radiation; and a step of using a developer to develop the resist film after irradiation with the second actinic ray or radiation.

The pattern forming method according to [9], wherein a wavelength of the first actinic ray or radiation is shorter than a wavelength of the second actinic ray or radiation.

The pattern forming method according to [9] or [10], wherein the first actinic ray or radiation is an electron beam or extreme ultraviolet rays.

The pattern forming method according to any one of [9] to [11], wherein the irradiating with the first actinic ray or radiation generates a first active species in the resist film, the first active species causes a structural change of the cation, and the irradiating with the second actinic ray or radiation generates a second active species from the cation having undergone the structural change.

The pattern forming method according to any one of [9] to [12], wherein the developer is an alkaline aqueous solution.

The pattern forming method according to any one of [9] to [12], wherein the developer is an organic solvent.

A method for producing an electronic device, the method including the pattern forming method according to any one of [9] to [14].

The present invention can provide an actinic ray-sensitive or radiation-sensitive resin composition that provides high sensitivity, high LCDU, and high resolution.

The present invention can also provide a resist film, a pattern forming method, and a method for producing an electronic device that use the above-described actinic ray-sensitive or radiation-sensitive resin composition.

### DESCRIPTION OF THE PREFERRED EMBODIMENTS

Hereinafter, the present invention will be described in detail.

Features may be described below on the basis of representative embodiments of the present invention; however, the present invention is not limited to such embodiments.

In this Specification, “actinic ray” or “radiation” means, for example, the emission line spectrum of a mercury lamp, far-ultraviolet rays represented by excimer lasers, extreme ultraviolet rays (EUV: Extreme Ultraviolet), X-rays, soft X-rays, or an electron beam (EB: Electron Beam).

In this Specification, “light” means an actinic ray or a radiation.

In this Specification, “exposure” includes, unless otherwise specified, not only exposure using, for example, the emission line spectrum of a mercury lamp, far-ultraviolet rays represented by excimer lasers, extreme ultraviolet rays, X-rays, or EUV, but also patterning using a corpuscular beam such as an electron beam or an ion beam.

In this Specification, “a value ‘to’ another value” is used to mean that it includes the value and the other value as the lower limit value and the upper limit value.

In this Specification, (meth)acrylate represents at least one of acrylate or methacrylate. (Meth)acrylic acid represents at least one of acrylic acid or methacrylic acid.

In this Specification, for resins, the weight-average molecular weight (Mw), the number-average molecular weight (Mn), and the dispersity (also referred to as molecular weight distribution) (also referred to as “Mw/Mn” or “PDI”) are defined as polystyrene-equivalent values determined using a GPC (Gel Permeation Chromatography) apparatus (HLC-8120GPC manufactured by Tosoh Corporation) by GPC measurement (solvent: tetrahydrofuran, flow rate (sample injection amount): 10 μL, column: TSK gel Multipore HXL-M manufactured by Tosoh Corporation, column temperature: 40° C., flow rate: 1.0 mL/min, detector: differential refractive index detector (Refractive Index Detector)).

In this Specification, for written forms of groups (atomic groups), written forms without referring to substituted or unsubstituted encompass, in addition to groups not having a substituent, groups including a substituent without departing from the spirit and scope of the present invention. For example, “alkyl group” encompasses not only alkyl groups not having a substituent (unsubstituted alkyl groups), but also alkyl groups having a substituent (substituted alkyl groups). In this Specification, “organic group” refers to a group including at least one carbon atom.

The substituent is preferably a monovalent substituent unless otherwise specified. Examples of the substituent include monovalent non-metallic atomic groups except for the hydrogen atom and, for example, can be selected from the group consisting of the following Substituents T.

### Substituents T

Examples of the substituents T include halogen atoms such as a fluorine atom, a chlorine atom, a bromine atom, and an iodine atom; alkoxy groups such as a methoxy group, an ethoxy group, and a tert-butoxy group; cycloalkyloxy groups; aryloxy groups such as a phenoxy group and a p-tolyloxy group; alkoxycarbonyl groups such as a methoxycarbonyl group and a butoxycarbonyl group; cycloalkyloxycarbonyl groups; aryloxycarbonyl groups such as a phenoxycarbonyl group; acyloxy groups such as an acetoxy group, a propionyloxy group, and a benzoyloxy group; acyl groups such as an acetyl group, a benzoyl group, an isobutyryl group, an acryloyl group, a methacryloyl group, and a methoxalyl group; a sulfanyl group; alkylsulfanyl groups such as a methylsulfanyl group and a tert-butylsulfanyl group; arylsulfanyl groups such as a phenylsulfanyl group and a p-tolylsulfanyl group; alkyl groups; alkenyl groups; cycloalkyl groups; aryl groups; aromatic heterocyclic groups; a hydroxy group; a carboxyl group; a formyl group; a sulfo group; a cyano group; alkylaminocarbonyl groups; arylaminocarbonyl groups; a sulfonamide group; a silyl group; an amino group; and a carbamoyl group. When such a substituent can additionally have one or more substituents, a group having, as the additional substituents, one or more substituents selected from the group consisting of the substituents described above (such as a monoalkylamino group, a dialkylamino group, an arylamino group, or a trifluoromethyl group) is also included in examples of the substituents T.

Note that, in the cases of descriptions of not having fluorine atoms such as the “substituent not having fluorine atoms” in R_{1b} and R_{2b} in the formula (N1), the substituents T do not include fluorine atoms.

In this Specification, the bonding directions of divalent groups described are not limited unless otherwise specified. For example, in a compound represented by a formula “X—Y—Z” where Y is —COO—, Y may be —CO—O— or may be —O—CO—. The compound may be “X—CO—O—Z” or may be “X—O—CO—Z”.

In this Specification, the acid dissociation constant (pKa) represents pKa in an aqueous solution, specifically, a value determined using the following Software package 1, on the basis of the Hammett's substituent constant and the database of values in publicly known documents, by calculation. All the values of pKa described in this Specification are values determined by calculation using this software package.

Software package 1: Advanced Chemistry Development (ACD/Labs) Software V8.14 for Solaris (1994-2007 ACD/Labs)

Alternatively, pKa can be determined by a molecular orbital calculation method. Specifically, this method may be a calculation method of calculating H+dissociation free energy in an aqueous solution based on a thermodynamic cycle. The H+dissociation free energy can be calculated by a method such as DFT (density functional theory); however, the calculation method is not limited thereto and various other methods have been reported in documents and the like. Note that there are a plurality of pieces of software for performing DFT, such as Gaussian 16.

In this Specification, as described above, pKa refers to a value determined using Software package 1, on the basis of the Hammett's substituent constant and the database of values in publicly known documents, by calculation; however, when use of this method cannot determine pKa, a value determined on the basis of DFT (density functional theory) using Gaussian 16 is employed.

In this Specification, as described above, pKa refers to “pKa in an aqueous solution”; however, when pKa in an aqueous solution cannot be determined, “pKa in a dimethyl sulfoxide (DMSO) solution” is employed.

In this Specification, the “solid content” means a component that forms an actinic ray-sensitive or radiation-sensitive film (when the actinic ray-sensitive or radiation-sensitive film is a resist composition, a resist film), and does not include a solvent. As long as a component forms the actinic ray-sensitive or radiation-sensitive film, even when the component has the form of liquid, it is regarded as the solid content.

In this Specification, the peak area in the absorption spectrum for light having wavelengths of 300 nm to 450 nm refers to a value obtained by integrating peaks in the range of wavelengths of 300 nm to 450 nm in the ultraviolet-visible absorption spectrum. In this Specification, all the peak areas in the absorption spectra for light having wavelengths of 300 nm to 450 nm are values obtained by calculation using the following method.

The values were determined by TD-DFT calculation using Gaussian 16 as the electronic state calculation software provided by Gaussian, using B3LYP/6-31+G (d) and Acetonitrile solvent conditions using the IEFPCM method, and by UV-Vis spectrum calculation using the calculation software GaussView under a condition of a half-width of 0.2 eV and with output wavelength intervals of 1 nm.

Actinic ray-sensitive or radiation-sensitive resin composition

An actinic ray-sensitive or radiation-sensitive resin composition of the present invention (also referred to as “composition of the present invention”) is:
an actinic ray-sensitive or radiation-sensitive resin composition including a resin (X) having a repeating unit (u1), and a solvent,
wherein the repeating unit (u1) includes at least one cation selected from the group consisting of a cation represented by a formula (CT-1) below and a cation represented by a formula (CT-2) below, and an anion bonded to a molecular chain included in the resin (X), and
a content of the repeating unit (u1) relative to a total resin content in the actinic ray-sensitive or radiation-sensitive resin composition is 40 mass % or more.

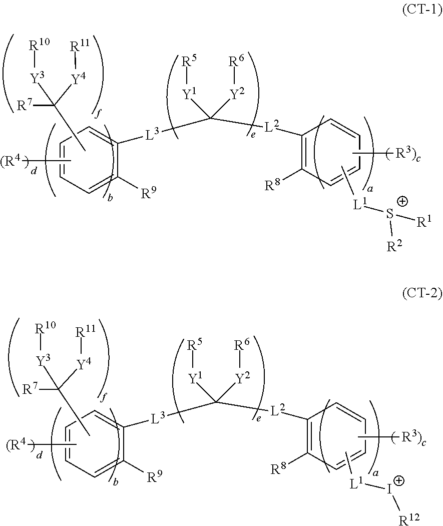

In the formula (CT-1) and the formula (CT-2),
R³ and R⁴ each independently represent an organic group, a hydroxy group, a mercapto group, an amino group, a nitro group, a phosphino group, a silyl group, or a halogen atom. When a plurality of R³ are present, the plurality of R³ may be bonded together directly by a single bond or via a linking group, to form a ring. When a plurality of R⁴ are present, the plurality of R⁴ may be bonded together directly by a single bond or via a linking group, to form a ring.
R⁵ and R⁶ each independently represent an alkyl group, a cycloalkyl group, an alkenyl group, a cycloalkenyl group, an aryl group, or a heteroaryl group. When R⁵ and R⁶ include a methylene group, at least one of the methylene group may be substituted with a divalent heteroatom-containing group. R⁵ and R⁶ may be bonded together directly by a single bond or via any one selected from the group consisting of an oxygen atom, a sulfur atom, and an alkylene group, to form a ring.

R⁷ represents a hydrogen atom, an alkyl group, a cycloalkyl group, an alkenyl group, a cycloalkenyl group, an aryl group, or a heteroaryl group.

R⁸ and R⁹ each independently represent a hydrogen atom, an organic group, a hydroxy group, a mercapto group, an amino group, a nitro group, a phosphino group, a silyl group, or a halogen atom, or R⁸ and R⁹ are bonded together to represent a single bond or a divalent linking group.

R¹⁰ and R¹¹ each independently represent an alkyl group, a cycloalkyl group, an alkenyl group, a cycloalkenyl group, an aryl group, or a heteroaryl group. When R¹⁰ and R¹¹ include a methylene group, at least one of the methylene group may be substituted with a divalent heteroatom-containing group. R¹⁰ and R¹¹ may be bonded together directly by a single bond or via any one selected from the group consisting of an oxygen atom, a sulfur atom, and an alkylene group, to form a ring.

Y¹, Y², Y³, and Y⁴ each independently represent an oxygen atom or a sulfur atom.

L¹ represents an alkylene group, a cycloalkylene group, an alkenylene group, a cycloalkenylene group, an arylene group, a heteroarylene group, a linking group in which at least two groups selected from the group consisting of an alkylene group, a cycloalkylene group, an alkenylene group, a cycloalkenylene group, an arylene group, and a heteroarylene group are bonded together via at least one selected from the group consisting of a single bond, an oxygen atom, a sulfur atom, and a nitrogen atom-containing group, or a single bond.

L² and L³ each independently represent a single bond, an alkenylene group having 2 carbon atoms, an alkynylene group having 2 carbon atoms, a carbonyl group, a sulfinyl group, or a sulfonyl group.

a and b each independently represent an integer of 1 to 3.

When a represents 1, c represents an integer of 0 to 3.

When a represents 2, c represents an integer of 0 to 5.

When a represents 3, c represents an integer of 0 to 7.

When b represents 1, d represents an integer of 0 to 4, provided that d+f is an integer of 0 to 4.

When b represents 2, d represents an integer of 0 to 6, provided that d+f is an integer of 0 to 6.

When b represents 3, d represents an integer of 0 to 8, provided that d+f is an integer of 0 to 8.

e represents 0 or 1 and f represents an integer of 0 to 4, provided that e+f is an integer of 1 to 4.

In the formula (CT-1),

R¹ and R² each independently represent an alkyl group, a cycloalkyl group, an alkenyl group, a cycloalkenyl group, an aryl group, or a heteroaryl group. When R¹ and R² include a methylene group, at least one of the methylene group may be substituted with a divalent heteroatom-containing group.

At least two of R¹, R², and the aromatic ring to which L¹ is bonded may be bonded together directly by a single bond or via any one selected from the group consisting of an oxygen atom, a sulfur atom, a nitrogen atom-containing group, and a methylene group, to form a ring. In the formula (CT-2),

R¹² represents an aryl group or a heteroaryl group.

R¹² and the aromatic ring to which L¹ is bonded may be bonded together directly by a single bond or via any one selected from the group consisting of an oxygen atom, a sulfur atom, a nitrogen atom-containing group, and a methylene group, to form a ring.

The composition of the present invention is typically a resist composition, and may be a positive resist composition or may be a negative resist composition. The composition of the present invention may be a resist composition for alkali development or may be a resist composition for organic-solvent development.

The composition of the present invention is preferably a chemical amplification resist composition.

The composition of the present invention can be used to form an actinic ray-sensitive or radiation-sensitive film. The actinic ray-sensitive or radiation-sensitive film formed using the composition of the present invention is typically a resist film.

Hereinafter, first, various components of the composition of the present invention will be described in detail.

### Resin (X)

The resin (X) has a repeating unit (u1) including at least one cation selected from the group consisting of a cation represented by the formula (CT-1) and a cation represented by the formula (CT-2), and an anion bonded to the molecular chain of the resin (X).

The resin (X) may be a linear polymer, a non-linear polymer (for example, a polymer having a branched, grafted, comb-like, star-like, cyclic, or network structure), or a mixture of a linear polymer and a non-linear polymer.

The resin (X) may have, in addition to the repeating unit (u1), a repeating unit other than the repeating unit (u1), or may have only the repeating unit (u1) (may be a resin composed only of the repeating unit (u1)).

Repeating unit (u1)

The repeating unit (u1) includes at least one cation selected from the group consisting of a cation represented by the formula (CT-1) and a cation represented by the formula (CT-2), and an anion bonded to the molecular chain of the resin (X).

The molecular chain of the resin (X) is a group formed by covalent bonding of a plurality of atoms; when the resin (X) is a linear polymer, the molecular chain may be, for example, the main chain or a side chain. Alternatively, the molecular chain is, when the resin (X) is a non-linear polymer (for example, a polymer having a branched, grafted, comb-like, star-like, cyclic, or network structure), a molecular chain forming at least a part of the structure of the non-linear polymer.

The anion included in the repeating unit (u1) is preferably covalently bonded to the molecular chain of the resin (X).

The repeating unit (u1) may have only one anion or two or more anions bonded to the molecular chain of the resin (X). When the repeating unit (u1) has two or more anions, the types of anions may be the same or different.

The repeating unit (u1) includes at least one cation (also referred to as “cation (CT)”) selected from the group consisting of a cation represented by the formula (CT-1) and a cation represented by the formula (CT-2).

The cation (CT) is preferably not covalently bonded to the molecular chain of the resin (X)

In the formula (CT-1) and the formula (CT-2), R³ and R⁴ each independently represent an organic group, a hydroxy group, a mercapto group, an amino group, a nitro group, a phosphino group, a silyl group, or a halogen atom.

For R³ and R⁴, the organic group is not particularly limited, but is preferably an organic group having 1 to 20 carbon atoms, and more preferably an organic group having 1 to 12 carbon atoms. Examples of the organic group include alkyl groups, cycloalkyl groups, alkenyl groups, cycloalkenyl groups, alkoxy groups, cycloalkyloxy groups, alkylcarbonyl groups, cycloalkylcarbonyl groups, arylcarbonyl groups, heteroarylcarbonyl groups, alkoxycarbonyl groups, cycloalkyloxycarbonyl groups, aryloxycarbonyl groups, heteroaryloxycarbonyl groups, arylsulfanylcarbonyl groups, heteroarylsulfanylcarbonyl groups, arylsulfanyl groups, heteroarylsulfanyl groups, alkylsulfanyl groups, aryl groups, heteroaryl groups, aryloxy groups, heteroaryloxy groups, alkylsulfinyl groups, arylsulfinyl groups, heteroarylsulfinyl groups, alkylsulfonyl groups, arylsulfonyl groups, arylsulfonyl groups, heteroarylsulfonyl groups, (meth)acryloyloxy groups, hydroxy (poly)alkyleneoxy groups, alkylamino groups, dialkylamino groups, arylamino groups, diarylamino groups, N-alkyl-N-arylamino groups, cyano groups, alkylthio groups, cycloalkylthio groups, arylthio groups, dialkylphosphino groups, diarylphosphino groups, trialkylsilyl groups, and triarylsilyl groups.

For R³ and R⁴, the alkyl group may be either linear or branched. The number of carbon atoms of the alkyl group is not particularly limited, but is, for example, preferably 1 to 20, more preferably 1 to 10, and still more preferably 1 to 6. Examples of the alkyl group include a methyl group, an ethyl group, an n-propyl group, an i-propyl group, an n-butyl group, a t-butyl group, an n-pentyl group, and an n-hexyl group.

Among the groups described above as the organic groups represented by R³ and R⁴, the descriptions, specific examples, and preferred ranges of the alkyl groups in the groups including an alkyl group (for example, alkoxy groups and alkylcarbonyl groups) are the same as those described above for the alkyl groups represented by R³ and R⁴.

For R³ and R⁴, the cycloalkyl group may be either monocyclic or polycyclic. The number of carbon atoms of the cycloalkyl group is not particularly limited, but is, for example, preferably 4 to 20, and more preferably 5 to 15. Examples of the cycloalkyl group include a cyclopentyl group, a cyclohexyl group, a norbornyl group, a tetracyclodecanyl group, a tetracyclododecanyl group, and an adamantyl group. One of the methylene groups constituting the cycloalkane ring of the cycloalkyl group may be replaced by a heteroatom such as an oxygen atom or a sulfur atom, a group having a heteroatom such as a carbonyl group, a sulfonyl group, or an ester bond, or a vinylidene group.

Among the groups described above as the organic groups represented by R³ and R⁴, the descriptions, specific examples, and preferred ranges of the cycloalkyl groups in the groups including a cycloalkyl group (for example, cycloalkyloxy groups and cycloalkylcarbonyl groups) are the same as those described above for the cycloalkyl groups represented by R³ and R⁴.

For R³ and R⁴, the aryl group may be either monocyclic or polycyclic. The number of carbon atoms of the aryl group is not particularly limited, but is, for example, preferably 6 to 20, and more preferably 6 to 14. The aryl group is preferably a phenyl group or a naphthyl group, and more preferably a phenyl group.

Among the groups described above as the organic groups represented by R³ and R⁴, the descriptions, specific examples, and preferred ranges of the aryl groups in the groups including an aryl group (for example, aryloxy groups and arylcarbonyl groups) are the same as those described above for the aryl groups represented by R³ and R⁴

For R³ and R⁴, the heteroaryl group may be either monocyclic or polycyclic. The heteroaryl group preferably includes, as a ring member, at least one heteroatom selected from the group consisting of a nitrogen atom, an oxygen atom, and a sulfur atom. The number of carbon atoms of the heteroaryl group is not particularly limited, but is, for example, preferably 2 to 18, more preferably 3 to 12, and still more preferably 4 to 12. The number of the ring-members atoms of the heteroaryl group is not particularly limited, but is, for example, preferably 5 to 20, and more preferably 6 to 15. The heteroaryl group may be, for example, a group formed by removing one hydrogen atom from a five-membered aromatic heterocyclic compound such as pyrrole, imidazole, pyrazole, oxazole, isoxazole, thiazole, isothiazole, triazole, thiophene, or furan, or a six-membered aromatic heterocyclic compound such as pyridine, pyrazine, pyrimidine, pyridazine, triazine, thiazine, or oxazine.

Alternatively, the heteroaryl group may be a group formed by removing one hydrogen atom from a compound (for example, indole, quinoline, or isoquinoline) in which the five-membered aromatic heterocyclic compound or the six-membered aromatic heterocyclic compound is fused with at least one selected from the group consisting of the above-described five-membered aromatic heterocyclic compounds, the above-described six-membered aromatic heterocyclic compounds, aromatic hydrocarbons (for example, benzene and naphthalene), cycloalkanes (for example, cyclopentane and cyclohexane), and non-aromatic heterocyclic compounds (for example, five-membered non-aromatic heterocyclic compounds such as pyrrolidine, pyrroline, 2-oxazolidone, tetrahydrofuran, pyrrolidine, and tetrahydrothiophene, and six-membered non-aromatic heterocyclic compounds such as morpholine, piperidine, piperazine, tetrahydropyran, and pyrrolidine).

Among the groups described above as the organic groups represented by R³ and R⁴, the descriptions, specific examples, and preferred ranges of the heteroaryl groups in the groups including a heteroaryl group (for example, heteroaryloxy groups and heteroarylcarbonyl groups) are the same as those described above for the heteroaryl groups represented by R³ and R⁴.

For R³ and R⁴, the alkenyl group may be either linear or branched. The number of carbon atoms of the alkenyl group is not particularly limited, but is, for example, preferably 2 to 20, more preferably 2 to 10, and still more preferably 2 to 6. Examples of the alkenyl group include groups obtained by replacing one or more ethylene groups constituting the above-described alkyl groups represented by R³ and R⁴ with vinylene groups.

For R³ and R⁴, the cycloalkenyl group may be either monocyclic or polycyclic. The number of carbon atoms of the cycloalkenyl group is not particularly limited, but is, for example, preferably 4 to 20, and more preferably 5 to 15. Examples of the cycloalkenyl group include groups obtained by replacing one or more ethylene groups constituting the above-described cycloalkyl groups represented by R³ and R⁴ with vinylene groups.

The organic group may further have one or more substituents. The substituents are not particularly limited. Examples of the substituents include the above-described organic group, a hydroxy group, a mercapto group, an amino group, a nitro group, a phosphino group, a silyl group, halogen atoms (such as a fluorine atom, a chlorine atom, a bromine atom, and an iodine atom), acid-decomposable groups, and substituents that are combinations of two or more of the foregoing (substituents in which one or more hydrogen atoms included in the above-described organic group, a hydroxy group, a mercapto group, an amino group, a phosphino group, a silyl group, or an acid-decomposable group are substituted with the above-described organic group, a hydroxy group, a mercapto group, an amino group, a nitro group, a phosphino group, a silyl group, a halogen atom, or an acid-decomposable group). The “acid-decomposable group” is the same as that in the description of “Repeating unit having acid-decomposable group” serving as an example of a repeating unit (u2) described later.

The organic groups represented by R³ and R⁴ preferably have an acid-decomposable group.

R³ and R⁴ are also preferably acid groups. The organic groups represented by R³ and R⁴ also preferably have an acid group. The acid group is preferably an acid group having a pKa of 2 or more and 16 or less, more preferably an acid group having a pKa of 4 or more and 14 or less, and still more preferably an acid group having a pKa of 6 or more and 12 or less. Note that the pKa is the pKa of the cation (CT) determined by the above-described method.

For R³ and R⁴, the halogen atom is preferably a fluorine atom, a chlorine atom, a bromine atom, or an iodine atom.

When a plurality of R³ are present, the plurality of R³ may be bonded together directly by a single bond or via a linking group to form a ring. When a plurality of R⁴ are present, the plurality of R⁴ may be bonded together directly by a single bond or via a linking group to form a ring.

The linking group is not particularly limited. The linking group may be, for example, a divalent organic group, an oxygen atom, a sulfur atom, a nitrogen atom-containing group, a sulfinyl group (—SO—), a sulfonyl group (—SO₂—), or a linking group that is a combination of two or more of the foregoing.

The divalent organic group is not particularly limited, but is preferably a divalent organic group having 1 to 20 carbon atoms, and more preferably a divalent organic group having 1 to 12 carbon atoms. The divalent organic group may be, for example, a carbonyl group (—CO—), an ester group (—COO—), an alkylene group, a cycloalkylene group, an arylene group, a heteroarylene group, an alkenylene group, or a group that is a combination of two or more of the foregoing. Examples of the nitrogen atom-containing group include —NR—, where R represents a hydrogen atom or an organic group. Examples of the organic group represented by R include the same groups as the above-described organic groups represented by R³ and R⁴, and preferred are alkyl groups or aryl groups.

In the formula (CT-1) and the formula (CT-2), R⁵ and R⁶ each independently represent an alkyl group, a cycloalkyl group, an alkenyl group, a cycloalkenyl group, an aryl group, or a heteroaryl group.

The descriptions, specific examples, and preferred ranges of the alkyl groups, cycloalkyl groups, alkenyl groups, cycloalkenyl groups, aryl groups, and heteroaryl groups represented by R⁵ and R⁶ are the same as those described above for the alkyl groups, cycloalkyl groups, alkenyl groups, cycloalkenyl groups, aryl groups, and heteroaryl groups represented by R³ and R⁴.

When R⁵ and R⁶ include a methylene group, at least one of the methylene group may be substituted with a divalent heteroatom-containing group. The divalent heteroatom-containing group may be, for example, an oxygen atom, a sulfur atom, a nitrogen atom-containing group, a sulfinyl group, a sulfonyl group, a carbonyl group, an ester group, or a group that is a combination of two or more of the foregoing. The nitrogen atom-containing group may be, for example, —NR—, where R represents a hydrogen atom or an organic group. Examples of the organic group represented by R include the same groups as the above-described organic groups represented by R³ and R⁴, and preferred are alkyl groups or aryl groups.

R⁵ and R⁶ may be bonded together directly by a single bond or via any one selected from the group consisting of an oxygen atom, a sulfur atom, and an alkylene group, to form a ring. The alkylene group may be either linear or branched. The number of carbon atoms of the alkylene group is not particularly limited, but is, for example, preferably 1 to 20, more preferably 1 to 10, and still more preferably 1 to 6. Examples of the alkylene group include a methylene group and an ethylene group.

R⁵ and R⁶ preferably represent an alkyl group.

R⁷ in the formula (CT-1) and the formula (CT-2) represents a hydrogen atom, an alkyl group, a cycloalkyl group, an alkenyl group, a cycloalkenyl group, an aryl group, or a heteroaryl group.

The descriptions, specific examples, and preferred ranges of the alkyl group, cycloalkyl group, alkenyl group, cycloalkenyl group, aryl group, and heteroaryl group represented by R⁷ are the same as those described above for the alkyl groups, cycloalkyl groups, alkenyl groups, cycloalkenyl groups, aryl groups, and heteroaryl groups represented by R³ and R⁴. R⁸ and R⁹ in the formula (CT-1) and the formula (CT-2) each independently represent a hydrogen atom, an organic group, a hydroxy group, a mercapto group, an amino group, a nitro group, a phosphino group, a silyl group, or a halogen atom, or R⁸ and R° are bonded together to represent a single bond or a divalent linking group.

The descriptions, specific examples, and preferred ranges of the organic groups represented by R⁸ and R⁹ are the same as those described above for the organic groups represented by R³ and R⁴.

For R⁸ and R⁹, the halogen atom is preferably a fluorine atom, a chlorine atom, a bromine atom, or an iodine atom.

R⁸ and R⁹ may be bonded together to represent a single bond or a divalent linking group (R⁸ and R⁹ may be bonded together to form a single bond or a divalent linking group). The divalent linking group is not particularly limited. The divalent linking group may be, for example, a group composed of at least one selected from the group consisting of a sulfinyl group, a sulfonyl group, a carbonyl group, a methylene group, a sulfur atom, a nitrogen atom-containing group, and an oxygen atom. Examples of the nitrogen atom-containing group include —NR—, where R represents a hydrogen atom or an organic group. Examples of the organic group represented by R include the same groups as the above-described organic groups represented by R³ and R⁴, and preferred are alkyl groups or aryl groups.

R⁸ and R⁹ preferably represent a hydrogen atom, or R⁸ and R⁹ are preferably bonded together to represent a sulfonyl group.

The descriptions, specific examples, and preferred ranges of R¹⁰ and R¹¹ in the formula (CT-1) and the formula (CT-2) are the same as those described above for R⁵ and R⁶.

In the formula (CT-1) and the formula (CT-2), Y¹, Y², Y³, and Y⁴ each independently represent an oxygen atom or a sulfur atom, and preferably represent an oxygen atom.

In the formula (CT-1) and the formula (CT-2), L¹ represents an alkylene group, a cycloalkylene group, an alkenylene group, a cycloalkenylene group, an arylene group, a heteroarylene group, a linking group in which at least two groups selected from the group consisting of an alkylene group, a cycloalkylene group, an alkenylene group, a cycloalkenylene group, an arylene group, and a heteroarylene group are bonded together via at least one selected from the group consisting of a single bond, an oxygen atom, a sulfur atom, and a nitrogen atom-containing group, or a single bond.

The alkylene group represented by L¹ may be either linear or branched. The number of carbon atoms of the alkylene group is not particularly limited, but is preferably 1 to 20, more preferably 1 to 10, and still more preferably 1 to 6. Examples of the alkylene group include a methylene group and an ethylene group.

The cycloalkylene group represented by L¹ may be monocyclic or polycyclic. The number of carbon atoms of the cycloalkylene group is not particularly limited, but is, for example, preferably 4 to 20, and more preferably 5 to 15. Examples of the cycloalkylene group include a cyclopentylene group and a cyclohexylene group. One of the methylene groups constituting the cycloalkane ring of the cycloalkylene group may be replaced by a heteroatom such as an oxygen atom or a sulfur atom, a group having a heteroatom such as a carbonyl group, a sulfonyl group, or an ester bond, or a vinylidene group.

The arylene group represented by L¹ may be either monocyclic or polycyclic. The number of carbon atoms of the arylene group is not particularly limited, but is, for example, preferably 6 to 20, and more preferably 6 to 14. The arylene group is preferably a phenylene group or a naphthylene group, and more preferably a phenylene group.

The heteroarylene group represented by L¹ may be either monocyclic or polycyclic. The heteroarylene group preferably includes, as a ring member, at least one heteroatom selected from the group consisting of a nitrogen atom, an oxygen atom, and a sulfur atom. The number of carbon atoms of the heteroarylene group is not particularly limited, but is, for example, preferably 2 to 18, more preferably 3 to 12, and still more preferably 4 to 12. The number of ring-member atoms of the heteroarylene group is not particularly limited, but is, for example, preferably 5 to 20, and more preferably 6 to 15. Examples of the heteroarylene group include groups formed by removing two hydrogen atoms from a five-membered aromatic heterocyclic compound such as pyrrole, imidazole, pyrazole, oxazole, isoxazole, thiazole, isothiazole, triazole, thiophene, or furan or a six-membered aromatic heterocyclic compound such as pyridine, pyrazine, pyrimidine, pyridazine, triazine, thiazine, or oxazine.

Alternatively, the heteroarylene group may be a group formed by removing two hydrogen atoms from a compound (for example, indole, quinoline, or isoquinoline) in which the five-membered aromatic heterocyclic compound or the six-membered aromatic heterocyclic compound is fused with at least one selected from the group consisting of the above-described five-membered aromatic heterocyclic compounds, the above-described six-membered aromatic heterocyclic compounds, aromatic hydrocarbons (for example, benzene, and naphthalene), cycloalkanes (for example, cyclopentane and cyclohexane), and non-aromatic heterocyclic compounds (for example, five-membered non-aromatic heterocyclic compounds such as pyrrolidine, pyrroline, 2-oxazolidone, tetrahydrofuran, pyrrolidine, and tetrahydrothiophene, and six-membered non-aromatic heterocyclic compounds such as morpholine, piperidine, piperazine, tetrahydropyran, and pyrrolidine).

The alkenylene group represented by L¹ may be either linear or branched. The number of carbon atoms of the alkenylene group is not particularly limited, but is, for example, preferably 2 to 20, more preferably 2 to 10, and still more preferably 2 to 6. Examples of the alkenylene group include a group obtained by replacing one or more ethylene groups constituting the above-described alkylene group represented by L¹ with vinylene groups.

The cycloalkenylene group represented by L¹ may be either monocyclic or polycyclic. The number of carbon atoms of the cycloalkenylene group is not particularly limited, but is, for example, preferably 4 to 20, and more preferably 5 to 15. Examples of the cycloalkenylene group include a group obtained by replacing one or more ethylene groups constituting the above-described cycloalkylene group represented by L¹ with vinylene groups.

L¹ may represent a linking group in which at least two groups selected from the group consisting of an alkylene group, a cycloalkylene group, an alkenylene group, a cycloalkenylene group, an arylene group, and a heteroarylene group are bonded together via at least one selected from the group consisting of a single bond, an oxygen atom, a sulfur atom, and a nitrogen atom-containing group. The descriptions, specific examples, and preferred ranges of the alkylene group, cycloalkylene group, alkenylene group, cycloalkenylene group, arylene group, and heteroarylene group of “at least two groups selected from the group consisting of an alkylene group, a cycloalkylene group, an alkenylene group, a cycloalkenylene group, an arylene group, and a heteroarylene group” are respectively the same as those described above for the alkylene group, cycloalkylene group, alkenylene group, cycloalkenylene group, arylene group, and heteroarylene group represented by L¹.

Examples of the nitrogen atom-containing group include —NR—, where R represents a hydrogen atom or an organic group. Examples of the organic group represented by R include the same groups as the above-described organic groups represented by R³ and R⁴, and preferred are alkyl groups or aryl groups.

The linking group may also be a linking group in which at least two groups of the same type are bonded together via at least one selected from the group consisting of a single bond, an oxygen atom, a sulfur atom, and a nitrogen atom-containing group.

L² and L³ in the formula (CT-1) and the formula (CT-2) each independently represent a single bond, an alkenylene group having 2 carbon atoms, an alkynylene group having 2 carbon atoms, a carbonyl group, a sulfinyl group, or a sulfonyl group.

In the formula (CT-1) and the formula (CT-2), a represents an integer of 1 to 3.

When a represents 1, the aromatic ring to which L¹ is bonded is a benzene ring, and c represents an integer of 0 to 3.

When a represents 2, the aromatic ring to which L¹ is bonded is a naphthalene ring, and c represents an integer of 0 to 5.

When a represents 3, the aromatic ring to which L¹ is bonded is an anthracene ring, and c represents an integer of 0 to 7.

In the formula (CT-1) and the formula (CT-2), b represents an integer of 1 to 3.

When b represents 1, the aromatic ring to which R⁹ is bonded is a benzene ring, and d represents an integer of 0 to 4, provided that d+fis an integer of 0 to 4.

When b represents 2, the aromatic ring to which R⁹ is bonded is a naphthalene ring, and d represents an integer of 0 to 6, provided that d+f is an integer of 0 to 6.

When b represents 3, the aromatic ring to which R⁹ is bonded is an anthracene ring, and d represents an integer of 0 to 8, provided that d+f is an integer of 0 to 8.

In the formula (CT-1) and the formula (CT-2), e represents 0 or 1. When e represents 0, L² and L³ are bonded together by a single bond.

In the formula (CT-1) and the formula (CT-2), f represents an integer of 0 to 4, and may represent an integer of 0 to 2, or may represent 0 or 1. Note that e+f is an integer of 1 to 4, and e+f may be 1 or 2.

R¹ and R² in the formula (CT-1) each independently represent an alkyl group, a cycloalkyl group, an alkenyl group, a cycloalkenyl group, an aryl group, or a heteroaryl group.

The descriptions, specific examples, and preferred ranges of the alkyl groups, cycloalkyl groups, alkenyl groups, cycloalkenyl groups, aryl groups, and heteroaryl groups represented by R¹ and R² are the same as those described above for the alkyl groups, cycloalkyl groups, alkenyl groups, cycloalkenyl groups, aryl groups, and heteroaryl groups represented by R³ and R⁴.

When R¹ and R² include a methylene group, at least one of the methylene group may be substituted with a divalent heteroatom-containing group. The divalent heteroatom-containing group may be, for example, an oxygen atom, a sulfur atom, a sulfinyl group, a sulfonyl group, a carbonyl group, an ester group, a nitrogen atom-containing group, or a group that is a combination of two or more of the foregoing. The nitrogen atom-containing group may be, for example, —NR—, where R represents a hydrogen atom or an organic group. Examples of the organic group represented by R include the same groups as the above-described organic groups represented by R³ and R⁴, and preferred are alkyl groups or aryl groups.

At least two of R¹, R², and the aromatic ring to which L¹ is bonded may be bonded together directly by a single bond or via any one selected from the group consisting of an oxygen atom, a sulfur atom, a nitrogen atom-containing group, and a methylene group, to form a ring. Examples of the nitrogen atom-containing group include —NR—, where R represents a hydrogen atom or an organic group. Examples of the organic group represented by R include the same groups as the above-described organic groups represented by R³ and R⁴, and preferred are alkyl groups or aryl groups.

R¹ and R² preferably represent an aryl group.

R¹ and R² preferably represent an aryl group, and any one of R¹ and R² is also preferably directly bonded, by a single bond, to the aromatic ring to which L¹ is bonded, to form a ring. In the formula (CT-2), R¹² represents an aryl group or a heteroaryl group.

The descriptions, specific examples, and preferred ranges of the aryl group and heteroaryl group represented by R¹² are the same as those described above for the aryl groups and heteroaryl groups represented by R³ and R⁴.

R¹² and the aromatic ring to which L¹ is bonded may be bonded together directly by a single bond or via any one selected from the group consisting of an oxygen atom, a sulfur atom, a nitrogen atom-containing group, and a methylene group, to form a ring. Examples of the nitrogen atom-containing group include —NR—, where R represents a hydrogen atom or an organic group. Examples of the organic group represented by R include the same groups as the above-described organic groups represented by R³ and R⁴, and preferred are alkyl groups or aryl groups.

The cation (CT) is preferably a cation represented by the formula (CT-1), more preferably a cation represented by the following formula (CT-1-1) or a cation represented by a formula (CT-1-2), and still more preferably a cation represented by the formula (CT-1-2).

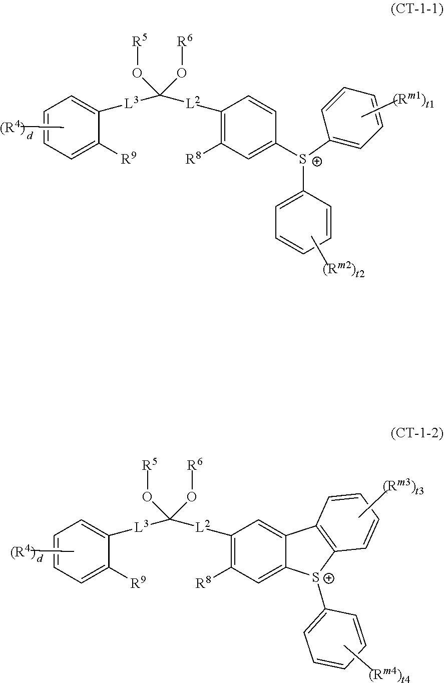

In the formula (CT-1-1) and the formula (CT-1-2),

R⁴ represents an organic group, a hydroxy group, a mercapto group, an amino group, a nitro group, a phosphino group, a silyl group, or a halogen atom. When a plurality of R⁴ are present, the plurality of R⁴ may be bonded together directly by a single bond or via a linking group to form a ring.

R⁵ and R⁶ each independently represent an alkyl group, a cycloalkyl group, an alkenyl group, a cycloalkenyl group, an aryl group, or a heteroaryl group. When R⁵ and R⁶ include a methylene group, at least one of the methylene group may be substituted with a divalent heteroatom-containing group. R⁵ and R⁶ may be bonded together directly by a single bond or via any one selected from the group consisting of an oxygen atom, a sulfur atom, and an alkylene group to form a ring.

R⁸ and R⁹ each independently represent a hydrogen atom, an organic group, a hydroxy group, a mercapto group, an amino group, a nitro group, a phosphino group, a silyl group, or a halogen atom, or R⁸ and R⁹ are bonded together to represent a single bond or a divalent linking group.

L² and L³ each independently represent a single bond, an alkenylene group having 2 carbon atoms, an alkynylene group having 2 carbon atoms, a carbonyl group, a sulfinyl group, or a sulfonyl group.

d represents an integer of 0 to 4.

R^{m 1}, R^{m 2}, R^{m 3}, and R^{m 4} each independently represent a substituent.

t1 and t2 each independently represent an integer of 0 to 5.

t3 represents an integer of 0 to 4.

t4 represents an integer of 0 to 5.

The descriptions, specific examples, and preferred ranges of R⁴, R⁵, R⁶, R⁸, R⁹, L², L³, and d in the formula (CT-1-1) and the formula (CT-1-2) are respectively the same as those described above for R⁴, R⁵, R⁶, R⁸, R⁹, L², L³, and d in the formula (CT-1).

R^{m 1}, R^{m 2}, R^{m 3}, and R^{m 4} each independently represent a substituent. The substituent is not particularly limited. Examples of the substituent include the above-described organic groups represented by R³ and R⁴ in the formula (CT-1), a hydroxy group, a mercapto group, an amino group, a nitro group, a phosphino group, a silyl group, halogen atoms (such as a fluorine atom, a chlorine atom, a bromine atom, and an iodine atom), acid-decomposable groups, and substituents that are combinations of two or more of the foregoing (substituents in which one or more hydrogen atoms included in such an organic group, hydroxy group, mercapto group, amino group, phosphino group, silyl group, or acid-decomposable group are substituted with such an organic group, hydroxy group, mercapto group, amino group, nitro group, phosphino group, silyl group, halogen atom, or acid-decomposable group). The “acid-decomposable group” is the same as that in the description of “Repeating unit having acid-decomposable group” serving as an example of the repeating unit (u2) described later.

t1 and t2 each independently represent an integer of 0 to 5, may be an integer of 0 to 4, or may be an integer of 0 to 3.

t3 represents an integer of 0 to 4, may be an integer of 0 to 3, or may be an integer of 0 to 2.

t4 represents an integer of 0 to 5, may be an integer of 0 to 4, or may be an integer of 0 to 3.

Specific examples of the cation (CT) will be described below, but the present invention is not limited to these.

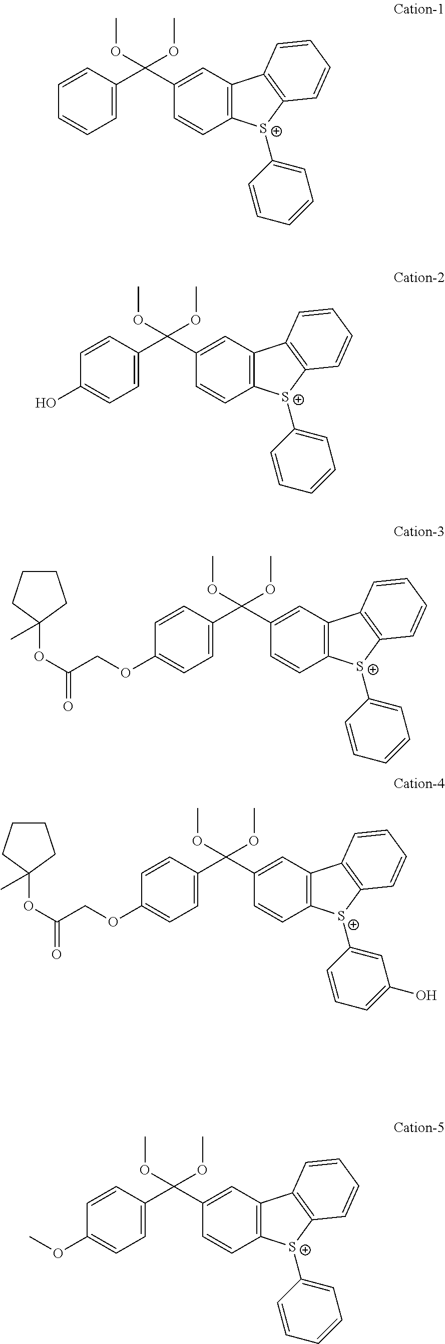 [SMILES: COC(OC)(c1ccccc1)c1ccc2c(c1)c1ccccc1[s+]2-c1ccccc1 ; COC(OC)(c1ccc(O)cc1)c1ccc2c(c1)c1ccccc1[s+]2-c1ccccc1 ; COC(OC)(c1ccc(OCC(=O)OC2(C)CCCC2)cc1)c1ccc2c(c1)c1ccccc1[s+]2-c1ccccc1 ; COC(OC)(c1ccc(OCC(=O)OC2(C)CCCC2)cc1)c1ccc2c(c1)c1ccccc1[s+]2-c1cccc(O)c1 ; COc1ccc(C(OC)(OC)c2ccc3c(c2)c2ccccc2[s+]3-c2ccccc2)cc1]

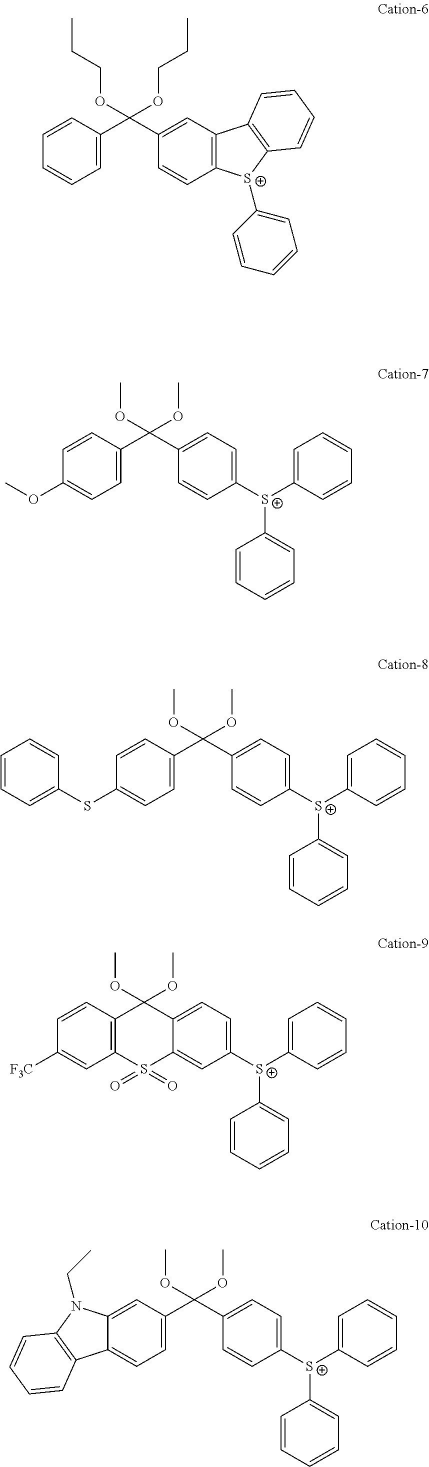 [SMILES: CCCOC(OCCC)(c1ccccc1)c1ccc2c(c1)c1ccccc1[s+]2-c1ccccc1 ; COc1ccc(C(OC)(OC)c2ccc([S+](c3ccccc3)c3ccccc3)cc2)cc1 ; COC(OC)(c1ccc(Sc2ccccc2)cc1)c1ccc([S+](c2ccccc2)c2ccccc2)cc1 ; COC1(OC)c2ccc([S+](c3ccccc3)c3ccccc3)cc2S(=O)(=O)c2cc(C(F)(F)F)ccc21 ; CCn1c2ccccc2c2ccc(C(OC)(OC)c3ccc([S+](c4ccccc4)c4ccccc4)cc3)cc21]

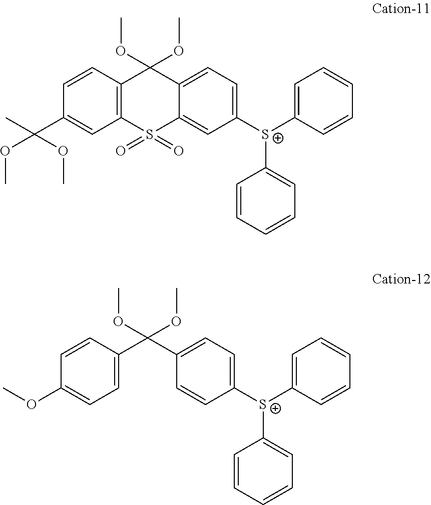 [SMILES: COC(C)(OC)c1ccc2c(c1)S(=O)(=O)c1cc([S+](c3ccccc3)c3ccccc3)ccc1C2(OC)OC ; COc1ccc(C(OC)(OC)c2ccc([S+](c3ccccc3)c3ccccc3)cc2)cc1]

The cation (CT) preferably undergoes a structural change by action of an acid, and preferably undergoes a structural change to generate a ketone group. The generated ketone compound having the ketone group preferably has a larger peak area of the absorption spectrum for light having wavelengths of 300 nm to 450 nm than the peak area of the absorption spectrum of the cation (CT) for light having wavelengths of 300 nm to 450 nm. The ketone compound preferably generates an acid upon irradiation with ultraviolet rays.

The Cation-1 to Cation-12 undergo a structural change by action of an acid to generate ketone compounds. The ketone compounds formed by structural change from the Cation-1 to Cation-12 have larger peak areas in the absorption spectra for light having wavelengths of 300 nm to 450 nm than the peak areas in the absorption spectra for light having wavelengths of 300 nm to 450 nm of the Cation-1 to Cation-12, which are the pre-change structures. The ketone compounds generate an acid upon irradiation with ultraviolet rays.

For example, as described below, the Cation-1 undergoes a structural change due to action of an acid to generate a ketone group to provide a ketone compound, a Ketone-1. The Ketone-1 has a larger peak area of the absorption spectrum for light having wavelengths of 300 nm to 450 nm than the peak area of the absorption spectrum for light having wavelengths of 300 nm to 450 nm of the Cation-1, which is the pre-change structure. In addition, the Ketone-1 generates an acid upon irradiation with ultraviolet rays.

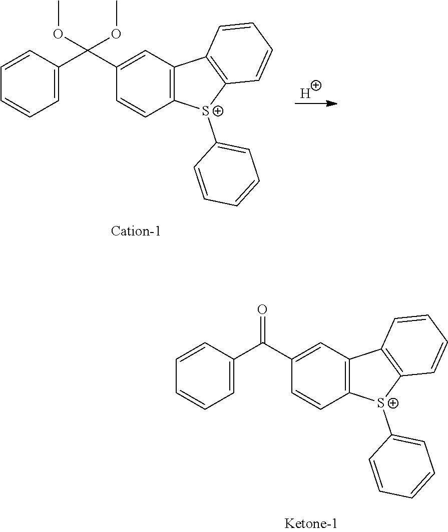

The repeating unit (u1) includes an anion bonded to the molecular chain of the resin (X). The anion is not particularly limited, but is, for example, preferably an anion represented by any one of the following formulas (an1) to (an8), and particularly preferably an anion represented by the following formula (an1).

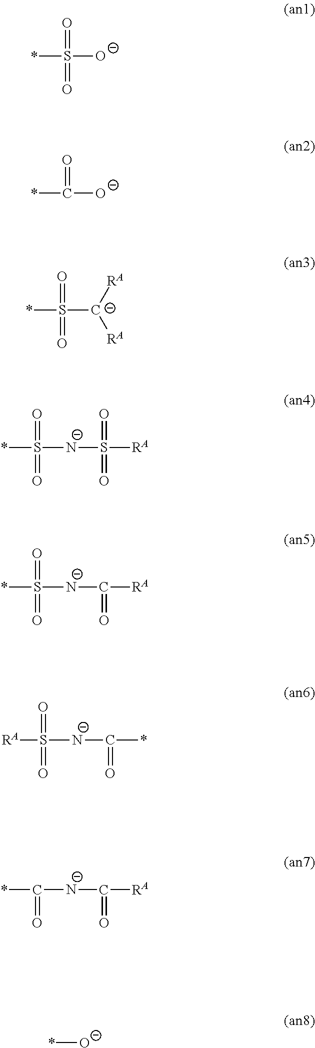

In the formulas (an1) to (an8), * represent a bonding site to the molecular chain of the resin (X). In the formulas (an3) to (an7), R^{A} each independently represent an organic group. The two R^{A} in the formula (an3) may be the same or different.

The organic group represented by R^{A} is not particularly limited, but may be, for example, an organic group having 1 to 20 carbon atoms, and is preferably an organic group having 1 to 10 carbon atoms. The organic group may include a heteroatom such as an oxygen atom, a sulfur atom, or a nitrogen atom. The organic group is, for example, preferably a cyano group, an alkyl group, a cycloalkyl group, or an aryl group. The organic group may have a substituent, and the substituent is not particularly limited, but may be, for example, a halogen atom or a hydroxy group, and is preferably a fluorine atom.

The anion represented by any one of the formulas (an1) to (an8) may be bonded to an aliphatic group or an aromatic group included in the molecular chain of the resin (X). When the anion represented by any one of the formulas (an1) to (an8) is bonded to an aliphatic group included in the molecular chain of the resin (X), the aliphatic group may have a substituent, and preferably has a fluorine atom. When the anions represented by the formulas (an1) to (an8) are bonded to an aromatic group included in the molecular chain of the resin (X), the aromatic group may have a substituent, and preferably has a fluorine atom.

The repeating unit (u1) is preferably represented by a formula (UA1) below.

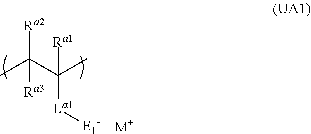

In the formula (UA1), R^{a1}, R^{a2}, and R^{a3} each independently represent a hydrogen atom, an alkyl group, a cycloalkyl group, a halogen atom, a cyano group, or an alkoxycarbonyl group. L^{a1} represents a single bond or a divalent linking group. Er represents an anion. M⁺represents a cation (CT).

In the formula (UA1), R^{a1}, R^{a2}, and R^{a3} each independently represent a hydrogen atom, an alkyl group, a cycloalkyl group, a halogen atom, a cyano group, or an alkoxycarbonyl group.

For R^{a1}, R^{a2}, and R^{a3}, the alkyl group may be either linear or branched. The number of carbon atoms of the alkyl group is not particularly limited, but is preferably 1 to 10, more preferably 1 to 5, and particularly preferably 1 to 3. Examples of the alkyl group include a methyl group, an ethyl group, an n-propyl group, an isopropyl group, an n-butyl group, an isobutyl group, and a t-butyl group.

For R^{a1}, R^{a2}, and R^{a3}, the number of carbon atoms of the cycloalkyl group is not particularly limited, but is preferably 3 to 20, and more preferably 5 to 15. For R^{a1}, R^{a2}, and R^{a3} the cycloalkyl group may be a monocyclic cycloalkyl group such as a cyclopentyl group or a cyclohexyl group, or may be a polycyclic cycloalkyl group such as a norbornyl group, a tetracyclodecanyl group, a tetracyclododecanyl group, or an adamantyl group.

For R^{a1}, R^{a2}, and R^{a3}, the halogen atom may be a fluorine atom, a chlorine atom, a bromine atom, or an iodine atom, and is preferably a fluorine atom or an iodine atom.

For R^{a1}, R^{a2}, and R^{a3}, the alkyl group included in the alkoxycarbonyl group may be either linear or branched. The number of carbon atoms of the alkyl group included in the alkoxycarbonyl group is not particularly limited, but is preferably 1 to 10, more preferably 1 to 5, and particularly preferably 1 to 3.

L^{a1} in the formula (UA1) represents a single bond or a divalent linking group.

The divalent linking group represented by L^{a1} may be —CO—, —O—, —S—, —SO—, —SO₂—, —NR^{B}—, an aliphatic group, an aromatic group, or a linking group in which a plurality of the foregoing are linked together. RB represents a hydrogen atom or an organic group. The aliphatic group is preferably an aliphatic group having 1 to 20 carbon atoms, and examples include alkylene groups, cycloalkylene groups, and alkenylene groups. The alkylene group may be linear or branched. The number of carbon atoms of the alkylene group is preferably 1 to 20, more preferably 1 to 10, and still more preferably 1 to 5. The number of carbon atoms of the cycloalkylene group is not particularly limited, but is preferably 3 to 20, and more preferably 5 to 15. The cycloalkylene group may be a monocyclic cycloalkylene group or a polycyclic cycloalkylene group. The alkenylene group may be linear or branched. The number of carbon atoms of the alkenylene group is preferably 2 to 20, more preferably 2 to 10, and still more preferably 2 to 5. The aromatic group may be an aromatic hydrocarbon group or an aromatic heterocyclic group. The aromatic hydrocarbon group may be, for example, an arylene group having 6 to 18 carbon atoms such as a phenylene group, a tolylene group, a naphthylene group, or an anthracenylene group, particularly preferably a phenylene group or a naphthylene group, and most preferably a phenylene group. The aromatic heterocyclic group is, for example, preferably a group including a heterocyclic ring such as a thiophene ring, a furan ring, a pyrrole ring, a benzothiophene ring, a benzofuran ring, a benzopyrrole ring, a triazine ring, an imidazole ring, a benzimidazole ring, a triazole ring, a thiadiazole ring, or a thiazole ring. The aliphatic group and the aromatic group may have a substituent. The substituent is not particularly limited, but may be an alkyl group, a cycloalkyl group, an aryl group, an alkoxy group, a halogen atom, a hydroxy group, or the like, and is preferably a fluorine atom.

L^{a1} preferably includes an arylene group, and more preferably includes an arylene group having a fluorine atom.

The organic group represented by RB is not particularly limited, but may be, for example, an organic group having 1 to 20 carbon atoms. The organic group may include a heteroatom such as an oxygen atom, a sulfur atom, or a nitrogen atom. Preferred examples of the organic group include a cyano group, alkyl groups, cycloalkyl groups, and aryl groups.

E₁ in the formula (UA1) represents an anion. Er is, for example, preferably an anion represented by any one of the formulas (an1) to (an7), and is particularly preferably an anion represented by the formula (an1).

M⁺in the formula (UA1) represents a cation (CT). The descriptions, specific examples, and preferred ranges of the cation (CT) are the same as those described above.

The repeating unit (u1) is preferably represented by a formula (UA2) below.

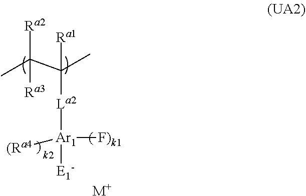

In the formula (UA2), R^{a1}, R^{a2}, and R^{a3} each independently represent a hydrogen atom, an alkyl group, a cycloalkyl group, a halogen atom, a cyano group, or an alkoxycarbonyl group. L^{a2} represents a single bond or a divalent linking group. Ar₁ represents an aromatic group. R^{a4} represents a substituent other than fluorine atoms. k1 represents an integer of 1 or more. k2 represents an integer of 0 or more. Er represents an anion. M⁺represents a cation (CT).

The descriptions, specific examples, and preferred ranges of R^{a1}, R^{a2}, R^{a3}, E1; and M+in the formula (UA2) are respectively the same as those described above for R^{a1}, R^{a2}, R^{a3}, E1⁻, and M⁺in the formula (UA1).

L^{a2} in the formula (UA2) represents a single bond or a divalent linking group.

The divalent linking group represented by L^{a2} may be —CO—, —O—, —S—, —SO—, —SO₂—, an aliphatic group, an aromatic group, and a linking group in which a plurality of the foregoing are linked together.

The divalent linking group represented by L^{a2} is preferably —COO—, —O—, —SO₃—, an aliphatic group, an aromatic group, or a linking group in which a plurality of the foregoing are linked together.

The descriptions, specific examples, and preferred ranges of the aliphatic group and the aromatic group represented by L^{a2} are respectively the same as the descriptions, specific examples, and preferred ranges described above for the aliphatic group and the aromatic group represented by L^{a1} in the formula (UA1).

Ar₁ in the formula (UA2) represents an aromatic group.

The aromatic group represented by Ar₁may be an aromatic hydrocarbon group or an aromatic heterocyclic group. The aromatic hydrocarbon group may be, for example, an arylene group having 6 to 18 carbon atoms such as a phenylene group, a tolylene group, a naphthylene group, or an anthracenylene group, particularly preferably a phenylene group or a naphthylene group, and most preferably a phenylene group. The aromatic heterocyclic group is preferably a group including a heterocyclic ring such as a thiophene ring, a furan ring, a pyrrole ring, a benzothiophene ring, a benzofuran ring, a benzopyrrole ring, a triazine ring, an imidazole ring, a benzimidazole ring, a triazole ring, a thiadiazole ring, or a thiazole ring.

In the formula (UA2), R^{a4} represents a substituent other than a fluorine atom.

The substituent represented by R^{a4} is not particularly limited as long as it is not a fluorine atom, but may be, for example, an alkyl group, a cycloalkyl group, an aryl group, an alkoxy group, or a hydroxy group.

In the formula (UA2), k1 represents an integer of 1 or more. k1 represents the number of fluorine atoms substituting the aromatic group represented by Ar₁. The upper limit of k1 varies depending on the type of the aromatic group represented by Ar₁. When Ar₁ represents a phenylene group, k1 preferably represents an integer of 1 to 4.

k2 in the formula (UA2) represents an integer of 0 or more. k2 represents the number of substituents other than fluorine atoms that can substitute the aromatic group represented by Ar₁. The upper limit of k2 varies depending on the type of the aromatic group represented by Ar₁. When Ar₁represents a phenylene group, k2 preferably represents an integer of 0 to 3.

The repeating unit (u1) is preferably represented by a formula (UA3) below.

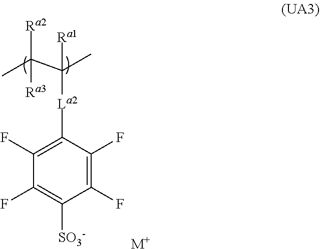

In the formula (UA3), R^{a1}, R^{a2}, and R^{a3} each independently represent a hydrogen atom, an alkyl group, a cycloalkyl group, a halogen atom, a cyano group, or an alkoxycarbonyl group. L^{a2} represents a single bond or a divalent linking group. M⁺represents a cation (CT).

The descriptions, specific examples, and preferred ranges of R^{a1}, R^{a2}, R^{a3}, L^{a2}, and M+in the formula (UA2) are respectively the same as those described above for R^{a1}, R^{a2}, R^{a3}, L^{a2}, and M⁺in the formula (UA2).

The repeating unit (u1) is preferably a repeating unit that generates an acid upon irradiation with an actinic ray or a radiation (also referred to as a “photoacid-generating repeating unit”).

The acid generated from the repeating unit (u1) is preferably a sulfonic acid.

The acid generated from the repeating unit (u1) has a pKa of preferably 2.0 or less, more preferably 1.0 or less, and still more preferably 0.0 or less. The acid generated from the repeating unit (u1) may have a pKa of-20.0 or more.

The pKa of the acid generated from the repeating unit (u1) is determined for the corresponding monomer by the above-described method. For example, when the repeating unit (u1) is the following X-1u (M⁺represents a cation (CT)), the acid generated from the repeating unit (u1) is the following X-1a; however, for the following X-1m, which is a monomer corresponding to the following X-1a, the pKa is determined by the above-described method, and this is defined as the pKa of the acid generated from the following X-1u.

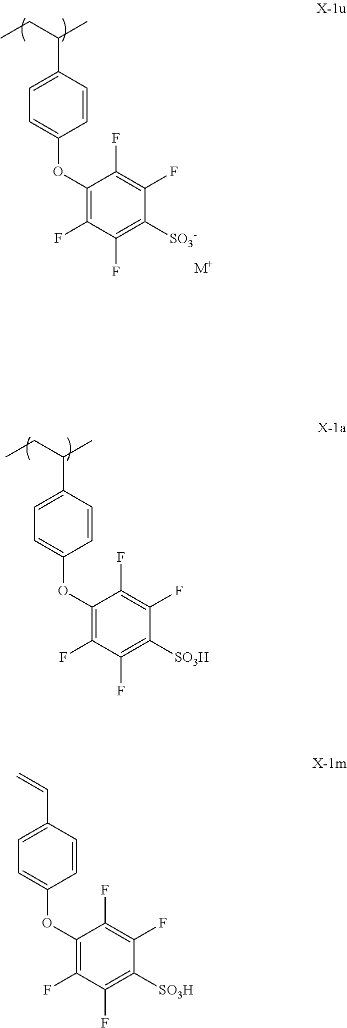

The content of the photoacid-generating repeating unit relative to the total resin content in the composition of the present invention is preferably 0.300 mmol/g or more and 2.000 mmol/g or less, more preferably 0.500 mmol/g or more and 2.000 mmol/g or less, and still more preferably 0.700 mmol/g or more and 2.000 mmol/g or less.

The content of the repeating unit (u1) relative to all the repeating units in the resin (X) is preferably 40 mass % or more, more preferably 50 mass % or more, still more preferably 60 mass % or more, particularly preferably 80 mass % or more, and most preferably 100 mass %.

The content of the repeating unit (u1) relative to the total resin content in the composition of the present invention is 40 mass % or more, preferably 50 mass % or more, more preferably 60 mass % or more, still more preferably 80 mass % or more, and particularly preferably 100 mass %. The content of the repeating unit (u1) relative to the total resin content in the composition of the present invention is 100 mass % or less.

The resin (X) may have a single type of repeating unit (u1) alone, or two or more types of repeating units (u1). When the resin (X) has two or more types of repeating units (u1), the total content thereof is preferably within such a preferred content range.

The total resin content in the composition of the present invention means the total mass of all the resins contained in the composition of the present invention. The “resin” is a compound having a weight-average molecular weight of 3000 or more. The “resin” includes not only the resin (X) but also resins (having a weight-average molecular weight of 3000 or more) other than the resin (X), such as the resin (A), hydrophobic resins, and surfactants described later.

Specific examples of the monomer corresponding to the structure other than the cation (CT) in the repeating unit (u1) will be described below, but the present invention is not limited thereto.

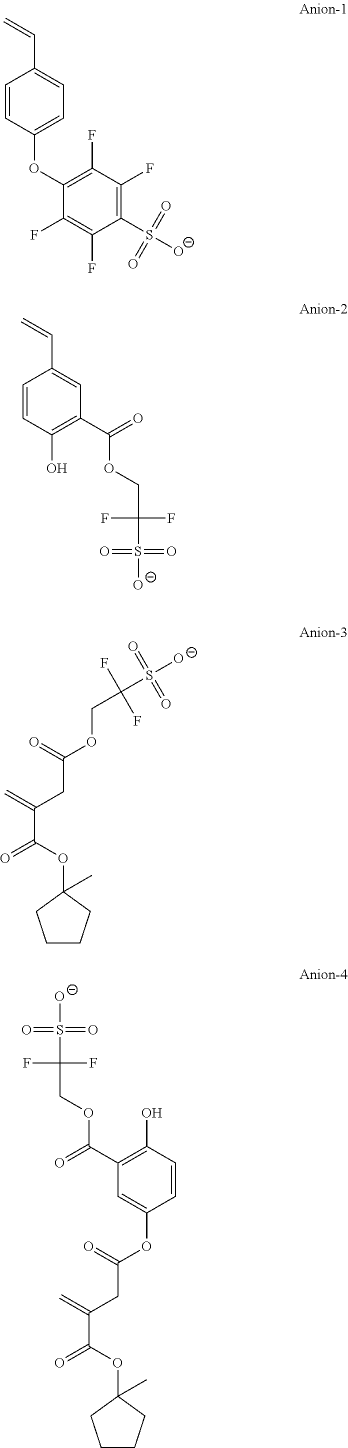

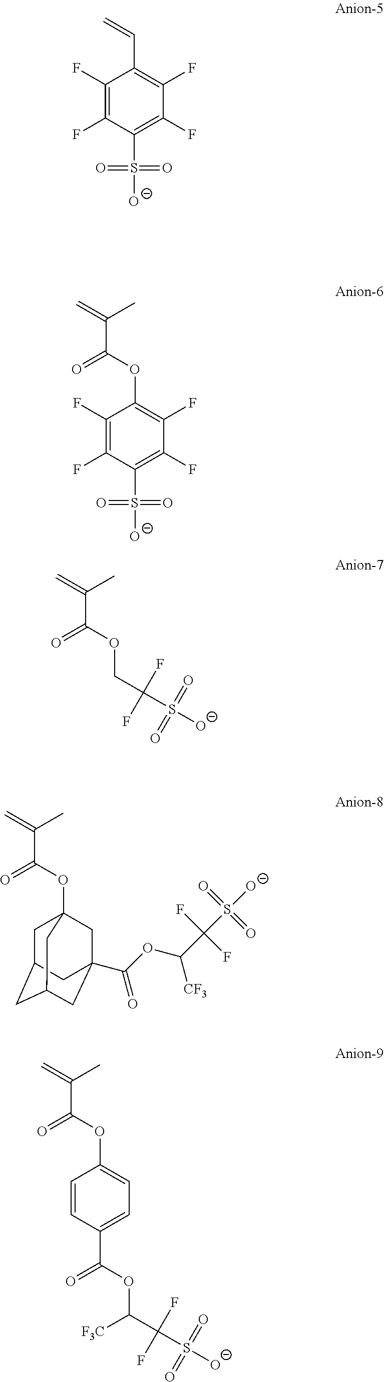

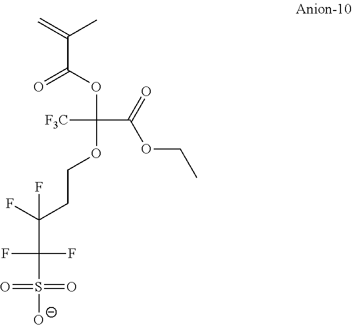

The reason why the composition of the present invention provides high sensitivity, high LCDU, and high resolution is not clear, but the inventors of the present invention has inferred the following mechanism. However, the present invention is not limited at all by the following inferred mechanism.

The resin having a photoacid-generating repeating unit generates a low-diffusion acid and hence high resolution for fine patterns is expected; however, acid diffusion is extremely suppressed, so that sufficient amplification is not obtained, which tends to result in lower sensitivity. In existing resist compositions using low-molecular-weight-compound photoacid generators, when the amount of photoacid generator added is increased, acid generation fluctuation is reduced and roughness performance is improved; however, when the amount of photoacid generator added is excessive, it causes excessive acid diffusion, which inferentially deteriorates resolution.

The inventors of the present invention have found that when the repeating unit (u1) including an anion bonded to the molecular chain of the resin and a cation (CT) constitutes 40 mass % or more of the total resin content in the composition of the present invention, sensitivity, LCDU, and resolution are improved. The composition of the present invention includes 40 mass % or more of a repeating unit corresponding to a photoacid generator relative to the total resin content; however, the anion is bonded to the molecular chain of the resin, so that, without causing excessive acid diffusion, sufficient amplification is obtained, which inferentially results in the remarkable advantages.

### Other Repeating Unit

The resin (X) may have another repeating unit in addition to the repeating unit (u1). The other repeating unit is also referred to as “repeating unit (u2)”. The repeating unit (u2) is a repeating unit different from the repeating unit (u1).

The content of the repeating unit (u2) relative to all the repeating units in the resin (X) may be 0 mass % or more and 60 mass % or less. When the resin (X) has the repeating unit (u2), the content of the repeating unit (u2) relative to all the repeating units in the resin (X) may be 1 mass % or more, 5 mass % or more, or 10 mass % or more. The content of the repeating unit (u2) relative to all the repeating units in the resin (X) may be 50 mass % or less, 40 mass % or less, or 30 mass % or less.

The resin (X) may have one type of repeating unit (u2) alone, or may have two or more types of repeating units (u2). When the resin (X) has two or more types of repeating units (u2), the total content thereof is preferably within such a preferred content range.

### Repeating Unit Having Acid-Decomposable Group

The repeating unit (u2) may be a repeating unit having an acid-decomposable group.

The repeating unit having an acid-decomposable group may be a repeating unit having an acid-decomposable group including an unsaturated bond.

The acid-decomposable group refers to a group that is decomposed by action of an acid to generate a polar group. The acid-decomposable group preferably has a structure in which the polar group is protected with a group (leaving group) that leaves by action of an acid.

The polar group is preferably an alkali-soluble group; examples include acidic groups such as a carboxyl group, a phenolic hydroxy group, fluorinated alcohol groups, a sulfonic acid group, a phosphoric acid group, a sulfonamide group, a sulfonylimide group, (alkylsulfonyl) (alkylcarbonyl)methylene groups, (alkylsulfonyl) (alkylcarbonyl)imide groups, bis(alkylcarbonyl)methylene groups, bis(alkylcarbonyl)imide groups, bis(alkylsulfonyl)methylene groups, bis(alkylsulfonyl)imide groups, tris(alkylcarbonyl)methylene groups, and tris(alkylsulfonyl)methylene groups, and an alcoholic hydroxy group.

In particular, the polar group is preferably a carboxyl group, a phenolic hydroxy group, a fluorinated alcohol group (preferably a hexafluoroisopropanol group), or a sulfonic acid group.

Examples of the group that leaves by action of an acid include groups represented by formulas (Y¹) to (Y⁴).

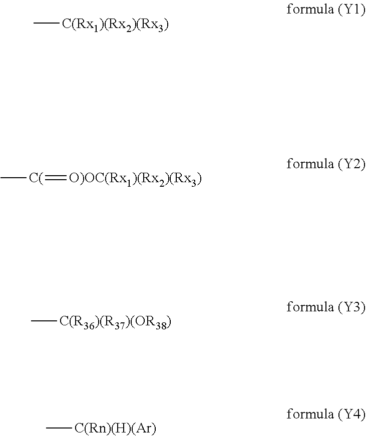

In the formula (Y¹) and the formula (Y²), Rx1 to Rx3 each independently represent an alkyl group (linear or branched), a cycloalkyl group (monocyclic or polycyclic), an alkenyl group (linear or branched), or an aryl group (monocyclic or polycyclic). Note that, when Rx₁ to Rx₃ are all alkyl groups (linear or branched), at least two of Rx₁ to Rx₃ are preferably methyl groups.

In particular, Rx₁ to Rx₃ preferably each independently represent a linear or branched alkyl group, and Rx₁ to Rx₃ more preferably each independently represent a linear alkyl group.

Two of Rx₁ to Rx₃ may be bonded together to form a monocycle or a polycycle.

For Rx₁ to Rx₃, the alkyl group is preferably an alkyl group having 1 to 5 carbon atoms such as a methyl group, an ethyl group, an n-propyl group, an isopropyl group, an n-butyl group, an isobutyl group, or a t-butyl group.

For Rx₁ to Rx₃, the cycloalkyl group may be a monocyclic cycloalkyl group such as a cyclopentyl group or a cyclohexyl group, or may be a polycyclic cycloalkyl group such as a norbornyl group, a tetracyclodecanyl group, a tetracyclododecanyl group, or an adamantyl group.

For Rx₁ to Rx₃, the aryl group is preferably an aryl group having 6 to 10 carbon atoms, and may be, for example, a phenyl group, a naphthyl group, or an anthryl group.

For Rx₁ to Rx₃, the alkenyl group is preferably a vinyl group.

The ring formed by bonding together two of Rx₁ to Rx₃ is preferably a cycloalkyl group. The cycloalkyl group formed by bonding together two of Rx₁ to Rx₃ is preferably a monocyclic cycloalkyl group such as a cyclopentyl group or a cyclohexyl group, or a polycyclic cycloalkyl group such as a norbornyl group, a tetracyclodecanyl group, a tetracyclododecanyl group, or an adamantyl group, and more preferably a monocyclic cycloalkyl group having 5 to 6 carbon atoms.

In the cycloalkyl group formed by bonding together two of Rx₁ to Rx₃, one of methylene groups constituting the ring may be replaced by a heteroatom such as an oxygen atom, a group including a heteroatom such as a carbonyl group, or a vinylidene group. In the cycloalkyl group, one or more ethylene groups constituting the cycloalkane ring may be replaced by vinylene groups.

The group represented by the formula (Y¹) or the formula (Y²) preferably has a form in which, for example, Rx₁ is a methyl group or an ethyl group, and Rx₂ and Rx₃ are bonded together to form the above-described cycloalkyl group.

When a composition of the present invention is, for example, a resist composition used for EUV exposure, the alkyl groups, cycloalkyl groups, alkenyl groups, and aryl groups represented by Rx₁ to Rx₃ and the ring formed by bonding together two of Rx₁ to Rx₃ also preferably further have, as a substituent, a fluorine atom or an iodine atom.

In the formula (Y³), R₃₆ to R₃₈ each independently represent a hydrogen atom or a monovalent organic group. R₃₇ and R₃₈ may be bonded together to form a ring. The monovalent organic group may be an alkyl group, a cycloalkyl group, an aryl group, an aralkyl group, or an alkenyl group. R₃₆ is also preferably a hydrogen atom.

Note that the alkyl group, the cycloalkyl group, the aryl group, and the aralkyl group may include a heteroatom such as an oxygen atom and/or a group including a heteroatom such as a carbonyl group. For example, in the alkyl group, the cycloalkyl group, the aryl group, and the aralkyl group, one or more methylene groups may be replaced by a heteroatom such as an oxygen atom and/or a group including a heteroatom such as a carbonyl group.

R₃₈ and another substituent of the main chain of the repeating unit may be bonded together to form a ring. The group formed by bonding together R₃₈ and another substituent of the main chain of the repeating unit is preferably an alkylene group such as a methylene group.

When a composition of the present invention is, for example, a resist composition used for EUV exposure, the monovalent organic groups represented by R₃₆ to R₃₈ and the ring formed by bonding together R₃₇ and R₃₈ also preferably further have, as a substituent, a fluorine atom or an iodine atom.

The formula (Y³) is preferably a group represented by the following formula (Y³-1).

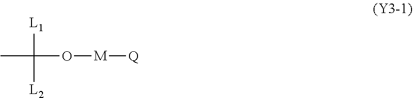

L₁ and L₂ each independently represent a hydrogen atom, an alkyl group, a cycloalkyl group, an aryl group, or a group that is a combination of the foregoing (for example, a group that is a combination of an alkyl group and an aryl group).

M represents a single bond or a divalent linking group.

Q represents an alkyl group that may include a heteroatom, a cycloalkyl group that may include a heteroatom, an aryl group that may include a heteroatom, an amino group, an ammonium group, a mercapto group, a cyano group, an aldehyde group, or a group that is a combination of the foregoing (for example, a group that is a combination of an alkyl group and a cycloalkyl group).

In the alkyl group and the cycloalkyl group, for example, one of methylene groups may be replaced by a heteroatom such as an oxygen atom or a group including a heteroatom such as a carbonyl group.

Note that one of L₁ and L₂ is preferably a hydrogen atom and the other is preferably an alkyl group, a cycloalkyl group, an aryl group, or a group that is a combination of an alkylene group and an aryl group.

At least two of Q, M, and L₁ may be bonded together to form a ring (preferably a 5-membered or 6-membered ring).

From the viewpoint of forming finer patterns, L₂ is preferably a secondary or tertiary alkyl group, and more preferably a tertiary alkyl group. Examples of the secondary alkyl group include an isopropyl group, a cyclohexyl group, and a norbornyl group; examples of the tertiary alkyl group include a tert-butyl group and an adamantane group. In such examples, Tg (glass transition temperature) and activation energy are increased, so that film hardness is ensured and fogging can be suppressed.

When a composition of the present invention is, for example, a resist composition used for EUV exposure, the alkyl groups, cycloalkyl groups, aryl groups, and groups that are combinations of the foregoing represented by L₁ and L² also preferably further have, as a substituent, a fluorine atom or an iodine atom. The alkyl groups, the cycloalkyl groups, the aryl groups, and the aralkyl groups also preferably include, in addition to a fluorine atom and an iodine atom, a heteroatom such as an oxygen atom. Specifically, in the alkyl groups, the cycloalkyl groups, the aryl groups, and the aralkyl groups, for example, one of methylene groups may be replaced by a heteroatom such as an oxygen atom or a group including a heteroatom such as a carbonyl group.

When a composition of the present invention is, for example, a resist composition used for EUV exposure, in the alkyl group that may include a heteroatom, cycloalkyl group that may include a heteroatom, aryl group that may include a heteroatom, amino group, ammonium group, mercapto group, cyano group, aldehyde group, and group that is a combination of the foregoing represented by Q, such a heteroatom is also preferably a heteroatom selected from the group consisting of a fluorine atom, an iodine atom, and an oxygen atom.

In the formula (Y4), Ar represents an aromatic ring group. Rn represents an alkyl group, a cycloalkyl group, or an aryl group. Rn and Ar may be bonded together to form a non-aromatic ring. Ar is preferably an aryl group.

When a composition of the present invention is, for example, a resist composition used for EUV exposure, the aromatic ring group represented by Ar and the alkyl group, cycloalkyl group, and aryl group represented by Rn also preferably have, as a substituent, a fluorine atom or an iodine atom.

From the viewpoint of providing a repeating unit having high acid-decomposability, in the leaving group protecting the polar group, when a non-aromatic ring is directly bonded to the polar group (or its residue), in the non-aromatic ring, a ring-member atom adjacent to a ring-member atom directly bonded to the polar group (or its residue) also preferably does not have, as a substituent, a halogen atom such as a fluorine atom.

Alternatively, the group that leaves by the action of an acid may be a 2-cyclopentenyl group having a substituent (such as an alkyl group) such as a 3-methyl-2-cyclopentenyl group, or a cyclohexyl group having a substituent (such as an alkyl group) such as a 1,1,4,4-tetramethylcyclohexyl group.

The repeating unit having an acid-decomposable group is also preferably a repeating unit represented by a formula (A).

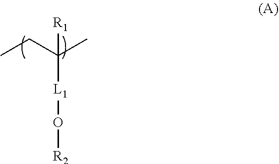

L₁ represents a divalent linking group that may have a fluorine atom or an iodine atom; R₁ represents a hydrogen atom, a fluorine atom, an iodine atom, or an alkyl group that may have a fluorine atom or an iodine atom, or an aryl group that may have a fluorine atom or an iodine atom; R₂ represents a leaving group that leaves by the action of an acid and that may have a fluorine atom or an iodine atom. Note that at least one of L₁, R₁, or R₂ has a fluorine atom or an iodine atom.

Examples of the divalent linking group that is represented by L¹ and may have a fluorine atom or an iodine atom include —CO—, —O—, —S—, —SO—, —SO₂—, hydrocarbon groups that may have a fluorine atom or an iodine atom (for example, alkylene groups, cycloalkylene groups, alkenylene groups, and arylene groups), and linking groups in which a plurality of the foregoing are linked together. In particular, L₁ is preferably —CO—, an arylene group, or an -arylene group-alkylene group having a fluorine atom or an iodine atom-, and more preferably —CO— or an -arylene group-alkylene group having a fluorine atom or an iodine atom-.

The arylene group is preferably a phenylene group.

The alkylene group may be linear or may be branched. The number of carbon atoms of the alkylene group is not particularly limited, but is preferably 1 to 10, and more preferably 1 to 3.

In the alkylene group having a fluorine atom or an iodine atom, the total number of fluorine atoms and iodine atoms is not particularly limited, but is preferably 2 or more, more preferably 2 to 10, and still more preferably 3 to 6.

The alkyl group represented by R₁ may be linear or may be branched. The number of carbon atoms of the alkyl group is not particularly limited, but is preferably 1 to 10, and more preferably 1 to 3.

In the alkyl group represented by R₁ and having a fluorine atom or an iodine atom, the total number of fluorine atoms and iodine atoms is not particularly limited, but is preferably 1 or more, more preferably 1 to 5, and still more preferably 1 to 3.

The alkyl group represented by R₁ may include a heteroatom other than halogen atoms, such as an oxygen atom.

Examples of the leaving group that is represented by R₂ and may have a fluorine atom or an iodine atom include leaving groups that are represented by the above-described formulas (Y1) to (Y4) and that have a fluorine atom or an iodine atom.

The repeating unit having an acid-decomposable group is also preferably a repeating unit represented by a formula (AI).

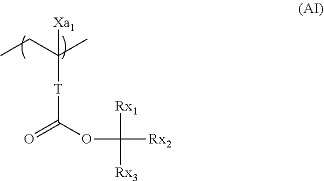

In the formula (AI), Xa1 represents a hydrogen atom or an alkyl group that may have a substituent. T represents a single bond or a divalent linking group. Rx₁ to Rx₃ each independently represent an alkyl group (linear or branched), a cycloalkyl group (monocyclic or polycyclic), an alkenyl group (linear or branched), or an aryl group (monocyclic or polycyclic). Note that, when Rx₁ to Rx₃ are all alkyl groups (linear or branched), at least two of Rx₁ to Rx₃ are preferably methyl groups.

Two of Rx₁ to Rx₃ may be bonded together to form a monocycle or a polycycle (such as a monocyclic or polycyclic cycloalkyl group).

The alkyl group that is represented by Xa₁ and may have a substituent may be, for example, a methyl group or a group represented by —CH₂—R₁₁. R₁₁ represents a halogen atom (such as a fluorine atom), a hydroxy group, or a monovalent organic group. The monovalent organic group represented by R₁₁ is, for example, an alkyl group that has 5 or less carbon atoms and that may be substituted with a halogen atom, an acyl group that has 5 or less carbon atoms and that may be substituted with a halogen atom, or an alkoxy group that has 5 or less carbon atoms and that may be substituted with a halogen atom, and is preferably an alkyl group having 3 or less carbon atoms, and more preferably a methyl group. Xa₁ is preferably a hydrogen atom, a methyl group, a trifluoromethyl group, or a hydroxymethyl group.

For T, the divalent linking group may be an alkylene group, an aromatic ring group, a —COO-Rt- group, or an —O-Rt- group. In the formulas, Rt represent an alkylene group or a cycloalkylene group.

Tis preferably a single bond or a —COO-Rt- group. When T represents a —COO-Rt- group, Rt is preferably an alkylene group having 1 to 5 carbon atoms, and more preferably a —CH₂— group, a —(CH₂)₂— group, or a —(CH₂)₃— group.

For Rx₁ to Rx₃, the alkyl group is preferably an alkyl group having 1 to 4 carbon atoms such as a methyl group, an ethyl group, an n-propyl group, an isopropyl group, an n-butyl group, an isobutyl group, or a t-butyl group.

For Rx₁ to Rx₃, the cycloalkyl group is preferably a monocyclic cycloalkyl group such as a cyclopentyl group or a cyclohexyl group, or a polycyclic cycloalkyl group such as a norbornyl group, a tetracyclodecanyl group, a tetracyclododecanyl group, or an adamantyl group.

For Rx₁ to Rx₃, the aryl group is preferably an aryl group having 6 to 10 carbon atoms and may be, for example, a phenyl group, a naphthyl group, or an anthryl group.

For Rx₁ to Rx₃, the alkenyl group is preferably a vinyl group.

The cycloalkyl group formed by bonding together two of Rx₁ to Rx₃ is preferably a monocyclic cycloalkyl group such as a cyclopentyl group or a cyclohexyl group. Also preferred are polycyclic cycloalkyl groups such as a norbornyl group, a tetracyclodecanyl group, a tetracyclododecanyl group, and an adamantyl group. In particular, preferred is a monocyclic cycloalkyl group having 5 to 6 carbon atoms.

In the cycloalkyl group formed by bonding together two of Rx₁ to Rx₃, for example, one of methylene groups constituting the ring may be replaced by a heteroatom such as an oxygen atom, a group including a heteroatom such as a carbonyl group, or a vinylidene group. In the cycloalkyl group, one or more of the ethylene groups constituting the cycloalkane ring may be replaced by vinylene groups.

The repeating unit represented by the formula (AI) preferably has a form in which, for example, Rx₁ is a methyl group or an ethyl group, and Rx₂ and Rx₃ are bonded together to form the above-described cycloalkyl group.

When the above-described groups each have a substituent, examples of the substituent include alkyl groups (having 1 to 4 carbon atoms), halogen atoms, a hydroxyl group, alkoxy groups (having 1 to 4 carbon atoms), a carboxyl group, and alkoxycarbonyl groups (having 2 to 6 carbon atoms). The substituent preferably has 8 or less carbon atoms.

The repeating unit represented by the formula (AI) is preferably an acid-decomposable (meth)acrylic acid tertiary alkyl ester-based repeating unit (the repeating unit where Xa1 represents a hydrogen atom or a methyl group and T represents a single bond).

The resin (X) may have, as the repeating unit having an acid-decomposable group, a repeating unit having an acid-decomposable group including an unsaturated bond.

The repeating unit having an acid-decomposable group including an unsaturated bond is preferably a repeating unit represented by a formula (B).

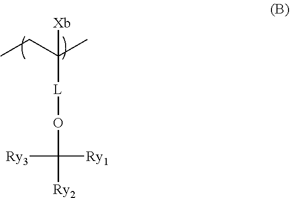

In the formula (B), Xb represents a hydrogen atom, a halogen atom, or an alkyl group that may have a substituent. L represents a single bond or a divalent linking group that may have a substituent. Ry₁ to Ry₃ each independently represent a linear or branched alkyl group, a monocyclic or polycyclic cycloalkyl group, an alkenyl group, an alkynyl group, or a monocyclic or polycyclic aryl group. Note that at least one of Ry₁ to Ry₃ represents an alkenyl group, an alkynyl group, a monocyclic or polycyclic cycloalkenyl group, or a monocyclic or polycyclic aryl group.

Two of Ry₁ to Ry₃ may be bonded together to form a monocycle or a polycycle (such as a monocyclic or polycyclic cycloalkyl group or cycloalkenyl group).

For Xb, the alkyl group that may have a substituent may be, for example, a methyl group or a group represented by —CH₂—R₁₁. R₁₁ represents a halogen atom (such as a fluorine atom), a hydroxy group, or a monovalent organic group such as an alkyl group that has 5 or less carbon atoms and that may be substituted with a halogen atom, an acyl group that has 5 or less carbon atoms and that may be substituted with a halogen atom, or an alkoxy group that has 5 or less carbon atoms and that may be substituted with a halogen atom, is preferably an alkyl group having 3 or less carbon atoms, and more preferably a methyl group. Xb is preferably a hydrogen atom, a fluorine atom, a methyl group, a trifluoromethyl group, or a hydroxymethyl group.

For L, the divalent linking group may be an -Rt- group, a —CO— group, a —COO-Rt- group, a —COO-Rt-CO— group, an -Rt-CO— group, or an —O-Rt- group. In the formulas, Rt represent an alkylene group, a cycloalkylene group, or an aromatic ring group, and is preferably an aromatic ring group.

Lis preferably an -Rt- group, a —CO— group, a —COO-Rt-CO— group, or an -Rt-CO— group. Rt may have a substituent such as a halogen atom, a hydroxy group, or an alkoxy group.

For Ry₁ to Ry₃, the alkyl group is preferably an alkyl group having 1 to 4 carbon atoms such as a methyl group, an ethyl group, an n-propyl group, an isopropyl group, an n-butyl group, an isobutyl group, or a t-butyl group.

For Ry₁ to Ry₃, the cycloalkyl group is preferably a monocyclic cycloalkyl group such as a cyclopentyl group or a cyclohexyl group, or a polycyclic cycloalkyl group such as a norbornyl group, a tetracyclodecanyl group, a tetracyclododecanyl group, or an adamantyl group.

For Ry₁ to Ry₃, the aryl group is preferably an aryl group having 6 to 10 carbon atoms, and may be, for example, a phenyl group, a naphthyl group, or an anthryl group.

For Ry to Ry₃, the alkenyl group is preferably a vinyl group.

For Ry₁ to Ry₃, the alkynyl group is preferably an ethynyl group.

For Ry₁ to Ry₃, the cycloalkenyl group is preferably a structure in which a monocyclic cycloalkyl group such as a cyclopentyl group or a cyclohexyl group includes partially a double bond.

The cycloalkyl group formed by bonding together two of Ry₁ to Ry₃ is preferably a monocyclic cycloalkyl group such as a cyclopentyl group or a cyclohexyl group, or a polycyclic cycloalkyl group such as a norbornyl group, a tetracyclodecanyl group, a tetracyclododecanyl group, or an adamantyl group. In particular, more preferred is a monocyclic cycloalkyl group having 5 to 6 carbon atoms.

In the cycloalkyl group or the cycloalkenyl group formed by bonding together two of Ry₁ to Ry₃, for example, one of methylene groups constituting the ring may be replaced by a heteroatom such as an oxygen atom, a group including a heteroatom such as a carbonyl group, a —SO₂— group, or a —SO₃— group, a vinylidene group, or a combination of the foregoing. In the cycloalkyl group or the cycloalkenyl group, one or more ethylene groups constituting the cycloalkane ring or the cycloalkene ring may be replaced by vinylene groups.

The repeating unit represented by the formula (B) preferably has a form in which, for example, Ry is a methyl group, an ethyl group, a vinyl group, an allyl group, or an aryl group, and Ry₂ and Ry₃ are bonded together to form the above-described cycloalkyl group or cycloalkenyl group.

When the above-described groups each have a substituent, examples of the substituent include alkyl groups (having 1 to 4 carbon atoms), halogen atoms, a hydroxyl group, alkoxy groups (having 1 to 4 carbon atoms), a carboxyl group, and alkoxycarbonyl groups (having 2 to 6 carbon atoms). The substituent preferably has 8 or less carbon atoms.

The repeating unit represented by the formula (B) is preferably an acid-decomposable (meth)acrylic acid tertiary ester-based repeating unit (the repeating unit where Xb represents a hydrogen atom or a methyl group, and L represents a —CO— group), an acid-decomposable hydroxystyrene tertiary alkyl ether-based repeating unit (the repeating unit where Xb represents a hydrogen atom or a methyl group, and L represents a phenyl group), or an acid-decomposable styrenecarboxylic acid tertiary ester-based repeating unit (the repeating unit where Xb represents a hydrogen atom or a methyl group, and L represents an -Rt-CO— group (where R^{t} is an aromatic group)).

Specific examples of the repeating unit having an acid-decomposable group including an unsaturated bond include, for example, the repeating units described in to of WO2022/024928A. The above descriptions are incorporated herein.

For the repeating unit having an acid-decomposable group, the descriptions in to of WO2022/024928A can be referred to. The above descriptions are incorporated herein.

Specific examples of the repeating unit having an acid-decomposable group will be described below, but are not limited to these.

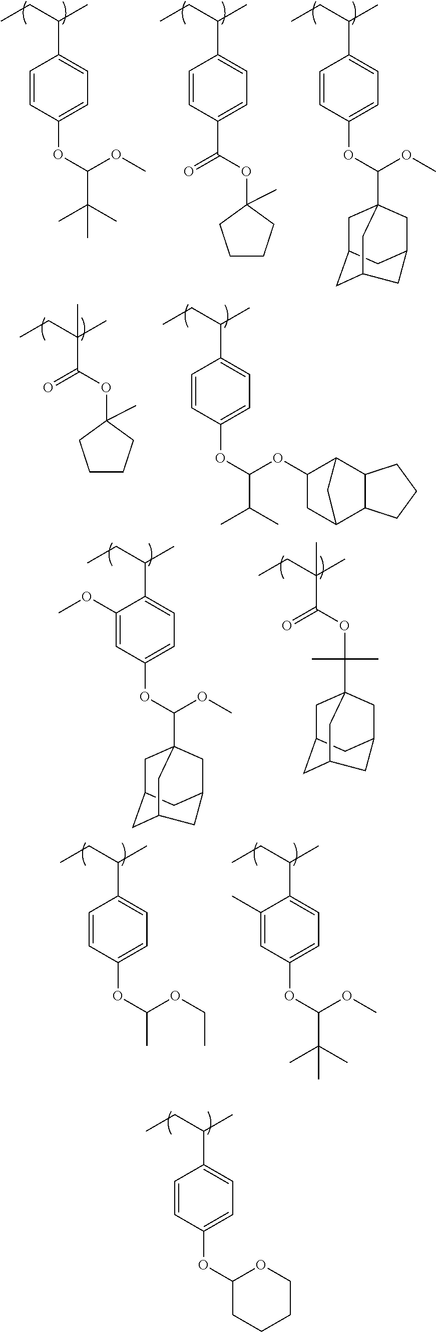

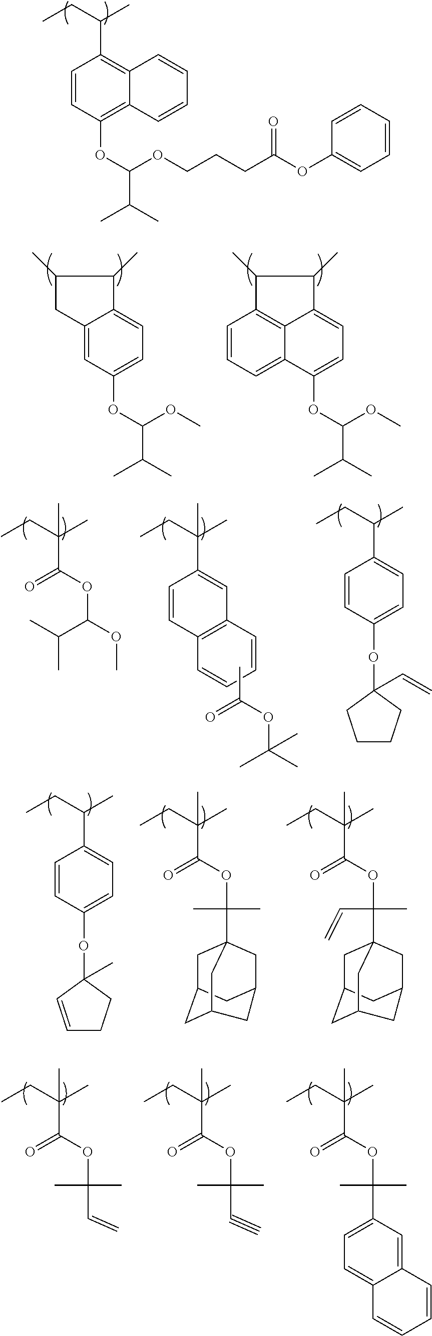

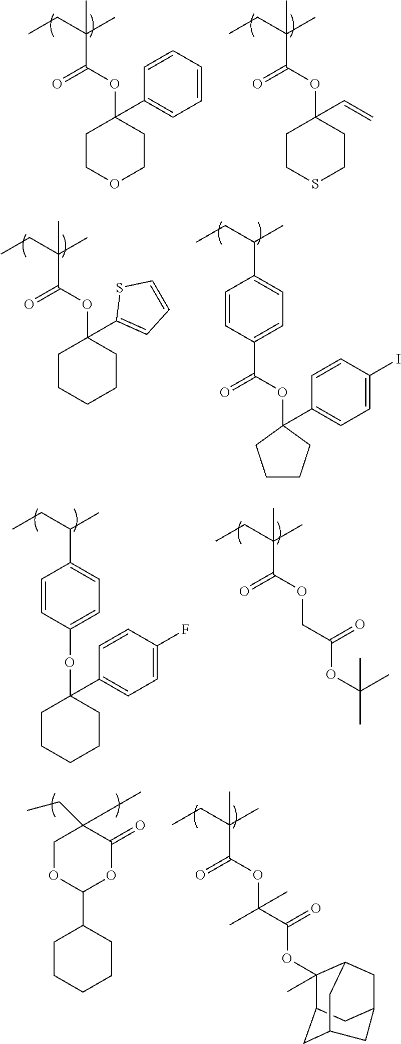

Any one of all the resins contained in the composition of the present invention preferably has a repeating unit having an acid-decomposable group. The content of the repeating unit having an acid-decomposable group relative to the total resin content in the composition of the present invention is preferably 0.500 mmol/g or more and 6.000 mmol/g, more preferably 1.000 mmol/g or more and 6.000 mmol/g or less, and still more preferably 1.500 mmol/g or more and 6.000 mmol/g or less.

### Repeating Unit Having Acid Group

The repeating unit (u2) may be a repeating unit having an acid group.

The acid group is preferably, for example, a carboxyl group, a phenolic hydroxyl group, a fluoroalcohol group (preferably a hexafluoroisopropanol group), a sulfonic acid group, a sulfonamide group, or an isopropanol group.

In the hexafluoroisopropanol group, one or more (preferably one to two) of the fluorine atoms may be substituted with groups other than fluorine atoms (such as alkoxycarbonyl groups). The acid group is also preferably —C(CF₃)(OH)—CF₂— formed in this manner. Alternatively, one or more of the fluorine atoms may be substituted with groups other than fluorine atoms, to form a ring including —C(CF₃)(OH)—CF₂—.

The repeating unit having an acid group is preferably a repeating unit different from the above-described repeating unit having a structure in which a polar group is protected with a group that leaves by action of an acid and repeating units described later and having a lactone group, a sultone group, or a carbonate group.

The repeating unit having an acid group may have a fluorine atom or an iodine atom.

Specific examples of the repeating unit having an acid group include, for example, the repeating units described in to and to of WO2022/024928A. The above descriptions are incorporated herein.

The repeating unit having an acid group is preferably a repeating unit having a phenolic hydroxyl group.

The repeating unit having a phenolic hydroxyl group is preferably a repeating unit different from the above-described repeating unit having an acid-decomposable group.

The repeating unit having a phenolic hydroxyl group is preferably a repeating unit represented by a formula (Pa2) below.

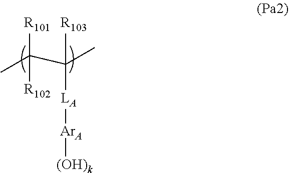

In the formula (Pa2), R₁₀₁, R₁₀₂, and R₁₀₃ each independently represent a hydrogen atom, an alkyl group, a cycloalkyl group, a halogen atom, a cyano group, or an alkoxycarbonyl group. R₁₀₂ may be bonded to ArA to form a ring and, in this case, R₁₀₂ represents a single bond or an alkylene group.

L_{A} represents a single bond or a divalent linking group.

Ar_{A} represents an aromatic ring group.

k represents an integer of 1 to 5.

R₁₀₁, R₁₀₂, and R₁₀₃ in the formula (Pa2) each independently represent a hydrogen atom, an alkyl group, a cycloalkyl group, a halogen atom, a cyano group, or an alkoxycarbonyl group.

For R₁₀₁, R₁₀₂, and R₁₀₃, the alkyl group may be either linear or branched. The number of carbon atoms of the alkyl group is not particularly limited, but is preferably 1 to 10, more preferably 1 to 5, and particularly preferably 1 to 3. Examples of the alkyl group include a methyl group, an ethyl group, an n-propyl group, an isopropyl group, an n-butyl group, an isobutyl group, and a t-butyl group.

For R₁₀₁, R₁₀₂, and R₁₀₃, the number of carbon atoms of the cycloalkyl group is not particularly limited, but is preferably 3 to 20, and more preferably 5 to 15. For R₁₀₁, R₁₀₂, and R₁₀₃, the cycloalkyl group is preferably a monocyclic cycloalkyl group such as a cyclopentyl group or a cyclohexyl group or a polycyclic cycloalkyl group such as a norbornyl group, a tetracyclodecanyl group, a tetracyclododecanyl group, or an adamantyl group.

For R₁₀₁, R₁₀₂, and R₁₀₃, the halogen atom may be a fluorine atom, a chlorine atom, a bromine atom, or an iodine atom, and is preferably a fluorine atom or an iodine atom.

For R₁₀₁, R₁₀₂, and R₁₀₃, the alkyl group included in the alkoxycarbonyl group may be either linear or branched. For the alkyl group included in the alkoxycarbonyl group, the number of carbon atoms is not particularly limited, but is preferably 1 to 5, and more preferably 1 to 3.

Ar_{A} in the formula (Pa2) represents an aromatic ring group, and more specifically represents a (k+1)-valent aromatic ring group. When k is 1, the divalent aromatic ring group is, for example, preferably an arylene group having 6 to 18 carbon atoms such as a phenylene group, a tolylene group, a naphthylene group, or an anthracenylene group, or a divalent aromatic ring group including a heterocycle such as a thiophene ring, a furan ring, a pyrrole ring, a benzothiophene ring, a benzofuran ring, a benzopyrrole ring, a triazine ring, an imidazole ring, a benzimidazole ring, a triazole ring, a thiadiazole ring, or a thiazole ring. The aromatic ring group may have a substituent.

When k is an integer of 2 or more, specific examples of the (k+1)-valent aromatic ring group include groups provided by removing any (k-1) hydrogen atoms from the above-described specific examples of the divalent aromatic ring group.

The (k+1)-valent aromatic ring group may further have a substituent.

The substituent that the (k+1)-valent aromatic ring group may have is not particularly limited, but examples thereof include alkyl groups such as a methyl group, an ethyl group, a propyl group, an isopropyl group, an n-butyl group, a sec-butyl group, a hexyl group, a 2-ethylhexyl group, an octyl group, and a dodecyl group; alkoxy groups such as a methoxy group, an ethoxy group, a hydroxyethoxy group, a propoxy group, a hydroxypropoxy group, and a butoxy group; and aryl groups such as a phenyl group.

Ar_{A} preferably represents an aromatic ring group having 6 to 18 carbon atoms, and more preferably represents a benzene ring group, a naphthalene ring group, or a biphenylene ring group.

L_{A} in the formula (Pa2) represents a single bond or a divalent linking group.

The divalent linking group represented by L_{A} is not particularly limited, but may be, for example, —COO—, —CONR₁₀₄—, an alkylene group, or a group that is a combination of two or more of the foregoing groups. The above R¹⁰⁴ represents a hydrogen atom or an alkyl group.

The alkylene group is not particularly limited, but is preferably an alkylene group having 1 to 8 carbon atoms such as a methylene group, an ethylene group, a propylene group, a butylene group, a hexylene group, or an octylene group.

When R₁₀₄ represents an alkyl group, the alkyl group may be an alkyl group having 20 or less carbon atoms such as a methyl group, an ethyl group, a propyl group, an isopropyl group, an n-butyl group, a sec-butyl group, a hexyl group, a 2-ethylhexyl group, an octyl group, or a dodecyl group, and is preferably an alkyl group having 8 or less carbon atoms.

The repeating unit represented by the formula (Pa2) preferably includes a hydroxystyrene structure. In other words, Ar_{A} preferably represents a benzene ring group.

k preferably represents an integer of 1 to 3, and more preferably represents 1 or 2.

Specific examples of the repeating unit having an acid group will be described below, but are not limited to these. In the following structural formulas, G¹ and G² each independently represent a hydrogen atom, a methyl group, a fluorine atom, a chlorine atom, a trifluoromethyl group, a cyano group, a hydroxy group, or a hydroxymethyl group. f1 represent an integer of 1 to 3.

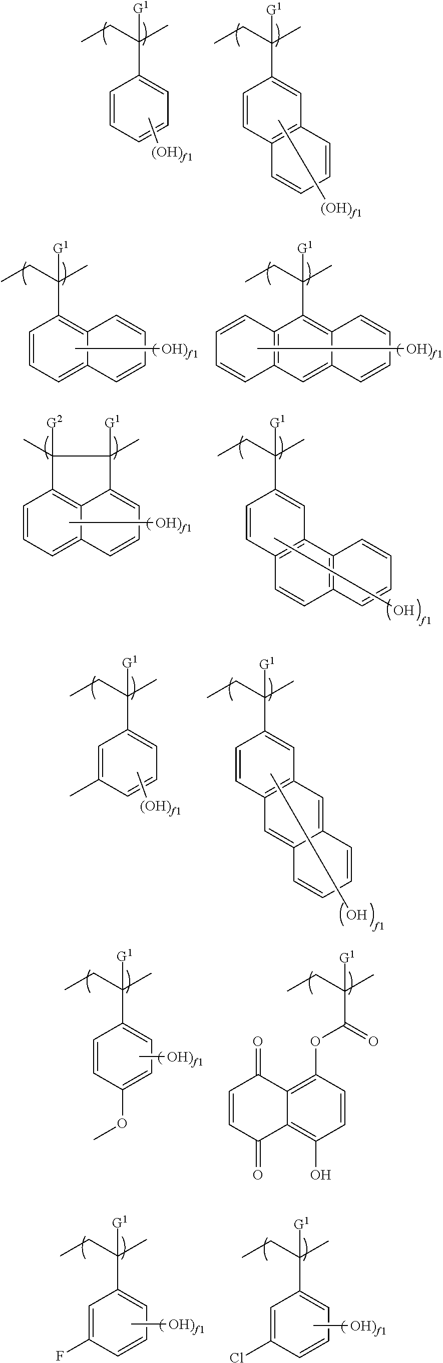

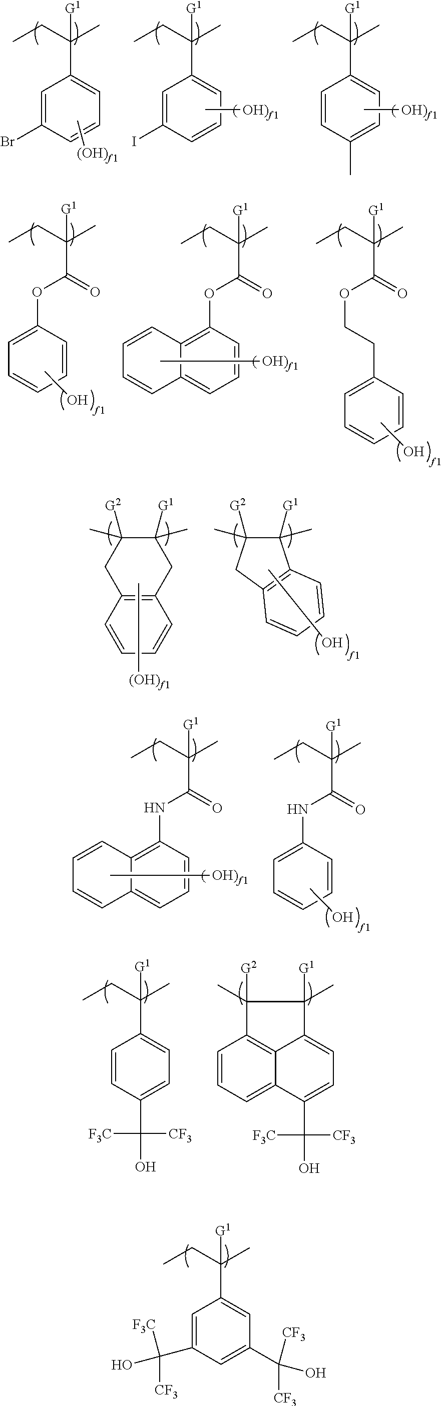

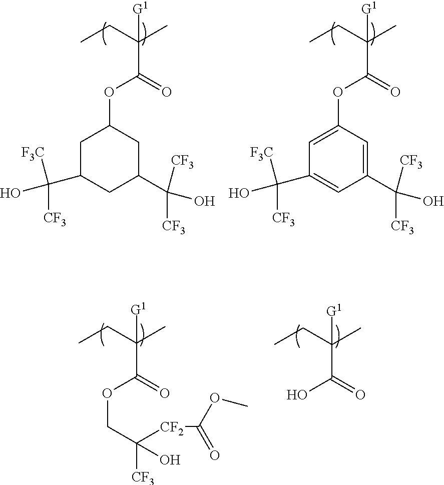

Any one of all the resins contained in the composition of the present invention preferably has a repeating unit having an acid group. The acid group is preferably an acid group having a pKa of 2 or more and 16 or less, more preferably an acid group having a pKa of 4 or more and 14 or less, and still more preferably an acid group having a pKa of 6 or more and 12 or less. Note that the above pKa is a pKa determined, by the above-described method, for a monomer corresponding to the repeating unit having an acid group. The content of the repeating unit having an acid group relative to the total resin content in the composition of the present invention is preferably 0.500 mmol/g or more to 6.000 mmol/g, more preferably 1.000 mmol/g or more to 6.000 mmol/g or less, and still more preferably 1.500 mmol/g or more to 6.000 mmol/g or less.

Repeating unit not having acid-decomposable group or acid group, but having fluorine atom, bromine atom, or iodine atom

The repeating unit (u2) may be a repeating unit not having an acid-decomposable group or an acid group, but having a fluorine atom, a bromine atom, or an iodine atom (hereafter, also referred to as “unit X”).

The unit X is preferably a repeating unit represented by a formula (C).

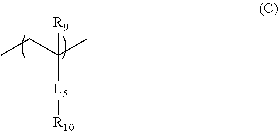

L₅ represents a single bond or an ester group. R₉ represents a hydrogen atom or an alkyl group that may have a fluorine atom or an iodine atom. R₁₀ represents a hydrogen atom, an alkyl group that may have a fluorine atom or an iodine atom, a cycloalkyl group that may have a fluorine atom or an iodine atom, an aryl group that may have a fluorine atom or an iodine atom, or a group that is a combination of the foregoing.

Specific examples of the repeating unit having a fluorine atom or an iodine atom include, for example, the repeating units described in to of WO2022/024928A . The above descriptions are incorporated herein.

### Repeating Unit Having Lactone Group, Sultone Group, or Carbonate Group

The repeating unit (u2) may be a repeating unit having a lactone group, a sultone group, or a carbonate group (hereafter, also referred to as “unit Y”).

The unit Y also preferably does not have acid groups such as a hydroxy group and a hexafluoropropanol group.

The lactone group or the sultone group has a lactone structure or a sultone structure. The lactone structure or the sultone structure is preferably a 5- to 7-membered lactone structure or a 5- to 7-membered sultone structure. In particular, more preferred is a 5- to 7-membered lactone structure to which another ring structure is fused so as to form a bicyclo structure or a spiro structure, or a 5- to 7-membered sultone structure to which another ring structure is fused so as to form a bicyclo structure or a spiro structure.

The carbonate group is preferably a cyclic carbonic acid ester group.

For the repeating unit having a cyclic carbonic acid ester group, for example, the descriptions in to of WO2022/024928A can be referred to. The above descriptions are incorporated herein.

The repeating unit (u2) may be a repeating unit having a lactone group, a sultone group, or a carbonate group obtained by removing one or more hydrogen atoms from a ring-member atom of a lactone structure represented by any one of the following formulas (LC1-1) to (LC1-22), a sultone structure represented by any one of the following formulas (SL1-1) to (SL1-3), or a cyclic carbonic acid ester structure represented by any one of the following formulas (CC1-1) to (CC1-2).

In the repeating unit (u2), a lactone group, a sultone group, or a carbonate group may be directly bonded to the main chain. For example, a ring-member atom of the lactone group, the sultone group, or the carbonate group may constitute the main chain of the resin (X). The lactone group, the sultone group, and the carbonate group may have a substituent.

In the following structural formulas, R^{L} represent a substituent. When a plurality of R^{L} are present, the plurality of R^{L} may be the same or may be different. R^{L} may be, for example, an alkyl group having 1 to 8 carbon atoms, a cycloalkyl group having 4 to 10 carbon atoms, an alkoxy group having 1 to 8 carbon atoms, an alkoxycarbonyl group having 2 to 8 carbon atoms, a carboxyl group, a halogen atom, a cyano group, or an acid-decomposable group. el represent an integer of 0 to 4. When a plurality of el are present, the plurality of el may be the same or may be different. When el is 2 or more, the plurality of R^{L} present may be the same or different, and the plurality of R^{L} present may bonded together to form a ring.

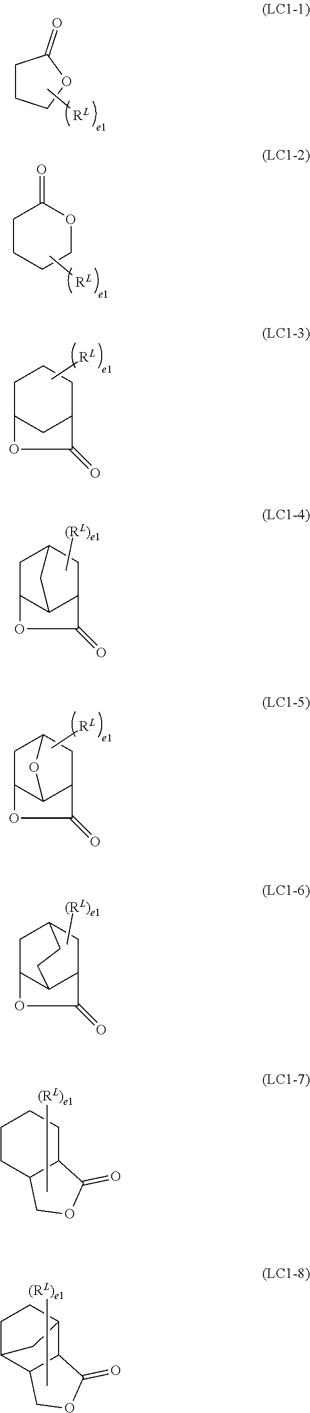

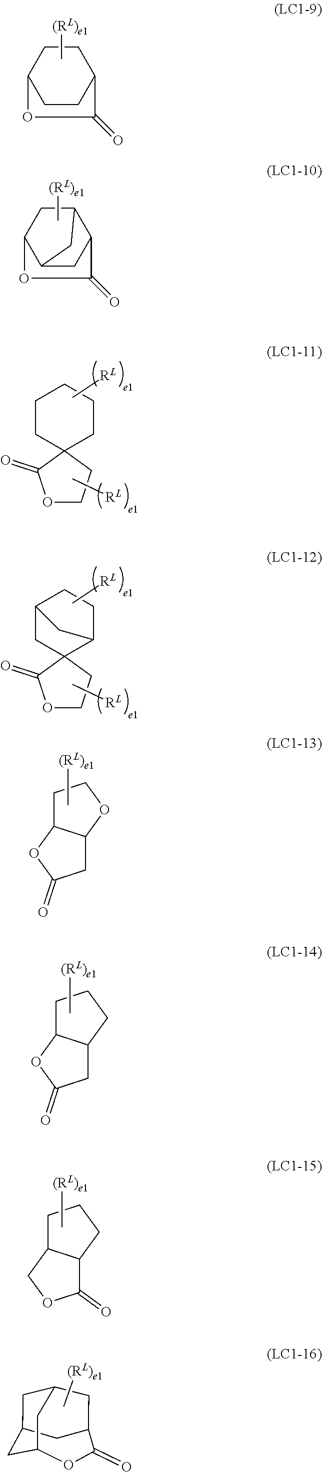

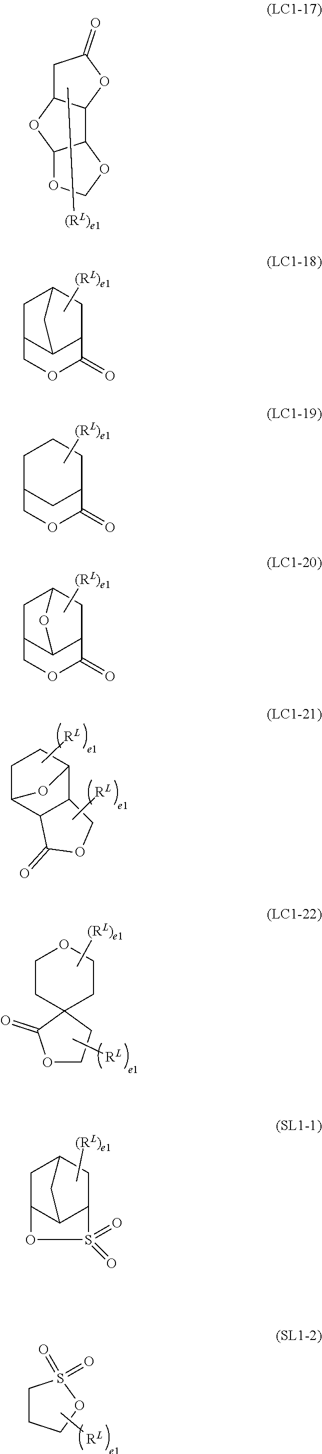

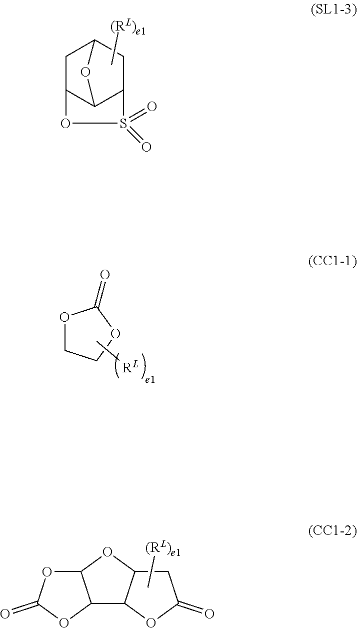

Examples of the repeating unit having a lactone group, a sultone group, or a carbonate group include a repeating unit represented by the following formula (AI-2).

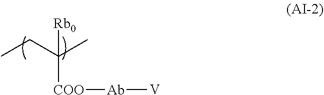

In the formula (AI-2), Rb₀ represents a hydrogen atom, a halogen atom, or an alkyl group having 1 to 4 carbon atoms. The alkyl group of Rb₀ may have a substituent. The substituent that the alkyl group of Rb₀ may have may be a hydroxyl group or a halogen atom.

The halogen atom of Rb₀ may be a fluorine atom, a chlorine atom, a bromine atom, or an iodine atom. Rb₀ is preferably a hydrogen atom or a methyl group.

Ab represents a single bond, an alkylene group, a divalent linking group having a monocyclic or polycyclic alicyclic hydrocarbon structure, an ether group, an ester group, a carbonyl group, or a divalent linking group that is a combination of the foregoing. In particular, Ab is preferably a single bond or a linking group represented by -Ab₁-CO₂—. Ab₁ is a linear or branched alkylene group or a monocyclic or polycyclic cycloalkylene group, and preferably a methylene group, an ethylene group, a cyclohexylene group, an adamantylene group, or a norbornylene group.

V represents a group formed by removing one hydrogen atom from a ring-member atom of a lactone structure represented by any one of the formulas (LC1-1) to (LC1-22), a group formed by removing one hydrogen atom from a ring-member atom of a sultone structure represented by any one of the formulas (SL1-1) to (SL1-3), or a group formed by removing one hydrogen atom from a ring-member atom of a cyclic carbonic acid ester structure represented by any one of the formulas (CC1-1) to (CC1-2).

### Repeating Unit Represented by Formula (V-1) or Formula (V-2)

The repeating unit (u2) may be a repeating unit represented by the following formula (V-1) or the following formula (V-2).

The repeating unit represented by the following formula (V-1) and the repeating unit represented by the following formula (V-2) are preferably repeating units different from the above-described repeating units.

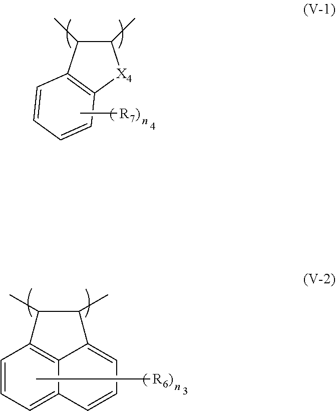

In the formulas (V-1) and (V-2), R⁶ and R⁷ each independently represent a hydrogen atom, a hydroxy group, an alkyl group, an alkoxy group, an acyloxy group, a cyano group, a nitro group, an amino group, a halogen atom, an ester group (—OCOR or —COOR:R is an alkyl group or a fluorinated alkyl group having 1 to 6 carbon atoms), or a carboxyl group. The alkyl group is preferably a linear, branched, or cyclic alkyl group having 1 to 10 carbon atoms. n3 represents an integer of 0 to 6. n4 represents an integer of 0 to 4. X4 is a methylene group, an oxygen atom, or a sulfur atom.

Examples of the repeating unit represented by the formula (V-1) or the formula (V-2) include the repeating units described in Paragraph of WO2018/193954A .

### Repeating Unit Having Acid Diffusion Control Ability

The repeating unit (u2) may be a repeating unit having acid diffusion control ability.

Examples of the repeating unit having acid diffusion control ability include a repeating unit represented by the following formula (S1).

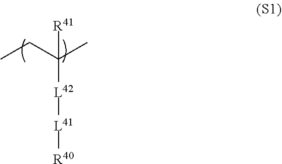

In the formula (S1), R⁴¹ represents a hydrogen atom or an alkyl group, L⁴¹ represents a single bond or a divalent linking group, L⁴² represents a divalent linking group, and R 40 represents a structural moiety that is decomposed upon irradiation with an actinic ray or a radiation to generate an acid in the side chain, provided that the pKa of the acid is higher than the pKa of the conjugate acid of the anion bonded to the molecular chain of the resin (X) included in the repeating unit (u1).

The alkyl group represented by R⁴¹ in the formula (S1) may be either linear or branched, and is preferably an alkyl group having 1 to 5 carbon atoms, more preferably a methyl group.

L⁴¹ represents a single bond or a divalent linking group, and preferably represents a single bond or an ester bond (—COO—).

L⁴² is preferably a linking group formed of at least one selected from the group consisting of an alkylene group, a cycloalkylene group, an arylene group, —O—, —CO—, —S—, —SO—, —SO₂—, and —NR—. R represents a hydrogen atom or an organic group. Examples of the organic group represented by R include the same groups as the above-described organic groups represented by R³ and R⁴, and preferred are alkyl groups and aryl groups.

The alkylene group may be either linear or branched. The number of carbon atoms of the alkylene group is not particularly limited, but is preferably 1 to 10.

The cycloalkylene group may be a monocyclic cycloalkylene group or a polycyclic cycloalkylene group. The number of carbon atoms of the cycloalkylene group is not particularly limited, but is preferably 3 to 20, and more preferably 5 to 15.

The number of carbon atoms of the arylene group is not particularly limited, but is preferably 6 to 20, and more preferably 6 to 10.

The alkylene group, the cycloalkylene group, and the arylene group may have a substituent, and examples of such substituents include the above-described substituents T.

R⁴⁰ is preferably a group represented by the following formula (S1-1).

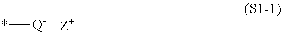

In the formula (S1-1), Q represents an acid residue, and Z+represents a cation. * represents a bonding site to L⁴¹

The acid residue is a group formed by dissociation of a proton from an acid.

Q is preferably O″, a carboxylate anion group (COO—), a sulfonate anion group (SO₃), or a sulfonamide group (represented by N—SO₂R^{N1} where R^{N1} represents an organic group, may be an organic group having 1 to 10 carbon atoms, is preferably an alkyl group, a fluoroalkyl group, or an aryl group), and more preferably O″ or COO″. When Q is O, L⁴² is preferably an arylene group, and more preferably a phenylene group.

Z⁺is preferably a sulfonium cation or an iodonium cation. Z+ may be the same as the above-described cation (CT).

The pKa of the acid generated from the repeating unit represented by the formula (S1) upon irradiation with an actinic ray or a radiation is preferably more than 2.0, more preferably 2.5 or more, and still more preferably 3.0 or more. The pKa of the acid generated from the repeating unit represented by the formula (S1) upon irradiation with an actinic ray or a radiation may be 13 or less.

The pKa of the acid generated from the repeating unit represented by the formula (S1) upon irradiation with an actinic ray or a radiation is determined for the corresponding monomer by the above-described method.

The number of types of repeating units that the resin (X) has is preferably 1 or more and 4 or less, more preferably 1 or more and 3 or less, and still more preferably 1 or more and 2 or less.

The number of types of repeating units included in all the resins contained in the composition of the present invention is preferably 1 or more and 4 or less, more preferably 1 or more and 3 or less, and still more preferably 1 or more and 2 or less.

The resin (X) can be synthesized by standard procedures (for example, by radical polymerization).

The weight-average molecular weight (Mw) of the resin (X) as a polystyrene-equivalent value determined by the GPC method is preferably 30000 or less, more preferably 1000 to 30000, still more preferably 3000 to 30000, and particularly preferably 5000 to 15000.

The dispersity (molecular weight distribution, PDI, Mw/Mn) of the resin (X) is preferably 1 to 5, more preferably 1 to 3, still more preferably 1 to 2.5, and particularly preferably 1 to 2.

The content of the resin (X) in the composition of the present invention is not particularly limited, but is, relative to the total solid content in the composition of the present invention, preferably 40 to 100 mass %, more preferably 50 to 100 mass %, still more preferably 60 to 100 mass %, and particularly preferably 70 to 100 mass %.

Such resins (X) may be used alone or in combination of two or more thereof. When two or more resins (X) are used, the total content thereof is preferably within such a preferred content range.

The composition of the present invention may contain other components in addition to the resin (X).

Resin that Undergoes Increase in Polarity by Action of Acid (Resin (A))

The composition of the present invention may contain a resin (also referred to as “resin (A)”) that undergoes an increase in polarity by action of an acid and that is different from the resin (X).

The resin (A) is a resin that does not have the above-described repeating unit (u1).

The resin (A) includes a group that is decomposed by action of an acid to undergo an increase in polarity (acid-decomposable group), and preferably includes a repeating unit having an acid-decomposable group.

The “repeating unit having an acid-decomposable group” that the resin (A) can have is the same as the above-described “repeating unit having an acid-decomposable group” in the repeating unit (u2).

The content of the repeating unit having an acid-decomposable group relative to all the repeating units in the resin (A) is preferably 15 mol % or more, more preferably 20 mol % or more, and still more preferably 30 mol % or more. The upper limit value relative to all the repeating units in the resin (A) is preferably 90 mol % or less, more preferably 80 mol % or less, still more preferably 70 mol % or less, and particularly preferably 60 mol % or less.

The resin (A) may include at least one repeating unit species selected from the group consisting of the following group A and/or at least one repeating unit species selected from the group consisting of the following group B.

Group A: the group consisting of the following repeating units (20) to (25):
(20) a repeating unit having an acid group;
(21) a repeating unit not having an acid-decomposable group or an acid group, but having a fluorine atom, a bromine atom, or an iodine atom;
(22) a repeating unit having a lactone group, a sultone group, or a carbonate group;
(23) a repeating unit represented by a formula (V-1) or a formula (V-2); and
(24) a repeating unit for lowering the mobility of the main chain.

Note that the repeating units described later and represented by a formula (A) to a formula (E) correspond to the repeating unit (24) for lowering the mobility of the main chain.

Group B: the group consisting of the following repeating units (30) to (32):
(30) a repeating unit having at least one group species selected from the group consisting of a lactone group, a sultone group, a carbonate group, a hydroxyl group, a cyano group, and an alkali-soluble group;
(31) a repeating unit having an alicyclic hydrocarbon structure and not exhibiting acid-decomposability; and
(32) a repeating unit not having a hydroxyl group or a cyano group and represented by a formula (III).

The “repeating unit having an acid group”, “repeating unit not having an acid-decomposable group or an acid group but having a fluorine atom, a bromine atom, or an iodine atom”, “repeating unit having a lactone group, a sultone group, or a carbonate group”, and “repeating unit represented by a formula (V-1) or a formula (V-2)” that the resin (A) can have are respectively the same as the above-described “repeating unit having an acid group”, “repeating unit not having an acid-decomposable group or an acid group but having a fluorine atom, a bromine atom, or an iodine atom”, “repeating unit having a lactone group, a sultone group, or a carbonate group”, and “repeating unit represented by the formula (V-1) or the formula (V-2)” described in the repeating unit (u2).

When the resin (A) includes a repeating unit having an acid group, the content of the repeating unit having an acid group is, relative to all the repeating units in the resin (A), preferably 10 mol % or more, and more preferably 15 mol % or more. The upper limit value relative to all the repeating units in the resin (A) is preferably 70 mol % or less, more preferably 65 mol % or less, and still more preferably 60 mol % or less.

The content of the repeating unit not having an acid-decomposable group or an acid group but having a fluorine atom, a bromine atom, or an iodine atom relative to all the repeating units in the resin (A) is preferably 0 mol % or more, more preferably 5 mol % or more, and still more preferably 10 mol % or more. The upper limit value relative to all the repeating units in the resin (A) is preferably 50 mol % or less, more preferably 45 mol % or less, and still more preferably 40 mol % or less.

When the resin (A) includes a repeating unit having a lactone group, a sultone group, or a carbonate group, the content of the repeating unit having a lactone group, a sultone group, or a carbonate group relative to all the repeating units in the resin (A) is preferably 1 mol % or more, and more preferably 10 mol % or more. The upper limit value relative to all the repeating units in the resin (A) is preferably 85 mol % or less, more preferably 80 mol % or less, still more preferably 70 mol % or less, and particularly preferably 60 mol % or less.

### Repeating Unit for Lowering Mobility of Main Chain

The resin (A) preferably has, from the viewpoint of suppressing excessive diffusion of the generated acid or pattern collapse during development, a relatively high glass transition temperature (Tg). Tg is preferably more than 90° C., more preferably more than 100° C., still more preferably more than 110° C., and particularly preferably more than 125° C. Note that, from the viewpoint of having a high dissolution rate in developers, Tg is preferably 400° C. or less, and more preferably 350° C. or less.

Note that, in this Specification, the glass transition temperatures (Tg) of polymers such as the resin (A) (hereafter, “Tg's of repeating units”) are calculated in the following manner. First, for the repeating units included in a polymer, the Tg's of homopolymers composed only of the repeating units are individually calculated by the Bicerano method. Subsequently, the mass ratios (%) of the repeating units relative to all the repeating units in the polymer are calculated. Subsequently, the Fox equation (described in Materials Letters 62 (2008) 3152, for example) is used to calculate Tg's for the mass ratios and the Tg's are summed up to determine the Tg (° C.) of the polymer.

The Bicerano method is described in Prediction of polymer properties, Marcel Dekker Inc, New York (1993). The calculation of Tg by the Bicerano method can be performed using the software for estimating properties of polymers, MDL Polymer (MDL Information Systems, Inc.).

In order to increase the Tg of the resin (A) (preferably, making Tg be more than 90° C.), the mobility of the main chain of the resin (A) is preferably lowered. Examples of the method for lowering the mobility of the main chain of the resin (A) include the following methods (a) to (e):
(a) introduction of a bulky substituent to the main chain;
(b) introduction of a plurality of substituents to the main chain;
(c) introduction of a substituent that induces interaction between the resins (A), to the vicinity of the main chain;
(d) formation of the main chain using a ring structure; and
(e) linkage of a ring structure to the main chain.

Note that the resin (A) preferably has a repeating unit whose homopolymer has a Tg of 130° C. or more.

Note that the repeating unit species whose homopolymer has a Tg of 130° C. or more is not particularly limited and is a repeating unit whose homopolymer has a Tg of 130° C. or more calculated by the Bicerano method. Note that the repeating units represented by a formula (A) to a formula (E) described later may, depending on the functional group species, belong to the repeating unit whose homopolymer has a Tg of 130° C. or more.

An example of specific means for achieving (a) above is a method of introducing, into the resin (A), a repeating unit represented by a formula (A).

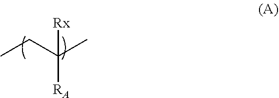

For the formula (A), R^{A} represents a group including a polycyclic structure. Rx represents a hydrogen atom, a methyl group, or an ethyl group. The group including a polycyclic structure is a group including a plurality of cyclic structures; the plurality of cyclic structures may be fused together or may not be fused together.

Specific examples of the repeating unit represented by the formula (A) include those described in Paragraphs to of WO2018/193954A .

An example of specific means for achieving (b) above is a method of introducing, into the resin (A), a repeating unit represented by a formula (B).

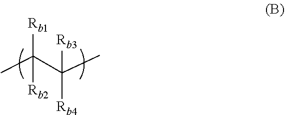

In the formula (B), R_{b1} to R_{b4} each independently represent a hydrogen atom or an organic group; at least two or more of R_{b1} to R_{b4} represent organic groups.

When at least one of the organic groups is a group whose cyclic structure is directly linked to the main chain in the repeating unit, the other organic group species is not particularly limited.

When none of the organic groups is a group whose cyclic structure is directly linked to the main chain in the repeating unit, at least two or more of the organic groups are substituents having three or more constituent atoms (except for hydrogen atoms).

Specific examples of the repeating unit represented by the formula (B) include those described in Paragraphs to of WO2018/193954A .

An example of specific means for achieving (c) above is a method of introducing, into the resin (A), a repeating unit represented by a formula (C).

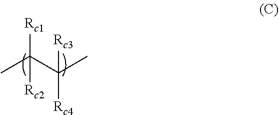

In the formula (C), R_{c1} to R_{c4} each independently represent a hydrogen atom or an organic group; at least one of R_{c1} to R_{c4} is a group including a hydrogen-bond-forming hydrogen atom positioned within three atoms from the carbon atom in the main chain. In particular, from the viewpoint of inducing the interaction between the main chains of the resin (A), it preferably has a hydrogen-bond-forming hydrogen atom positioned within two atoms (closer to the main chain side).

Specific examples of the repeating unit represented by the formula (C) include those described in Paragraphs to of WO2018/193954A .

An example of specific means for achieving (d) above is a method of introducing, into the resin (A), a repeating unit represented by a formula (D).

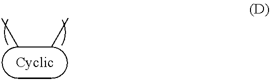

In the formula (D), “Cyclic” represents a group in which the ring structure forms the main chain. The number of atoms constituting the ring is not particularly limited.

Specific examples of the repeating unit represented by the formula (D) include those described in Paragraphs to of WO2018/193954A .

An example of specific means for achieving (e) above is a method of introducing, into the resin (A), a repeating unit represented by a formula (E).

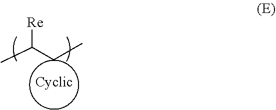

In the formula (E), Re each independently represent a hydrogen atom or an organic group. Examples of the organic group include alkyl groups, cycloalkyl groups, aryl groups, aralkyl groups, and alkenyl groups that may have substituents.

“Cyclic” is a cyclic group including a carbon atom of the main chain. The number of atoms included in the cyclic group is not particularly limited.

Specific examples of the repeating unit represented by the formula (E) include those described in Paragraphs to of WO2018/193954A .

Repeating unit having at least one group species selected from the group consisting of lactone group, sultone group, carbonate group, hydroxy group, cyano group, and alkali-soluble group

The resin (A) may have a repeating unit having at least one group species selected from the group consisting of a lactone group, a sultone group, a carbonate group, a hydroxy group, a cyano group, and an alkali-soluble group.

In the resin (A), the repeating unit having a lactone group, a sultone group, or a carbonate group may be the repeating unit having been described above in <Repeating unit having lactone group, sultone group, or carbonate group>. Preferred contents are also the same as those having been described above in <Repeating unit having lactone group, sultone group, or carbonate group>.

The resin (A) may have a repeating unit having a hydroxy group or a cyano group. This results in improvement in adhesiveness to the substrate and affinity for the developer.

The repeating unit having a hydroxy group or a cyano group is preferably a repeating unit having an alicyclic hydrocarbon structure substituted with a hydroxy group or a cyano group.

The repeating unit having a hydroxy group or a cyano group preferably does not have an acid-decomposable group. Examples of the repeating unit having a hydroxy group or a cyano

group include those described in Paragraphs to of JP2014-098921A .

The resin (A) may have a repeating unit having an alkali-soluble group.

The alkali-soluble group may be a carboxyl group, a sulfonamide group, a sulfonylimide group, a bissulfonylimide group, or an aliphatic alcohol group substituted, at the a position, with an electron-withdrawing group (for example, a hexafluoroisopropanol group), and is preferably a carboxyl group. When the resin (A) includes the repeating unit having an alkali-soluble group, increased resolution is provided in the contact hole application. Examples of the repeating unit

having an alkali-soluble group include those described in Paragraphs and of JP2014-098921A .

### Repeating Unit Having Alicyclic Hydrocarbon Structure and not Exhibiting Acid-Decomposability

The resin (A) may have a repeating unit having an alicyclic hydrocarbon structure and not exhibiting acid-decomposability. This results in, during liquid immersion exposure, a reduction in leaching of, from the resist film to the immersion liquid, low-molecular-weight components. Examples of the repeating unit having an alicyclic hydrocarbon structure and not exhibiting acid-decomposability include a repeating unit derived from 1-adamantyl (meth)acrylate, diamantyl (meth)acrylate, tricyclodecanyl (meth)acrylate, or cyclohexyl (meth)acrylate.

### Repeating Unit not Having Hydroxy Group or Cyano Group and Represented by Formula (III)

The resin (A) may have a repeating unit not having a hydroxy group or a cyano group and represented by a formula (III).

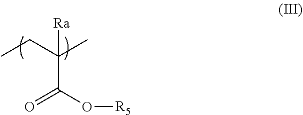

In the formula (III), R₅ represents a hydrocarbon group having at least one ring structure and not having a hydroxy group or a cyano group.

Ra represents a hydrogen atom, an alkyl group, or a —CH₂—O—Ra₂ group. In the formula, R^{a2} represents a hydrogen atom, an alkyl group, or an acyl group.

Examples of the repeating unit not having a hydroxy group or a cyano group and represented by the formula (III) include those described in Paragraphs to of JP2014-098921A .

The resin (A) can be synthesized by standard procedures (for example, radical polymerization).

The resin (A) has a weight-average molecular weight (Mw) of, as a polystyrene-equivalent value determined by the GPC method, preferably 30000 or less, more preferably 1000 to 30000, still more preferably 3000 to 30000, and particularly preferably 5000 to 15000.

The resin (A) has a dispersity (molecular weight distribution, Mw/Mn) of preferably 1 to 5, more preferably 1 to 3, still more preferably 1.2 to 3.0, and particularly preferably 1.2 to 2.0. As the dispersity lowers, the resolution becomes higher, the resist profile becomes better, the sidewalls of the resist pattern become smoother, and the roughness performance becomes higher.

The content of the resin (A) in the composition of the present invention relative to the total solid content of the composition of the present invention is preferably 0 to 20 mass %, more preferably 0 to 10 mass %, and still more preferably 0 mass % (the composition of the present invention still more preferably does not contain the resin (A)).

Such resins (A) may be used alone or may be used in combination of two or more thereof. When two or more thereof are used, the total content thereof is preferably within such a preferred content range.

Compound (B) that Generates Acid Upon Irradiation with Actinic Ray or Radiation

The composition of the present invention may include a compound (B) that generates an acid upon irradiation with an actinic ray or a radiation and that is different from the resin (X).

The compound (B) is a compound not having the above-described repeating unit (u1).

The compound (B) preferably has the form of a low-molecular-weight compound.

The compound (B) preferably has a molecular weight of 5000 or less, more preferably 4000 or less, and still more preferably 3000 or less. The lower limit of the molecular weight of the compound (B) is not particularly limited, but is preferably 100 or more.

The compound (B) may be, for example, a compound represented by “M⁺X-” (onium salt) and is preferably a compound that generates an organic acid upon exposure.

Examples of the organic acid include sulfonic acids (such as aliphatic sulfonic acids, aromatic sulfonic acids, and camphorsulfonic acid), carboxylic acids (such as aliphatic carboxylic acids, aromatic carboxylic acids, and aralkyl carboxylic acids), carbonylsulfonylimidic acid, bis(alkylsulfonyl) imidic acids, and tris(alkylsulfonyl) methide acids.

In the compound represented by “M⁺X⁻”, M⁺represents a cation, and preferably represents an organic cation.

Specific examples and preferred ranges of M⁺ are the same as the specific examples and preferred ranges described above for the cation included in the repeating unit (u1).

In the compound represented by “M⁺X⁻”, X-represents an anion, and preferably represents an organic anion.

The organic anion is not particularly limited, but may be a mono-, di-, or higher valent organic anion.

The organic anion is preferably an anion that has a very low capability of causing a nucleophilic reaction, and more preferably a non-nucleophilic anion.

Examples of the non-nucleophilic anion include sulfonate anions (such as aliphatic sulfonate anions, aromatic sulfonate anions, and a camphorsulfonate anion), carboxylate anions (such as aliphatic carboxylate anions, aromatic carboxylate anions, and aralkyl carboxylate anions), a sulfonylimide anion, bis(alkylsulfonyl)imide anions, and tris(alkylsulfonyl) methide anions.

In such an aliphatic sulfonate anion or aliphatic carboxylate anion, the aliphatic moiety may be a linear or branched alkyl group or may be a cycloalkyl group, and is preferably a linear or branched alkyl group having 1 to 30 carbon atoms, or a cycloalkyl group having 3 to 30 carbon atoms.

The alkyl group may be, for example, a fluoroalkyl group (that may have a substituent other than a fluorine atom, or may be a perfluoroalkyl group).

In such an aromatic sulfonate anion or aromatic carboxylate anion, the aryl group is preferably an aryl group having 6 to 14 carbon atoms, and may be, for example, a phenyl group, a tolyl group, or a naphthyl group.

The above-described alkyl group, cycloalkyl group, and aryl group may have a substituent. The substituent is not particularly limited; examples include a nitro group, halogen atoms such as a fluorine atom and a chlorine atom, a carboxyl group, a hydroxyl group, an amino group, a cyano group, alkoxy groups (preferably having 1 to 15 carbon atoms), alkyl groups (preferably having 1 to 10 carbon atoms), cycloalkyl groups (preferably having 3 to 15 carbon atoms), aryl groups (preferably having 6 to 14 carbon atoms), alkoxycarbonyl groups (preferably having 2 to 7 carbon atoms), acyl groups (preferably having 2 to 12 carbon atoms), alkoxycarbonyloxy groups (preferably having 2 to 7 carbon atoms), alkylthio groups (preferably having 1 to 15 carbon atoms), alkylsulfonyl groups (preferably having 1 to 15 carbon atoms), alkyliminosulfonyl groups (preferably having 1 to 15 carbon atoms), and aryloxysulfonyl groups (preferably having 6 to 20 carbon atoms).

In such an aralkyl carboxylate anion, the aralkyl group is preferably an aralkyl group having 7 to 14 carbon atoms.

Examples of the aralkyl group having 7 to 14 carbon atoms include a benzyl group, a phenethyl group, a naphthylmethyl group, a naphthylethyl group, and a naphthylbutyl group. The sulfonylimide anion may be, for example, a saccharin anion.

In such a bis(alkylsulfonyl)imide anion or tris(alkylsulfonyl) methide anion, the alkyl groups are preferably an alkyl group having 1 to 5 carbon atoms. A substituent of such an alkyl group may be a halogen atom, an alkyl group substituted with a halogen atom, an alkoxy group, an alkylthio group, an alkyloxysulfonyl group, an aryloxysulfonyl group, or a cycloalkylaryloxysulfonyl group, and is preferably a fluorine atom or an alkyl group substituted with a fluorine atom.

In the bis(alkylsulfonyl)imide anion, the alkyl groups may be bonded together to form a ring structure. This results in an increase in the acid strength.

Other examples of the non-nucleophilic anion include phosphorus fluoride (for example, PF6), boron fluoride (for example, BF4), and antimony fluoride (for example, SbF6).

The non-nucleophilic anion is also preferably an anion represented by the following formula (AN1).

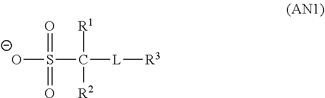

In the formula (AN1), R¹ and R² each independently represent a hydrogen atom or a substituent.

The substituent is not particularly limited, but is preferably a group that is not electron-withdrawing groups. Examples of the group that is not electron-withdrawing groups include hydrocarbon groups, a hydroxy group, oxyhydrocarbon groups, oxycarbonylhydrocarbon groups, an amino group, hydrocarbon-substituted amino groups, and hydrocarbon-substituted amide groups.

Such groups that are not electron-withdrawing groups are each independently preferably —R′, —OH, —OR′, —OCOR′, —NH₂, —NR′₂, —NHR′, or —NHCOR′. R′ are monovalent hydrocarbon groups.

Examples of the above-described monovalent hydrocarbon groups represented by R′ include monovalent linear or branched hydrocarbon groups such as alkyl groups such as a methyl group, an ethyl group, a propyl group, and a butyl group; alkenyl groups such as an ethenyl group, a propenyl group, and a butenyl group; and alkynyl groups such as an ethynyl group, a propynyl group, and a butynyl group; monovalent alicyclic hydrocarbon groups such as cycloalkyl groups such as a cyclopropyl group, a cyclobutyl group, a cyclopentyl group, a cyclohexyl group, a norbornyl group, and an adamantyl group; and cycloalkenyl groups such as a cyclopropenyl group, a cyclobutenyl group, a cyclopentenyl group, and a norbornenyl group; and monovalent aromatic hydrocarbon groups such as aryl groups such as a phenyl group, a tolyl group, a xylyl group, a mesityl group, a naphthyl group, a methylnaphthyl group, an anthryl group, and methylanthryl group; and aralkyl groups such as a benzyl group, a phenethyl group, a phenylpropyl group, a naphthylmethyl group, and an anthrylmethyl group.

In particular, R¹ and R² are each independently preferably a hydrocarbon group (preferably a cycloalkyl group) or a hydrogen atom.

L represents a divalent linking group.

When a plurality of L's are present, L's may be the same or different.

The divalent linking group may be, for example, —O—CO—O—, —COO—, —CONH—, —CO—, —O—, —S—, —SO—, —SO₂—, an alkylene group (preferably having 1 to 6 carbon atoms), a cycloalkylene group (preferably having 3 to 15 carbon atoms), an alkenylene group (preferably having 2 to 6 carbon atoms), or a divalent linking group that is a combination of a plurality of the foregoing. In particular, the divalent linking group is preferably —O—CO—O—, —COO—, —CONH—, —CO—, —O—, —SO₂—, —O—CO—O-alkylene group-, —COO-alkylene group-, or —CONH-alkylene group-, and more preferably —O—CO—O—, —O—CO—O-alkylene group-, —COO—, —CONH—, —SO₂—, or —COO-alkylene group-.

L is preferably, for example, a group represented by the following formula (AN1-1).

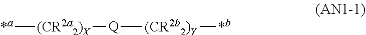

In the formula (AN1-1), *a represents a bonding site to R³ in the formula (AN1).

*b represents a bonding site to —C(R¹) (R²)— in the formula (AN1).

X and Y each independently represent an integer of 0 to 10, and is preferably an integer of 0 to 3.

R^{2a} and R^{2b} each independently represent a hydrogen atom or a substituent.

When a plurality of R^{2a}'s and a plurality of R^{2b}'s are present, the plurality of R^{2a}'s and the plurality of R^{2b}'s present may be individually the same or different.

Note that, when Y is 1 or more, in the formula (AN1), in CR262 directly bonded to —C (R¹) (R²)—, R^{2b}'s are not fluorine atoms.

Q represents *^{A}—O—CO—O—*^{B}*^{A}—CO—*^{B}*^{A}—CO—O—* ^{B}*^{A}—O—CO—*^{B}*^{A}—O—*^{B}*^{A}—S—* ^{B}or *^{A}—SO₂—* ^{B}.

Note that, when X+Y in the formula (AN1-1) is 1 or more, and R^{2a}'s and R^{2b}'s in the formula (AN1-1) are all hydrogen atoms, Q represents *^{A}—O—CO—O—*^{B}, *^{A}—CO—*^{B}*^{A}O—CO—* ^{B}, *^{A}—O—*^{B}, *^{A}—S—*^{B}, or *^{A}—SO₂—*^{B}.

*^{A} represent a bonding site on the R³ side in the formula (AN1) and *B represent a bonding site on the —SO₃ side in the formula (AN1).

In the formula (AN1), R³ represents an organic group.

The organic group is not particularly limited as long as it has 1 or more carbon atoms, and may be a linear group (for example, a linear alkyl group) or a branched group (for example, a branched alkyl group such as a t-butyl group), or may be a cyclic group. The organic group may have or may not have a substituent. The organic group may have or may not have a heteroatom (such as an oxygen atom, a sulfur atom, and/or a nitrogen atom).

In particular, R³ is preferably an organic group having a ring structure. The ring structure may be monocyclic or polycyclic, and may have a substituent. In the organic group including a ring structure, the ring is preferably directly bonded to L in the formula (AN1).

The organic group having a ring structure, for example, may have or may not have a heteroatom (such as an oxygen atom, a sulfur atom, and/or a nitrogen atom). The heteroatom may substitute one or more carbon atoms forming the ring structure.

The organic group having a ring structure is preferably, for example, a hydrocarbon group having a ring structure, a lactone ring group, or a sultone ring group. In particular, the organic group having a ring structure is preferably a hydrocarbon group having a ring structure.

The hydrocarbon group having a ring structure is preferably a monocyclic or polycyclic cycloalkyl group. Such groups may have a substituent.

The cycloalkyl group may be monocyclic (such as a cyclohexyl group) or polycyclic (such as an adamantyl group), and preferably has 5 to 12 carbon atoms.

The lactone group and the sultone group are, for example, preferably a group provided by removing, in any one of the above-described structures represented by the formulas (LC1-1) to (LC1-21) and the above-described structures represented by the formulas (SL1-1) to (SL1-3), a single hydrogen atom from a ring-member atom constituting the lactone structure or the sultone structure.

The non-nucleophilic anion may be a benzenesulfonate anion, and is preferably a benzenesulfonate anion substituted with a branched alkyl group or a cycloalkyl group.

The non-nucleophilic anion is also preferably an anion represented by the following formula (AN2).

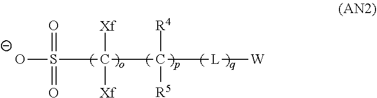

In the formula (AN2), o represents an integer of 1 to 3. p represents an integer of 0 to 10. q represents an integer of 0 to 10.

Xf's represent a hydrogen atom, a fluorine atom, an alkyl group substituted with at least one fluorine atom, or an organic group not having fluorine atoms. The alkyl group preferably has 1 to 10 carbon atoms, and more preferably 1 to 4 carbon atoms. The alkyl group substituted with at least one fluorine atom is preferably a perfluoroalkyl group.

Xf's are preferably a fluorine atom or a perfluoroalkyl group having 1 to 4 carbon atoms, and more preferably a fluorine atom or CF3; still more preferably, both of Xf's are fluorine atoms.

R⁴ and R⁵ each independently represent a hydrogen atom, a fluorine atom, an alkyl group, or an alkyl group substituted with at least one fluorine atom. When a plurality of R⁴'s and a plurality of R⁵'s are present, R⁴'s and R⁵'s may be individually the same or different.

For R⁴ and R⁵, the alkyl group preferably has 1 to 4 carbon atoms. The alkyl group may have a substituent. R⁴ and R⁵ are preferably a hydrogen atom.

L represents a divalent linking group. L has the same definition as L in the formula (AN1).

W represents an organic group including a ring structure. In particular, preferred is a cyclic organic group.

The cyclic organic group may be, for example, an alicyclic group, an aryl group, or a heterocyclic group.

The alicyclic group may be monocyclic or may be polycyclic. Examples of the monocyclic alicyclic group include monocyclic cycloalkyl groups such as a cyclopentyl group, a cyclohexyl group, and a cyclooctyl group. Examples of the polycyclic alicyclic group include polycyclic cycloalkyl groups such as a norbornyl group, a tricyclodecanyl group, a tetracyclodecanyl group, a tetracyclododecanyl group, and an adamantyl group. In particular, preferred are alicyclic groups having a bulky structure having 7 or more carbon atoms such as a norbornyl group, a tricyclodecanyl group, a tetracyclodecanyl group, a tetracyclododecanyl group, and an adamantyl group.

The aryl group may be monocyclic or polycyclic. Examples of the aryl group include a phenyl group, a naphthyl group, a phenanthryl group, and an anthryl group.

The heterocyclic group may be monocyclic or polycyclic. In particular, in the case of a polycyclic heterocyclic group, diffusion of acid can be further suppressed. The heterocyclic group may have aromaticity or may not have aromaticity. Examples of the heterocycle having aromaticity include a furan ring, a thiophene ring, a benzofuran ring, a benzothiophene ring, a dibenzofuran ring, a dibenzothiophene ring, and a pyridine ring. Examples of the heterocycle not having aromaticity include a tetrahydropyran ring, a lactone ring, a sultone ring, and a decahydroisoquinoline ring. In the heterocyclic group, the heterocycle is preferably a furan ring, a thiophene ring, a pyridine ring, or a decahydroisoquinoline ring.

The cyclic organic group may have a substituent. The substituent may be, for example, an alkyl group (that may be either linear or branched and preferably has 1 to 12 carbon atoms), a cycloalkyl group (that may have either a monocycle, a polycycle, or a spiro ring, and preferably has 3 to 20 carbon atoms), an aryl group (preferably having 6 to 14 carbon atoms), a hydroxy group, an alkoxy group, an ester group, an amide group, a urethane group, a ureido group, a thioether group, a sulfonamide group, or a sulfonic acid ester group. Note that a carbon constituting the cyclic organic group (carbon contributing to formation of the ring) may be a carbonyl carbon.

The anion represented by the formula (AN2) is preferably SO₃—CF₂—CH₂—OCO— (L)_{q}′-W, SO₃—CF₂—CHF—CH₂—OCO—(L)_{q}′-W, SO₃—CF₂—COO-(L)_{q}′-W, SO₃—CF₂—CF₂—CH₂—CH₂-(L)_{q}-W, or SO₃—CF₂—CH(CF₃)—OCO—(L)_{q}′-W. Here, L, q, and W are the same as those in the formula (AN2). q′ represent an integer of 0 to 10.

The non-nucleophilic anion is also preferably an aromatic sulfonate anion represented by the following formula (AN3).

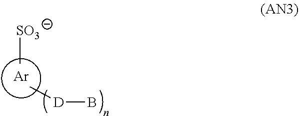

In the formula (AN3), Ar represents an aryl group (such as a phenyl group), and may further have a substituent other than the sulfonate anion and the (D-B) group. Examples of the substituent that Ar may further have include a fluorine atom and a hydroxy group.

n represents an integer of 0 or more. n is preferably 1 to 4, more preferably 2 to 3, and still more preferably 3.

D represents a single bond or a divalent linking group. The divalent linking group may be an ether group, a thioether group, a carbonyl group, a sulfoxide group, a sulfo group, a sulfonic acid ester group, an ester group, or a group that is a combination of two or more of the foregoing.

B represents a hydrocarbon group.

B is preferably an aliphatic hydrocarbon group, and more preferably an isopropyl group, a cyclohexyl group, or an aryl group that may further have a substituent (such as a tricyclohexylphenyl group).

The non-nucleophilic anion is also preferably a disulfonamide anion.

The disulfonamide anion is, for example, an anion represented by N—(SO₂-R⁹) 2.

Ra's represent an alkyl group that may have a substituent, are preferably a fluoroalkyl group, and more preferably a perfluoroalkyl group. Two R″'s may be bonded together to form a ring. The group formed by bonding together two Ra's is preferably an alkylene group that may have a substituent, more preferably a fluoroalkylene group, and still more preferably a perfluoroalkylene group. The alkylene group preferably has 2 to 4 carbon atoms.

The compound (B) is also preferably at least one selected from the group consisting of compounds (I) to (II).

### Compound (I)

The compound (I) is a compound having one or more structural moieties X described below and one or more structural moieties Y described below, and is a compound that generates, upon irradiation with an actinic ray or a radiation, an acid including a first acidic moiety described below derived from the structural moiety X described below and a second acidic moiety described below derived from the structural moiety Y described below.

Structural moiety X: a structural moiety that is constituted by an anionic moiety A₁ and a cationic moiety M₁⁺ and that forms, upon irradiation with an actinic ray or a radiation, the first acidic moiety represented by HA₁

Structural moiety Y: a structural moiety that is constituted by an anionic moiety A2 and a cationic moiety M₂⁺ and that forms, upon irradiation with an actinic ray or a radiation, the second acidic moiety represented by HA₂

The compound (I) satisfies the following condition I.

Condition I: a compound PI in which the cationic moiety M₁⁺in the structural moiety X and the cationic moiety M₂⁺in the structural moiety Y in the compound (I) are replaced by H⁺has an acid dissociation constant a1 derived from an acidic moiety represented by HA₁ in which the cationic moiety M₁⁺ in the structural moiety X is replaced by H⁺, and an acid dissociation constant a2 derived from an acidic moiety represented by HA₂ in which the cationic moiety M₂+in the structural moiety Y is replaced by H⁺, and the acid dissociation constant a2 is larger than the acid dissociation constant a1.

Hereinafter, the condition I will be more specifically described.

When the compound (I) is, for example, a compound that generates an acid having one first acidic moiety derived from the structural moiety X and one second acidic moiety derived from the structural moiety Y, the compound PI corresponds to a “compound having HA₁ and HA₂”.

The acid dissociation constant a1 and the acid dissociation constant a2 of the compound PI will be more specifically described as follows: in determination of the acid dissociation constants of the compound PI, the pKa at the time when the compound PI turns into a “compound having A1 and HA₂” is the acid dissociation constant a1, and the pKa at the time when the “compound having A1 and HA₂” turns into a “compound having Aj and A2” is the acid dissociation constant a2.

When the compound (I) is, for example, a compound that generates an acid having two first acidic moieties derived from the structural moieties X and one second acidic moiety derived from the structural moiety Y, the compound PI corresponds to a “compound having two HA₁ and one HA₂”.

In determination of the acid dissociation constants of the compound PI, the acid dissociation constant at the time when the compound PI turns into a “compound having one A₁”, one HA₁, and one HA₂″ and the acid dissociation constant at the time when the “compound having one A1”, one HA₁, and one HA₂″ turns into a “compound having two A₁ and one HA₂” correspond to the above-described acid dissociation constant a1. The acid dissociation constant at the time when the “compound having two A₁ and one HA₂” turns into a “compound having two A₁ and A₂” corresponds to the acid dissociation constant a2. In other words, when the compound PI has a plurality of acid dissociation constants derived from the acidic moieties represented by HA₁ in which the cationic moiety M₁⁺in the structural moiety X is replaced by H+, the value of the acid dissociation constant a2 is larger than the largest value among the plurality of the acid dissociation constants a1. Note that, in a case where the acid dissociation constant at the time when the compound PI turns into the “compound having one A₁”, one HA₁, and one HA₂″ is defined as aa, and the acid dissociation constant at the time when the “compound having one A₁”, one HA₁, and one HA₂″ turns into the “compound having two A₁-and one HA₂” is defined as ab, the relationship between aa and ab satisfies aa<ab.

The acid dissociation constant a1 and the acid dissociation constant a2 can be determined by the above-described method of measuring an acid dissociation constant.

The compound PI corresponds to an acid generated upon irradiation of the compound (I) with an actinic ray or a radiation.

When the compound (I) has two or more structural moieties X, the structural moieties X may be the same or different. The two or more A₁ and the two or more M₁⁺ may be individually the same or different.

In the compound (I), the A₁ and the A₂″, and the M₁⁺ and the M₂⁺ may be individually the same or different, but the A₁ and the A₂ are preferably different from each other.

In the compound PI, the difference (absolute value) between the acid dissociation constant a1 (when a plurality of acid dissociation constants a1 are present, the largest value thereof) and the acid dissociation constant a2 is preferably 0.1 or more, more preferably 0.5 or more, and still more preferably 1.0 or more. Note that the upper limit value of the difference (absolute value) between the acid dissociation constant a1 (when a plurality of acid dissociation constants a1 are present, the largest value thereof) and the acid dissociation constant a2 is not particularly limited, but is, for example, 16 or less.

In the compound PI, the acid dissociation constant a2 is preferably 20 or less, and more preferably 15 or less. Note that the lower limit value of the acid dissociation constant a2 is preferably-4.0 or more.

In the compound PI, the acid dissociation constant a1 is preferably 2.0 or less, and more preferably 0 or less. Note that the lower limit value of the acid dissociation constant a1 is preferably-20.0 or more.

The anionic moiety A₁ and the anionic moiety A₂ are structural moieties including a negatively charged atom or atomic group and may be, for example, structural moieties selected from the group consisting of formulas (AA-1) to (AA-3) and formulas (BB-1) to (BB-6) below.

The anionic moiety A₁ is preferably an anionic moiety that can form an acidic moiety having a small acid dissociation constant, in particular, more preferably any one of the formulas (AA-1) to (AA-3), and still more preferably any one of the formulas (AA-1) and (AA-3).

The anionic moiety A₂ is preferably an anionic moiety that can form an acidic moiety having a larger acid dissociation constant than the anionic moiety A₁″, more preferably any one of the formulas (BB-1) to (BB-6), and still more preferably any one of the formulas (BB-1) and (BB-4).

Note that, in the formulas (AA-1) to (AA-3) and the formulas (BB-1) to (BB-6) below, * represent a bonding site.

In the formula (AA-2), R^{A} represent a monovalent organic group. The monovalent organic groups represented by R^{A} are not particularly limited, but may be, for example, a cyano group, a trifluoromethyl group, or a methanesulfonyl group.

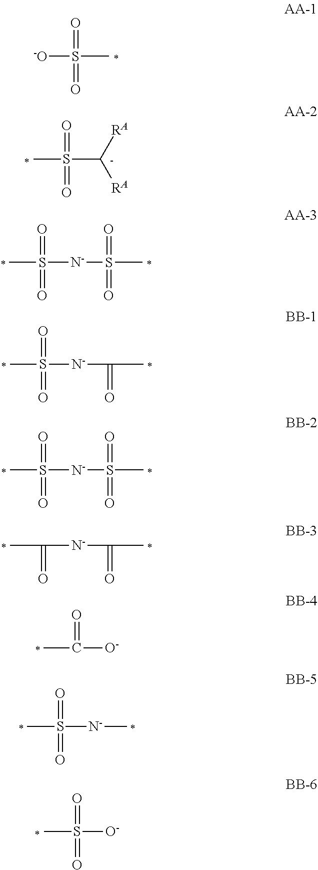

The cationic moiety M₁⁺ and the cationic moiety M₂⁺ are structural moieties including a positively charged atom or atomic group and may be, for example, singly charged organic cations. Note that such an organic cation may be, for example, the above-described organic cation represented by M⁺.

### Compound (II)

The compound (II) is a compound having two or more structural moieties X above and one or more structural moieties Z below, and is a compound that generates, upon irradiation with an actinic ray or a radiation, an acid including two or more first acidic moieties derived from the structural moieties X and the structural moiety Z.

Structural moiety Z: a nonionic moiety that can neutralize acid

In the compound (II), the definition of the structural moiety X and the definitions of A₁ and M₁⁺ are the same as the definition of the structural moiety X and the definitions of A₁-and M₁⁺in the above-described compound (I), and preferred examples are also the same.

For a compound PII in which the cationic moiety M₁⁺in the structural moiety X in the compound (II) is replaced by H+, the preferred range of the acid dissociation constant a1 derived from the acidic moiety represented by HA₁ in which the cationic moiety M₁⁺in the structural moiety X is replaced by H+is the same as in the acid dissociation constant a1 in the compound PI.

Note that, when the compound (II) is, for example, a compound that generates an acid having two first acidic moieties derived from the structural moiety X and the structural moiety Z, the compound PII corresponds to a “compound having two HA₁”. In determination of the acid dissociation constants of this compound PII, the acid dissociation constant at the time when the compound PII turns into a “compound having one A” and one HA₁″ and the acid dissociation constant at the time when the “compound having one A₁ and one HA₁” turns into a “compound having two A₁” correspond to the acid dissociation constant a1.

The acid dissociation constant a1 can be determined by the above-described method of measuring an acid dissociation constant.

The compound PII corresponds to an acid generated upon irradiation of the compound (II) with an actinic ray or a radiation.

Note that the two or more structural moieties X may be the same or different. The two or more A₁ and the two or more M₁⁺ may be individually the same or different.

The nonionic moiety that can neutralize acid in the structural moiety Z is not particularly limited, and is preferably, for example, a moiety including a group that can electrostatically interact with a proton or a functional group having an electron.

Examples of the group that can electrostatically interact with a proton or the functional group having an electron include a functional group having a macrocyclic structure such as cyclic polyether, and a functional group having a nitrogen atom having an unshared electron pair that does not contribute to x-conjugation. Examples of the nitrogen atom having an unshared electron pair that does not contribute to x-conjugation include nitrogen atoms having partial structures represented by the following formulas.

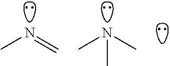

### Unshared Electron Pair

The partial structure of the group that can electrostatically interact with a proton or the functional group having an electron may be, for example, a crown ether structure, an azacrown ether structure, a primary to tertiary amine structure, a pyridine structure, an imidazole structure, or a pyrazine structure; in particular, preferred are primary to tertiary amine structures.

Examples of the non-cationic moieties that the compound (I) and the compound (II) can have are as follows.

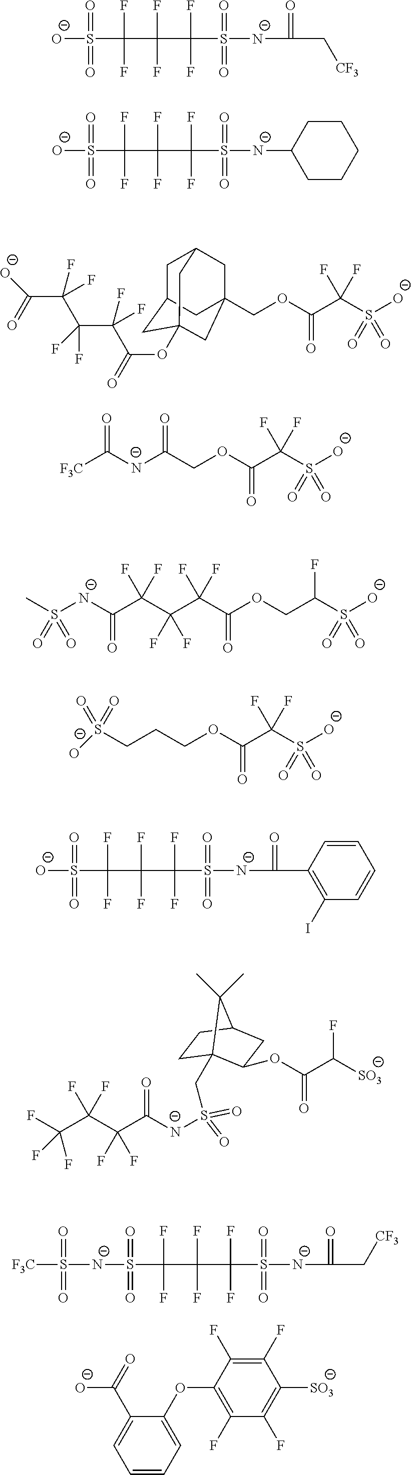

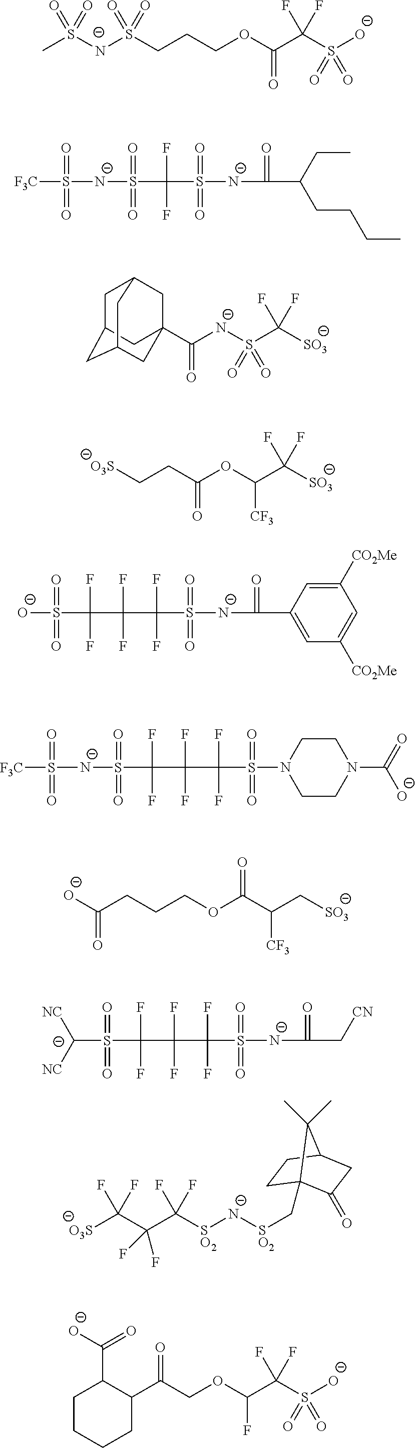

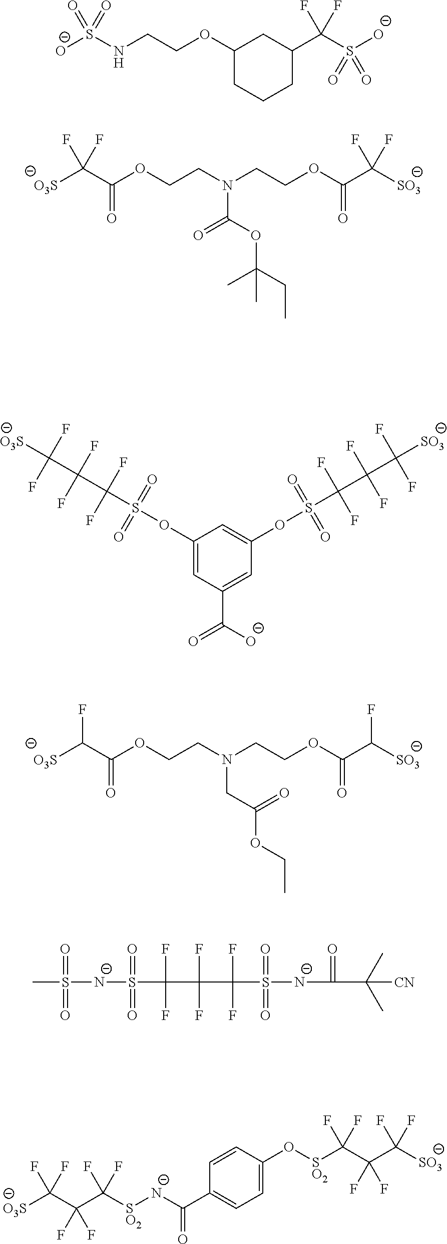

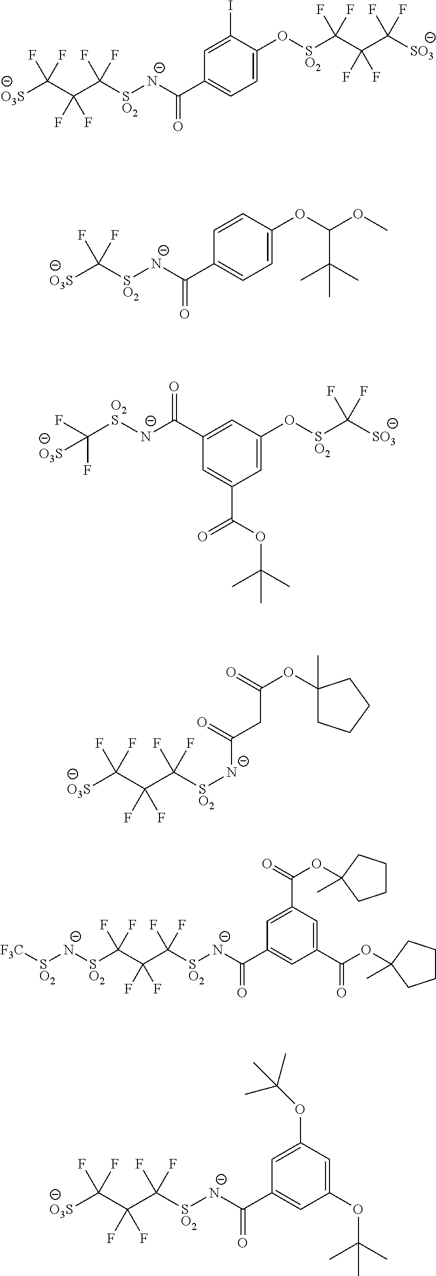

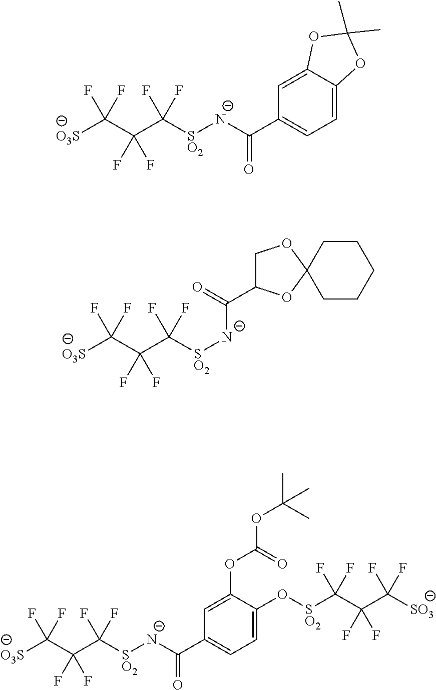

Specific examples of the compound (B) include, for example, the compounds described in to of WO2022/172715A . The above descriptions are incorporated herein.

The content of the compound (B) in the composition of the present invention relative to the total solid content of the composition of the present invention is preferably 0 to 20 mass %, more preferably 0 to 10 mass %, and still more preferably 0 mass % (the composition of the present invention still more preferably does not contain the compound (B)).

Such compounds (B) may be used alone or in combination of two or more thereof. When two or more thereof are used, the total content thereof is preferably within such a preferred content range.

### Acid Diffusion Control Agent

The composition of the present invention may include an acid diffusion control agent.

The type of the acid diffusion control agent is not particularly limited, and examples thereof include a basic compound (DA), a low-molecular-weight compound (DB) having a nitrogen atom and having a group that leaves by the action of an acid, and a compound (DC) whose acid diffusion control ability is reduced or lost upon irradiation with an actinic ray or a radiation.

Examples of the compound (DC) include an onium salt compound (DD) that becomes a weak acid relative to the photoacid generator, and a basic compound (DE) whose basicity is reduced or lost upon irradiation with an actinic ray or a radiation.

Specific examples of the basic compound (DA) include, for example, those described in Paragraphs to of WO2020/066824A ; specific examples of the basic compound (DE) whose basicity is reduced or lost upon irradiation with an actinic ray or a radiation include

those described in Paragraphs to of WO2020/066824A , and those described in Paragraph of WO2020/066824A ; and, specific examples of the low-molecular-weight compound (DB) having a nitrogen atom and having a group that leaves by the action of an acid include those described in Paragraphs to of WO2020/066824A .

Specific examples of the onium salt compound (DD) that becomes a weak acid relative to the photoacid generator include, for example, those described in Paragraphs to of WO2020/158337A .

In addition to those described above, for example, the publicly known compounds disclosed in Paragraphs to in US2016/0070167A , Paragraphs to in

US2015/0004544A , Paragraphs to in US2016/0237190A , and Paragraphs to in US2016/0274458A can be suitably used as acid diffusion control agents.

The composition of the present invention may or may not contain an acid diffusion control agent. The content of the acid diffusion control agent in the composition of the present invention is not particularly limited, and may be, for example, relative to the total solid content of the composition of the present invention, 0 to 50 mass %, 0 to 40 mass %, or 0 to 30 mass %. Hydrophobic resin

The composition of the present invention may include a hydrophobic resin (also referred to as “hydrophobic resin (D)”) different from the resin (X) and the resin (A).

The hydrophobic resin (D) is preferably designed so as to be localized in the surface of the resist film, but unlike surfactants, the hydrophobic resin (D) does not necessarily have a hydrophilic group in the molecule, and does not necessarily contribute to homogeneous mixing of a polar substance and a nonpolar substance.

The effects of adding the hydrophobic resin (D) may be control of the static and dynamic contact angles of the resist film surface with respect to water, and suppression of outgassing.

From the viewpoint of localization in the film surface layer, the hydrophobic resin (D) preferably has any one or more of a fluorine atom, a silicon atom, and a CH₃ partial structure included in the side chain portion of the resin, and more preferably has two or more thereof. The hydrophobic resin preferably has a hydrocarbon group having 5 or more carbon atoms. The resin may have such a group in the main chain or, as a substituent, in a side chain.

Examples of the hydrophobic resin (D) include the compounds described in Paragraphs to of WO2020/004306A .

The content of the hydrophobic resin (D) in the composition of the present invention relative to the total solid content of the composition of the present invention is preferably 0 to 20 mass %, more preferably 0 to 10 mass %, and still more preferably 0 mass % (the composition of the present invention still more preferably does not contain the hydrophobic resin (D)).

Such hydrophobic resins (D) may be used alone or in combination of two or more thereof. When two or more thereof are used, the total content thereof is preferably within such a preferred content range.

### Surfactant

The composition of the present invention may include a surfactant. In the case of including a surfactant, a pattern having higher adhesiveness and a less number of development defects can be formed.

The surfactant is a compound different from the resin (X).

The surfactant is preferably a fluorine-based and/or silicone-based surfactant.

Examples of the fluorine-based and/or silicone-based surfactant include the surfactants disclosed in Paragraphs and of WO2018/193954A .

The surfactant content in the composition of the present invention relative to the total solid content of the composition of the present invention is preferably 0 to 5 mass %, more preferably 0 to 1 mass %, and still more preferably 0 mass % (the composition of the present invention still more preferably does not contain surfactants).

Such surfactants may be used alone or may be used in combination of two or more thereof. When two or more thereof are used, the total content thereof is preferably within such a preferred content range.

### Solvent

The composition of the present invention preferably includes a solvent.

The solvent preferably includes at least one of (M1) a propylene glycol monoalkyl ether carboxylate or (M2) at least one selected from the group consisting of a propylene glycol monoalkyl ether, a lactate, an acetate, an alkoxypropionate, a chain ketone, a cyclic ketone, a lactone, and an alkylene carbonate. Note that the solvent may further include a component other than the components (M1) and (M2).

A combination of the above-described solvent and the above-described resin is preferred from the viewpoint of improving the coatability of the composition of the present invention and reducing the number of pattern development defects. The above-described solvent is well-balanced in terms of solubility of the above-described resin, boiling point, and viscosity, to thereby suppress, for example, unevenness of the film thickness of the resist film and generation of deposit during spin-coating.

Details of the component (M1) and the component (M2) are described in Paragraphs to in WO2020/004306A , and these contents are incorporated herein.

When the solvent further includes a component other than the components (M1) and (M2), the content of the component other than the components (M1) and (M2) relative to the total amount of the solvent is preferably 5 to 30 mass %.

The content of the solvent in the composition of the present invention is set such that the solid-content concentration is preferably 0.5 to 30 mass %, and more preferably 1 to 20 mass %. This further improves the coatability of the composition of the present invention.

### Other Additives

The composition of the present invention may further include a dissolution-inhibiting compound, a dye, a plasticizer, a photosensitizer, a light absorbent, and/or a compound that promotes solubility in a developer (for example, a phenol compound having a molecular weight of 1000 or less, or an alicyclic or aliphatic compound including a carboxyl group).

The “dissolution-inhibiting compound” is a compound that is decomposed by the action of an acid to cause a decrease in the degree of solubility in organic-based developers, and has a molecular weight of 3000 or less.

The composition of the present invention preferably satisfies at least one of the following condition (i) or the following condition (ii), and more preferably satisfies the following condition (ii):
Condition (i): The composition of the present invention contains an acid diffusion control agent that is a compound different from the resin (X); and
Condition (ii): The resin (X) has a repeating unit having acid diffusion control ability.

The composition of the present invention is also suitably used as a photosensitive composition for EUV exposure.

The present invention also relates to an actinic ray-sensitive or radiation-sensitive resin composition including a resin (X) having a repeating unit (u1) and a solvent, wherein the repeating unit (u1) includes at least one cation and an anion that is bonded to a molecular chain of the resin (X), the cation undergoes a structural change by action of an acid, and a post-change structure has a larger peak area in an absorption spectrum for light having wavelengths of 300 nm to 450 nm than a peak area in an absorption spectrum of a pre-change structure for light having wavelengths of 300 nm to 450 nm, and
a content of the repeating unit (u1) relative to a total resin content in the actinic ray-sensitive or radiation-sensitive resin composition is 40 mass % or more.

The present invention also relates to an actinic ray-sensitive or radiation-sensitive resin composition including a resin (X) having a repeating unit (u1) and a solvent,
wherein the repeating unit (u1) includes at least one cation and an anion that is bonded to a molecular chain of the resin (X),
the cation undergoes a structural change by action of an acid to generate a ketone compound, and
a content of the repeating unit (u1) relative to a total resin content in the actinic ray-sensitive or radiation-sensitive resin composition is 40 mass % or more.

### Actinic Ray-Sensitive or Radiation-Sensitive Film and Pattern Forming Method

The present invention also relates to an actinic ray-sensitive or radiation-sensitive film formed from the composition of the present invention. The actinic ray-sensitive or radiation-sensitive film of the present invention is preferably a resist film.

The procedures of the pattern forming method using the composition of the present invention are not particularly limited, but preferably have the following steps:
Step 1: a step of using the composition of the present invention to form a resist film on a substrate;
Step 2: a step of irradiating the resist film with a first actinic ray or radiation;
Step 3: a step of irradiating, with a second actinic ray or radiation, the resist film after irradiation with the first actinic ray or radiation; and
Step 4: a step of using a developer to develop the resist film after irradiation with the second actinic ray or radiation.

Hereinafter, procedures of the steps will be individually described in detail.

Step 1: resist film formation step

The step 1 is a step of using the composition of the present invention to form a resist film on a substrate.

Examples of the method of using the composition of the present invention to form a resist film on a substrate include a method of applying the composition of the present invention onto a substrate.

Note that the composition of the present invention is preferably filtered through a filter before application as needed. The filter preferably has a pore size of 0.1 μm or less, more preferably 0.05 μm or less, and still more preferably 0.03 μm or less. The filter is preferably formed of polytetrafluoroethylene, polyethylene, or nylon.

The composition of the present invention can be applied onto a substrate (for example, formed of silicon or silicon dioxide-covered silicon) used in the production of integrated circuit elements by an appropriate application method using a spinner, a coater, or the like. The application process is preferably spin-coating using a spinner. The spin-coating using a spinner is preferably performed at a rotation rate of 1000 to 3000 rpm (rotations per minute).

After application of the composition of the present invention, the substrate may be dried to form a resist film. Note that, as needed, various underlayer films (such as an inorganic film, an organic film, and an antireflection film) may be formed under the resist film.

The drying process may be, for example, a process of performing heating to achieve drying. The heating can be performed using means included in an ordinary exposure device and/or an ordinary development device, or may alternatively be performed using a hot plate, for example. The heating temperature is preferably 80 to 150° C., more preferably 80 to 140° C., and still more preferably 80 to 130° C. The heating time is preferably 30 to 1000 seconds, more preferably 60 to 800 seconds, and still more preferably 60 to 600 seconds.

The film thickness of the resist film is not particularly limited, but is, from the viewpoint of enabling formation of more precise fine patterns, preferably 10 to 120 nm. In particular, in the case of employing EUV exposure, the film thickness of the resist film is more preferably 10 to 65 nm, and still more preferably 15 to 50 nm. In the case of employing ArF liquid immersion exposure, the film thickness of the resist film is more preferably 10 to 120 nm, and still more preferably 15 to 90 nm.

Note that, for an overlying layer of the resist film, a topcoat composition may be used to form a topcoat.

The topcoat composition preferably does not mix with the resist film, and can be uniformly applied for an overlying layer of the resist film. The topcoat is not particularly limited; a publicly known topcoat can be formed by a publicly known process; for example, on the basis of descriptions of Paragraphs to in JP2014-059543A , a topcoat can be formed.

For example, a topcoat including a basic compound and described in JP2013-61648A is preferably formed on the resist film. Specific examples of the basic compound that can be included in the topcoat include basic compounds that may be included in the composition of the present invention.

The topcoat also preferably includes a compound including at least one group or bond selected from the group consisting of an ether bond, a thioether bond, a hydroxy group, a thiol group, a carbonyl bond, and an ester bond.

Step 2: first exposure step

The step 2 is a step of irradiating the resist film with the first actinic ray or radiation.

The exposure process may be a process of irradiating the formed resist film, through a predetermined mask, with an actinic ray or radiation.

The actinic ray or radiation (the first actinic ray or radiation) used in the step 2 may be infrared rays, visible light, ultraviolet rays, far ultraviolet rays, extreme ultraviolet rays, X-rays, or an electron beam.

The wavelength of the first actinic ray or radiation is preferably shorter than the wavelength of the second actinic ray or radiation.

The wavelength of the first actinic ray or radiation is preferably 250 nm or less, more preferably 220 nm or less, and still more preferably 1 to 200 nm. Specifically, the first actinic ray or radiation is preferably the KrF excimer laser (248 nm), the ArF excimer laser (193 nm), the F2 excimer laser (157 nm), EUV (13.5 nm), X-rays, or an electron beam, and more preferably an electron beam or extreme ultraviolet rays.

After the exposure, before development, baking (heating) is preferably performed. The baking accelerates the reaction in the exposed regions, to provide higher sensitivity and a better pattern profile.

The heating temperature is preferably 23 to 130° C., more preferably 23 to 110° C., and still more preferably 23 to 90° C.

The heating time is preferably 10 to 1000 seconds, more preferably 10 to 180 seconds, and still more preferably 30 to 120 seconds.

The heating can be performed using means included in an ordinary exposure device and/or an ordinary development device, and may alternatively be performed using a hot plate, for example.

This step is also referred to as post-exposure baking.

Step 3: second exposure step

The step 3 is a step of irradiating, with the second actinic ray or radiation, the resist film after irradiation with the first actinic ray or radiation.

Examples of the exposure method include a method in which the entire surface of the resist film after irradiation with the first actinic ray or radiation is irradiated with an actinic ray or radiation.

The actinic ray or radiation (the second actinic ray or radiation) used in the step 3 may be infrared rays, visible light, ultraviolet rays, or far ultraviolet rays, and is preferably ultraviolet rays.

The second actinic ray or radiation preferably has a wavelength of 350 nm to 450 nm.

After the exposure, before development, baking (heating) is preferably performed. The baking accelerates the reaction in the exposed regions, to provide higher sensitivity and a better pattern profile.

The heating temperature is preferably 70 to 150° C., more preferably 70 to 140° C., and still more preferably 70 to 130° C.

The heating time is preferably 10 to 1000 seconds, more preferably 10 to 180 seconds, and still more preferably 30 to 120 seconds.

The heating can be performed using means included in an ordinary exposure device and/or an ordinary development device, and may alternatively be performed using a hot plate, for example.

This step is also referred to as post-exposure baking.

Step 4: development step

The step 4 is a step of using a developer to develop the resist film after irradiation with the second actinic ray or radiation.

The step 4 is performed to thereby form a pattern.

The developer may be an alkali developer or may be a developer containing an organic solvent (hereafter, also referred to as organic-based developer).

Examples of the development process include a process of immersing, for a predetermined time, the substrate in a tank filled with the developer (dipping process), a process of puddling, with the developer, the surface of the substrate using surface tension and leaving the developer at rest for a predetermined time to achieve development (puddling process), a process of spraying the developer to the surface of the substrate (spraying process), and a process of scanning, at a constant rate, over the substrate rotated at a constant rate, a developer ejection nozzle to continuously eject the developer (dynamic dispensing process).

After the step of performing development, a step of performing exchange with another solvent to stop the development may be performed.

The development time is not particularly limited as long as the resin in the unexposed regions is sufficiently dissolved in the time, and is preferably 10 to 300 seconds, and more preferably 20 to 120 seconds.

The temperature of the developer is preferably 0 to 50° C., and more preferably 15 to 35° C. The alkali developer employed is preferably an alkali aqueous solution including an alkali. The type of the alkali aqueous solution is not particularly limited, but may be, for example, an alkali aqueous solution including a quaternary ammonium salt represented by tetramethylammonium hydroxide, an inorganic alkali, a primary amine, a secondary amine, a tertiary amine, an alcoholamine, a cyclic amine, or the like. In particular, the alkali developer is preferably an aqueous solution of a quaternary ammonium salt represented by tetramethylammonium hydroxide (TMAH). To the alkali developer, an appropriate amount of an alcohol, a surfactant, or the like may be added. The alkali developer ordinarily preferably has an alkali concentration of 0.1 to 20 mass %. The alkali developer ordinarily preferably has a pH of 10.0 to 15.0.

The organic-based developer is preferably a developer containing at least one organic solvent selected from the group consisting of ketone-based solvents, ester-based solvents, alcohol-based solvents, amide-based solvents, ether-based solvents, and hydrocarbon-based solvents.

A plurality of such solvents may be mixed together, or such a solvent may be mixed with a solvent other than those described above or water. The developer as a whole has a moisture content of preferably less than 50 mass %, more preferably less than 20 mass %, still more preferably less than 10 mass %, and particularly preferably contains substantially no moisture.

In the organic-based developer, the content of the organic solvent relative to the total amount of the developer is preferably 50 mass % or more and 100 mass % or less, more preferably 80 mass % or more and 100 mass % or less, still more preferably 90 mass % or more and 100 mass % or less, and particularly preferably 95 mass % or more and 100 mass % or less. Other step

The pattern forming method preferably includes a step of, after the step 3, using a rinse liquid to perform rinsing.

After the development step using an alkali developer, in the rinsing step, the rinse liquid employed may be, for example, pure water. Note that, to the pure water, an appropriate amount of surfactant may be added.

To the rinse liquid, an appropriate amount of surfactant may be added.

After the development step using an organic-based developer, in the rinsing step, the rinse liquid employed is not particularly limited as long as it does not dissolve the pattern, and can be a solution including an ordinary organic solvent. The rinse liquid employed is preferably a rinse liquid containing at least one organic solvent selected from the group consisting of hydrocarbon-based solvents, ketone-based solvents, ester-based solvents, alcohol-based solvents, amide-based solvents, and ether-based solvents.

The process of performing the rinsing step is not particularly limited; examples include a process of continuously ejecting, onto the substrate rotated at a constant rate, the rinse liquid (spin-coating process), a process of immersing, in a tank filled with the rinse liquid, the substrate for a predetermined time (dipping process), and a process of spraying, to the surface of the substrate, the rinse liquid (spraying process).

The pattern forming method may include a heating step (Post Bake) performed after the rinsing step. In this step, baking removes the developer and the rinse liquid remaining between and within the patterns. In addition, this step also provides an effect of annealing the resist pattern to address the rough surface of the pattern. The heating step after the rinsing step is performed ordinarily at 40 to 250° C. (preferably 90 to 200° C.) for ordinarily 10 seconds to 3 minutes (preferably 30 seconds to 120 seconds).

The formed pattern may be used as a mask for subjecting the substrate to etching treatment. Specifically, the pattern formed in the step 3 may be used as a mask for processing the substrate (or the underlayer film and the substrate), to form a pattern in the substrate.

The process of processing the substrate (or the underlayer film and the substrate) is not particularly limited, but is preferably a process of using the pattern formed in the step 3 as a mask for subjecting the substrate (or the underlayer film and the substrate) to dry etching, to thereby form a pattern in the substrate. The dry etching is preferably oxygen plasma etching.

Various materials used in the composition and the pattern forming method of the present invention (for example, a solvent, a developer, a rinse liquid, an antireflection film-forming composition, and a topcoat-forming composition) preferably do not include impurities such as metals. The content of impurities included in such materials is preferably 1 mass ppm (parts per million) or less, more preferably 10 mass ppb (parts per billion) or less, still more preferably 100 mass ppt or less, particularly preferably 10 mass ppt or less, and most preferably 1 mass ppt or less. The lower limit is not particularly limited, but is preferably 0 mass ppt or more. Examples of the metallic impurities include Na, K, Ca, Fe, Cu, Mg, Al, Li, Cr, Ni, Sn, Ag, As, Au, Ba, Cd, Co, Pb, Ti, V, W, and Zn.

The process of removing, from the various materials, impurities such as metals may be, for example, filtration using a filter. The details of filtration using a filter are described in Paragraph in WO2020/004306A .

Examples of the process of reducing the amount of impurities such as metals included in the various materials include a process of selecting, as raw materials constituting the various materials, raw materials having lower metal content, a process of subjecting raw materials constituting the various materials to filtration using a filter, and a process of performing distillation under conditions under which contamination is minimized by, for example, lining the interior of the apparatuses with TEFLON (registered trademark).

Instead of the filtration using a filter, an adsorption material may be used to remove impurities; alternatively, the filtration using a filter and the adsorption material may be used in combination. Such adsorption materials can be publicly known adsorption materials, and examples include inorganic-based adsorption materials such as silica gel and zeolite, and organic-based adsorption materials such as active carbon. In order to reduce the amount of impurities such as metals included in the various materials, ingress of metallic impurities in the production steps needs to be prevented. Whether or not metallic impurities are sufficiently removed from the production apparatuses can be determined by measuring the content of metallic components included in the washing liquid having been used for washing the production apparatuses. The content of metallic components included in the washing liquid having been used is preferably 100 mass ppt (parts per trillion) or less, more preferably 10 mass ppt or less, and still more preferably 1 mass ppt or less. The lower limit is not particularly limited, but is preferably 0 mass ppt or more.

To organic-based treatment liquids such as the rinse liquid, in order to prevent electrostatic buildup and the subsequent electrostatic discharge causing failure of the chemical solution pipe and various parts (such as a filter, an O-ring, and a tube), a conductive compound may be added. The conductive compound is not particularly limited, but may be, for example, methanol. The amount of addition is not particularly limited, but is, from the viewpoint of maintaining preferred development performance or rinsing performance, preferably 10 mass % or less, and more preferably 5 mass % or less. The lower limit is not particularly limited, but is preferably 0.01 mass % or more.

Examples of the chemical solution pipe include various pipes formed of SUS (stainless steel), or coated with polyethylene, polypropylene, or a fluororesin (such as polytetrafluoroethylene or a perfluoroalkoxy resin) treated so as to be antistatic. Similarly for the filter and the O-ring, polyethylene, polypropylene, or a fluororesin (such as polytetrafluoroethylene or a perfluoroalkoxy resin) treated so as to be antistatic can be used.

The pattern forming method is preferably performed such that irradiation with the first actinic ray or radiation generates a first active species in the resist film, the first active species changes the structure of the cation (CT), and irradiation with the second actinic ray or radiation generates a second active species from the cation whose structure has been changed (also referred to as “cation (CTA)”)

The first active species is preferably an acid (conjugate acid of the anion of the repeating unit (u1)), and more preferably a sulfonic acid.

The cation (CTA) formed by changing the structure of the cation (CT) by the first active species (preferably an acid) is preferably a ketone compound. The cation (CTA) preferably has a larger peak area in the absorption spectrum for light having wavelengths of 300 nm to 450 nm than the peak area in the absorption spectrum of the cation (CT) for light having wavelengths of 300 nm to 450 nm.

The second active species generated from the cation (CTA) upon irradiation with the second actinic ray or radiation is preferably an acid.

Method for producing electronic device

The present invention also relates to a method for producing an electronic device, the method including the above-described pattern forming method, and an electronic device produced by the production method.

Preferred embodiments of the electronic device of the present invention include embodiments of being mounted on electric and electronic apparatuses (home appliances, OA (Office Automation), media-related devices, optical devices, communication devices, and the like).

### EXAMPLES

Hereinafter, the present invention will be described further in detail with reference to Examples. In the following Examples, materials, usage amounts, ratios, details of treatments, and orders of treatments can be appropriately changed without departing from the spirit and scope of the present invention. Thus, the scope of the present invention should not be construed as being limited to the following Examples.

Various components used in the resist compositions of Examples and Comparative Examples will be described below.

### Resins

The resins (P-1 to P-79) described in Tables 1 to 3 below were synthesized by known methods. Note that P-1 to P-46 and P-48 to P-78 correspond to the resin (X), and P-47 and P-79 do not correspond to the resin (X).

Tables 1 to 3 describe the types and contents of the repeating units of P-1 to P-79. The content of each repeating unit is the mass ratio (mass %) of the repeating unit relative to all the repeating units. The type of each repeating unit is indicated by the type of monomer corresponding to the repeating unit.

Tables 1 to 3 also describe, for each resin, the weight-average molecular weight (Mw), the number-average molecular weight (Mn), and the dispersity (PDI). Mw, Mn, and PDI were measured by GPC (carrier: tetrahydrofuran (THF)) (polystyrene-equivalent amounts). The contents of the repeating units of the resins were measured by 13C-NMR (Nuclear Magnetic Resonance).

In Tables 1 to 3, “nᵤₙᵢₜ” represent the numbers of types of repeating units in the resins. “W_{PU}” represent the contents (mass %) of the photoacid-generating repeating units in the resins.

TABLE 1

| | Repeating | | Repeating | | Repeating | | Repeating | | | | | | |
|---|---|---|---|---|---|---|---|---|---|---|---|---|---|
| | unit 1 | | unit 2 | | unit 3 | | unit 4 | | | | | | |
| | | Content | | Content | | Content | | Content | | W_{PU} | | | |
| Resin | Type | (mass %) | Type | (mass %) | Type | (mass %) | Type | (mass %) | nᵤₙᵢₜ | (mass %) | Mw | Mn | PDI |
| P-1 | M-16 | 100 | — | 0 | — | 0 | — | 0 | 1 | 100 | 8800 | 6800 | 1.3 |
| P-2 | M-10 | 100 | — | 0 | — | 0 | — | 0 | 1 | 100 | 10100 | 6700 | 1.5 |
| P-3 | M-2 | 20 | M-8 | 80 | — | 0 | — | 0 | 2 | 80 | 6600 | 4400 | 1.5 |
| P-4 | M-13 | 100 | — | 0 | — | 0 | — | 0 | 1 | 100 | 12300 | 7700 | 1.6 |
| P-5 | M-1 | 20 | M-12 | 80 | — | 0 | — | 0 | 2 | 80 | 7800 | 5200 | 1.5 |
| P-6 | M-7 | 100 | — | 0 | — | 0 | — | 0 | 1 | 100 | 13100 | 7300 | 1.8 |
| P-7 | M-3 | 30 | M-7 | 70 | — | 0 | — | 0 | 2 | 70 | 11100 | 7900 | 1.4 |
| P-8 | M-1 | 30 | M-6 | 70 | — | 0 | — | 0 | 2 | 70 | 5000 | 4200 | 1.2 |
| P-9 | M-2 | 20 | M-5 | 80 | — | 0 | — | 0 | 2 | 80 | 14000 | 7800 | 1.8 |
| P-10 | M-1 | 30 | M-2 | 30 | M-4 | 40 | — | 0 | 3 | 40 | 12500 | 7800 | 1.6 |
| P-11 | M-17 | 100 | — | 0 | — | 0 | — | 0 | 1 | 100 | 10800 | 6000 | 1.8 |
| P-12 | M-1 | 10 | M-16 | 90 | — | 0 | — | 0 | 2 | 90 | 10900 | 6800 | 1.6 |
| P-13 | M-18 | 100 | — | 0 | — | 0 | — | 0 | 1 | 100 | 7800 | 4900 | 1.6 |
| P-14 | M-2 | 10 | M-16 | 90 | — | 0 | — | 0 | 2 | 90 | 7400 | 4600 | 1.6 |
| P-15 | M-11 | 100 | — | 0 | — | 0 | — | 0 | 1 | 100 | 9100 | 7600 | 1.2 |
| P-16 | M-3 | 40 | M-8 | 60 | — | 0 | — | 0 | 2 | 60 | 8200 | 5100 | 1.6 |
| P-17 | M-1 | 20 | M-10 | 80 | — | 0 | — | 0 | 2 | 80 | 7500 | 5000 | 1.5 |
| P-18 | M-2 | 40 | M-9 | 60 | — | 0 | — | 0 | 2 | 60 | 10600 | 5900 | 1.8 |
| P-19 | M-1 | 20 | M-2 | 30 | M-8 | 50 | — | 0 | 3 | 50 | 11700 | 6500 | 1.8 |
| P-20 | M-15 | 100 | — | 0 | — | 0 | — | 0 | 1 | 100 | 8400 | 6000 | 1.4 |
| P-21 | M-3 | 50 | M-12 | 50 | — | 0 | — | 0 | 2 | 50 | 6900 | 5300 | 1.3 |
| P-22 | M-1 | 30 | M-14 | 70 | — | 0 | — | 0 | 2 | 70 | 6700 | 4200 | 1.6 |
| P-23 | M-2 | 20 | M-13 | 80 | — | 0 | — | 0 | 2 | 80 | 10600 | 7600 | 1.4 |
| P-24 | M-1 | 30 | M-2 | 20 | M-12 | 50 | — | 0 | 3 | 50 | 7400 | 4100 | 1.8 |
| P-25 | M-19 | 100 | — | 0 | — | 0 | — | 0 | 1 | 100 | 5300 | 4100 | 1.3 |

TABLE 2

| | Repeating | | Repeating | | Repeating | | Repeating | | | | | | |
|---|---|---|---|---|---|---|---|---|---|---|---|---|---|
| | unit 1 | | unit 2 | | unit 3 | | unit 4 | | | | | | |
| | | Content | | Content | | Content | | Content | | W_{PU} | | | |
| Resin | Type | (mass %) | Type | (mass %) | Type | (mass %) | Type | (mass %) | nᵤₙᵢₜ | (mass %) | Mw | Mn | PDI |
| P-26 | M-3 | 30 | M-16 | 70 | — | 0 | — | 0 | 2 | 70 | 8100 | 5800 | 1.4 |
| P-27 | M-1 | 20 | M-18 | 80 | — | 0 | — | 0 | 2 | 80 | 7700 | 5100 | 1.5 |
| P-28 | M-2 | 20 | M-17 | 80 | — | 0 | — | 0 | 2 | 80 | 14400 | 8000 | 1.8 |
| P-29 | M-1 | 20 | M-2 | 20 | M-19 | 60 | — | 0 | 3 | 60 | 11900 | 7000 | 1.7 |
| P-30 | M-1 | 30 | M-2 | 30 | M-20 | 40 | — | 0 | 3 | 40 | 7800 | 6000 | 1.3 |
| P-31 | M-1 | 30 | M-2 | 30 | M-21 | 40 | — | 0 | 3 | 40 | 12500 | 7800 | 1.6 |
| P-32 | M-1 | 30 | M-2 | 30 | M-22 | 40 | — | 0 | 3 | 40 | 10900 | 6800 | 1.6 |
| P-33 | M-1 | 30 | M-2 | 30 | M-23 | 40 | — | 0 | 3 | 40 | 11700 | 7800 | 1.5 |
| P-34 | M-1 | 30 | M-2 | 30 | M-24 | 40 | — | 0 | 3 | 40 | 6400 | 5300 | 1.2 |
| P-35 | M-1 | 30 | M-2 | 30 | M-25 | 40 | — | 0 | 3 | 40 | 5200 | 4000 | 1.3 |
| P-36 | M-1 | 30 | M-2 | 30 | M-26 | 40 | — | 0 | 3 | 40 | 8300 | 5500 | 1.5 |
| P-37 | M-1 | 30 | M-2 | 30 | M-27 | 40 | — | 0 | 3 | 40 | 5900 | 4500 | 1.3 |
| P-38 | M-1 | 30 | M-2 | 30 | M-28 | 40 | — | 0 | 3 | 40 | 9000 | 6900 | 1.3 |
| P-39 | M-1 | 30 | M-2 | 30 | M-29 | 40 | — | 0 | 3 | 40 | 9000 | 5600 | 1.6 |
| P-40 | M-1 | 30 | M-2 | 30 | M-30 | 40 | — | 0 | 3 | 40 | 9300 | 5800 | 1.6 |
| P-41 | M-1 | 30 | M-2 | 30 | M-31 | 40 | — | 0 | 3 | 40 | 7700 | 4500 | 1.7 |
| P-42 | M-1 | 30 | M-2 | 30 | M-32 | 40 | — | 0 | 3 | 40 | 6800 | 4500 | 1.5 |
| P-43 | M-1 | 30 | M-2 | 30 | M-33 | 40 | — | 0 | 3 | 40 | 8600 | 4800 | 1.8 |
| P-44 | M-3 | 50 | M-4 | 40 | M-34 | 10 | — | 0 | 3 | 50 | 9800 | 7000 | 1.4 |
| P-45 | M-35 | 37 | M-36 | 10 | M-37 | 26 | M-38 | 27 | 4 | 37 | 9900 | 7100 | 1.4 |
| P-46 | M-35 | 39 | M-36 | 10 | M-37 | 24 | M-38 | 27 | 4 | 39 | 10400 | 5800 | 1.8 |
| P-47 | M-1 | 20 | M-2 | 30 | M-39 | 50 | — | 0 | 3 | 50 | 11500 | 6400 | 1.8 |
| P-48 | M-2 | 60 | M-4 | 40 | — | 0 | — | 0 | 2 | 40 | 4900 | 4100 | 1.2 |
| P-49 | M-2 | 45 | M-8 | 55 | — | 0 | — | 0 | 2 | 55 | 6200 | 4100 | 1.5 |
| P-50 | M-2 | 30 | M-12 | 70 | — | 0 | — | 0 | 2 | 70 | 7400 | 5300 | 1.4 |
| P-51 | M-2 | 45 | M-5 | 55 | — | 0 | — | 0 | 2 | 55 | 8500 | 5000 | 1.7 |

TABLE 3

| | Repeating | | Repeating | | Repeating | | Repeating | | | | | | |
|---|---|---|---|---|---|---|---|---|---|---|---|---|---|
| | unit 1 | | unit 2 | | unit 3 | | unit 4 | | | | | | |
| | | Content | | Content | | Content | | Content | | W_{PU} | | | |
| Resin | Type | (mass %) | Type | (mass %) | Type | (mass %) | Type | (mass %) | nᵤₙᵢₜ | (mass %) | Mw | Mn | PDI |
| P-52 | M-1 | 10 | M-2 | 50 | M-4 | 40 | — | 0 | 3 | 40 | 7300 | 6100 | 1.2 |
| P-53 | M-2 | 30 | M-16 | 70 | — | 0 | — | 0 | 2 | 70 | 7400 | 4100 | 1.8 |
| P-54 | M-2 | 45 | M-9 | 55 | — | 0 | — | 0 | 2 | 55 | 5600 | 4300 | 1.3 |
| P-55 | M-1 | 15 | M-2 | 45 | M-8 | 40 | — | 0 | 3 | 40 | 6500 | 5000 | 1.3 |
| P-56 | M-3 | 50 | M-12 | 50 | — | 0 | — | 0 | 2 | 50 | 7900 | 6100 | 1.3 |
| P-57 | M-2 | 35 | M-13 | 65 | — | 0 | — | 0 | 2 | 65 | 9200 | 5400 | 1.7 |
| P-58 | M-1 | 10 | M-2 | 30 | M-16 | 60 | — | 0 | 3 | 60 | 8200 | 5100 | 1.6 |
| P-59 | M-3 | 50 | M-16 | 50 | — | 0 | — | 0 | 2 | 50 | 9200 | 7700 | 1.2 |
| P-60 | M-2 | 40 | M-17 | 60 | — | 0 | — | 0 | 2 | 60 | 12200 | 7600 | 1.6 |
| P-61 | M-1 | 10 | M-2 | 30 | M-16 | 60 | — | 0 | 3 | 60 | 6700 | 5600 | 1.2 |
| P-62 | M-1 | 10 | M-2 | 50 | M-20 | 40 | — | 0 | 3 | 40 | 10900 | 6800 | 1.6 |
| P-63 | M-1 | 10 | M-2 | 50 | M-21 | 40 | — | 0 | 3 | 40 | 10500 | 7500 | 1.4 |
| P-64 | M-1 | 10 | M-2 | 50 | M-22 | 40 | — | 0 | 3 | 40 | 9600 | 6000 | 1.6 |
| P-65 | M-1 | 10 | M-2 | 50 | M-23 | 40 | — | 0 | 3 | 40 | 5300 | 4100 | 1.3 |
| P-66 | M-1 | 10 | M-2 | 50 | M-24 | 40 | — | 0 | 3 | 40 | 12600 | 7400 | 1.7 |
| P-67 | M-1 | 10 | M-2 | 50 | M-25 | 40 | — | 0 | 3 | 40 | 9100 | 6500 | 1.4 |
| P-68 | M-1 | 10 | M-2 | 50 | M-26 | 40 | — | 0 | 3 | 40 | 10000 | 5900 | 1.7 |
| P-69 | M-1 | 10 | M-2 | 50 | M-27 | 40 | — | 0 | 3 | 40 | 10800 | 7700 | 1.4 |
| P-70 | M-1 | 10 | M-2 | 50 | M-28 | 40 | — | 0 | 3 | 40 | 11900 | 7900 | 1.5 |
| P-71 | M-1 | 10 | M-2 | 50 | M-29 | 40 | — | 0 | 3 | 40 | 11300 | 6300 | 1.8 |
| P-72 | M-1 | 10 | M-2 | 50 | M-30 | 40 | — | 0 | 3 | 40 | 11300 | 6300 | 1.8 |
| P-73 | M-1 | 10 | M-2 | 50 | M-31 | 40 | — | 0 | 3 | 40 | 11100 | 7900 | 1.4 |
| P-74 | M-1 | 10 | M-2 | 50 | M-32 | 40 | — | 0 | 3 | 40 | 11700 | 6900 | 1.7 |
| P-75 | M-1 | 10 | M-2 | 50 | M-33 | 40 | — | 0 | 3 | 40 | 7200 | 5500 | 1.3 |
| P-76 | M-2 | 50 | M-4 | 40 | M-34 | 10 | — | 0 | 3 | 50 | 7100 | 5100 | 1.4 |
| P-77 | M-35 | 37 | M-36 | 5 | M-37 | 12 | M-38 | 46 | 4 | 37 | 8900 | 5900 | 1.5 |
| P-78 | M-35 | 39 | M-36 | 5 | M-37 | 10 | M-38 | 46 | 4 | 39 | 8600 | 5700 | 1.5 |
| P-79 | M-2 | 50 | M-39 | 50 | — | 0 | — | 0 | 2 | 50 | 10800 | 7700 | 1.4 |

The structural formulas of M-1 to M-3 and M-36 to M-38 are described below.

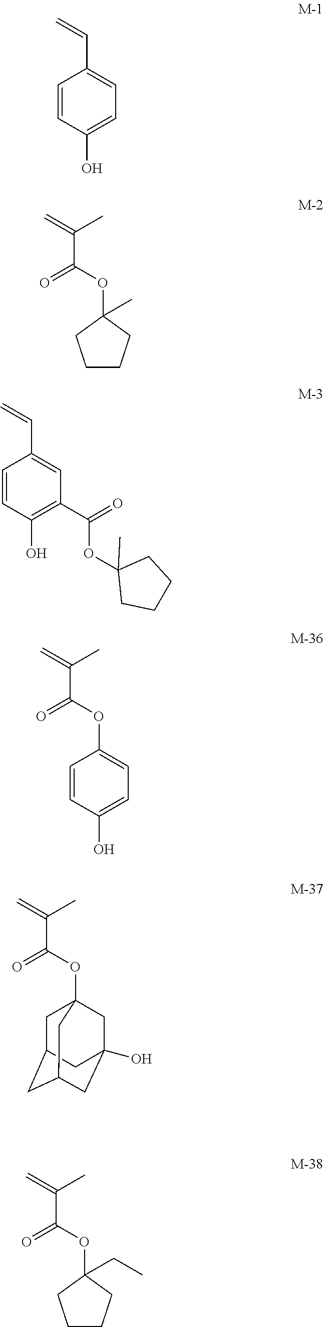

M-4 to M-35 and M-39 are monomers including, in the combinations described in Table 4 below, any “cation” of the Cation-1 to the Cation-12 described above as specific examples of the cation (CT) or a Cation-13 described below, which is not the cation (CT), and any “non-cation structure” of the Anion-1 to the Anion-10 described above as specific examples of the non-cation structure of the repeating unit (u1) or an Anion-11 described below, which is not the non-cation structure of the repeating unit (u1).

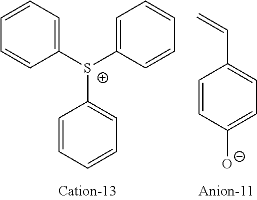

TABLE 4

| | | Non-cation |
|---|---|---|
| Monomer | Cation | structure |
| M-4 | Cation-1 | Anion-1 |
| M-5 | Cation-1 | Anion-2 |
| M-6 | Cation-1 | Anion-3 |
| M-7 | Cation-1 | Anion-4 |
| M-8 | Cation-2 | Anion-1 |
| M-9 | Cation-2 | Anion-2 |
| M-10 | Cation-2 | Anion-3 |
| M-11 | Cation-2 | Anion-4 |
| M-12 | Cation-3 | Anion-1 |
| M-13 | Cation-3 | Anion-2 |
| M-14 | Cation-3 | Anion-3 |
| M-15 | Cation-3 | Anion-4 |
| M-16 | Cation-4 | Anion-1 |
| M-17 | Cation-4 | Anion-2 |
| M-18 | Cation-4 | Anion-3 |
| M-19 | Cation-4 | Anion-4 |
| M-20 | Cation-1 | Anion-5 |
| M-21 | Cation-1 | Anion-6 |
| M-22 | Cation-1 | Anion-7 |
| M-23 | Cation-1 | Anion-8 |
| M-24 | Cation-1 | Anion-9 |
| M-25 | Cation-1 | Anion-10 |
| M-26 | Cation-5 | Anion-1 |
| M-27 | Cation-6 | Anion-1 |
| M-28 | Cation-7 | Anion-1 |
| M-29 | Cation-8 | Anion-1 |
| M-30 | Cation-9 | Anion-1 |
| M-31 | Cation-10 | Anion-1 |
| M-32 | Cation-11 | Anion-1 |
| M-33 | Cation-12 | Anion-1 |
| M-34 | Cation-1 | Anion-11 |
| M-35 | Cation-2 | Anion-7 |
| M-39 | Cation-13 | Anion-1 |

### Acid Diffusion Control Agents

As acid diffusion control agents, Q-1 to Q-13 were used. Q-1 to Q-13 are compounds including, in the combinations described in Table 5 below, any “cation” of the Cation-1 to the Cation-12 described above as specific examples of the cation (CT) in the resin (X) or the Cation-13 described above, which is not the cation (CT), and a structure including an anion represented by an Anion-12 described below.

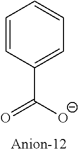

TABLE 5

| Acid diffusion control agent | Cation | Structure including anion |
|---|---|---|
| Q-1 | Cation-1 | Anion-12 |
| Q-2 | Cation-2 | Anion-12 |
| Q-3 | Cation-3 | Anion-12 |
| Q-4 | Cation-4 | Anion-12 |
| Q-5 | Cation-5 | Anion-12 |
| Q-6 | Cation-6 | Anion-12 |
| Q-7 | Cation-7 | Anion-12 |
| Q-8 | Cation-8 | Anion-12 |
| Q-9 | Cation-9 | Anion-12 |
| Q-10 | Cation-10 | Anion-12 |
| Q-11 | Cation-11 | Anion-12 |
| Q-12 | Cation-12 | Anion-12 |
| Q-13 | Cation-13 | Anion-12 |

### Solvents

As solvents, the following SL-3 and MSL-1 to MSL-6 obtained by mixing at least two selected from the group consisting of the following SL-1, SL-2, SL-4, SL-5, and SL-6 at ratios described in the following Table 6 were used. The numerical values in the following Table 6 are mass ratios (mass %) of SL-1, SL-2, SL-4, SL-5, and SL-6 included in MSL-1 to MSL-6.
SL-1: Propylene glycol monomethyl ether acetate (PGMEA)
SL-2: Propylene glycol monomethyl ether (PGME)
SL-3: Cyclohexanone
SL-4: y-Butyrolactone
SL-5: Ethyl lactate
SL-6: Diacetone alcohol

TABLE 6

| Solvent | SL-1 | SL-2 | SL-4 | SL-5 | SL-6 |
|---|---|---|---|---|---|
| MSL-1 | 60 | 40 | — | — | — |
| MSL-2 | 80 | 20 | — | — | — |
| MSL-3 | 20 | 20 | — | 60 | — |
| MSL-4 | 20 | | — | — | 80 |
| MSL-5 | 75 | — | — | — | 25 |
| MSL-6 | 85 | 10 | 5 | — | — |

### Developers and Rinse Liquids

As the developers and rinse liquids, the following D-1, D-2, D-3, D-5, and MD-1 to MD-3 obtained by mixing two selected from the group consisting of D-3 to D-5 at the ratios described in the following Table 7 were used. The numerical values in following Table 7 are the mass ratios (mass %) of D-3 to D-5 included in MD-1 to MD-3.
D-1:2.38 mass % Aqueous tetramethylammonium hydroxide solution
D-2: Pure water
D-3: Butyl acetate
D-4: n-Undecane
D-5:2-Heptanone

TABLE 7

| Developer or | | | |
|---|---|---|---|
| rinse liquid | D-3 | D-4 | D-5 |
| MD-1 | 90 | 10 | — |
| MD-2 | 80 | 20 | — |
| MD-3 | — | 10 | 90 |

### Examples 1 to 49 and Comparative Examples 1 to 3

### Preparation of Resist Compositions

A resin described in Tables 8 and 9 below and, only when described, an acid diffusion control agent were used so as to satisfy contents described in Tables 8 and 9, and were mixed in a solvent described in Tables 8 and 9 so as to satisfy a solid-content concentration described in Tables 8 and 9. Subsequently, the obtained mixed solution was filtered first through a polyethylene filter having a pore size of 50 nm, then through a nylon filter having a pore size of 10 nm, and finally through a polyethylene filter having a pore size of 5 nm in this order; in this way, resist compositions R-1 to R-49) were prepared. Note that, in the resist compositions, the solid contents mean all the components other than the solvents.

In Tables 8 and 9, the content (mass %) of each component other than the solvent represents the content (mass %) of the component relative to the total solid content in the resist composition.

Tables 8 and 9 also describe, in the columns “Cul”, the content (mass %) of the repeating unit (u1) relative to the total resin content in each resist composition. In other words, “Cui” in Tables 8 and 9 represent the content (mass %) of the repeating unit (u1) relative to the total resin content in each resist composition.

Tables 8 and 9 also describe the content of the photoacid-generating repeating unit relative to the total resin content in each resist composition (in the Tables, represented by “CPAG”, and the unit is “mmol/g”), the content of the repeating unit having an acid group relative to the total resin content in each resist composition (in the Tables, represented by “CAC”, and the unit is “mmol/g”), and the content of the repeating unit having an acid-decomposable group relative to the total resin content in each resist composition (in the Tables, represented by “CDC”, and the unit is “mmol/g”).

TABLE 8

| | | | Acid diffusion | | | | | | | |
|---|---|---|---|---|---|---|---|---|---|---|
| | Resin | | control agent | | Solid-content | | | | | |
| Resist | | Content | | Content | concentration | | Cᵤₗ | C_{PAG} | C_{AC} | C_{DC} |
| composition | Type | (mass %) | Type | (mass %) | (mass %) | Solvent | (mass %) | (mmol/g) | (mmol/g) | (mmol/g) |
| R-1 | P-1 | 90 | Q-1 | 10 | 2.5 | MSL-1 | 100 | 1.277 | 1.277 | 2.555 |
| R-2 | P-2 | 90 | Q-3 | 10 | 2.5 | MSL-4 | 100 | 1.277 | 1.277 | 2.555 |
| R-3 | P-3 | 90 | Q-1 | 10 | 2.5 | MSL-5 | 80 | 1.033 | 1.033 | 2.221 |
| R-4 | P-4 | 90 | Q-2 | 10 | 2.5 | MSL-3 | 100 | 1.143 | 1.143 | 2.286 |
| R-5 | P-5 | 90 | Q-1 | 10 | 2.5 | MSL-1 | 80 | 0.874 | 1.665 | 1.749 |
| R-6 | P-6 | 90 | Q-4 | 10 | 2.5 | SL-3 | 100 | 1.107 | 1.107 | 2.215 |
| R-7 | P-7 | 90 | Q-4 | 10 | 2.5 | SL-3 | 70 | 0.775 | 1.993 | 2.768 |
| R-8 | P-8 | 90 | Q-3 | 10 | 2.5 | MSL-1 | 70 | 0.913 | 2.497 | 1.826 |
| R-9 | P-9 | 90 | Q-2 | 10 | 2.5 | MSL-4 | 80 | 1.113 | 1.113 | 2.302 |
| R-10 | P-10 | 90 | Q-1 | 10 | 2.5 | MSL-3 | 40 | 0.527 | 2.497 | 2.310 |
| R-11 | P-11 | 90 | Q-2 | 10 | 2.5 | MSL-6 | 100 | 1.088 | 2.176 | 2.176 |
| R-12 | P-12 | 90 | Q-1 | 10 | 2.5 | MSL-2 | 90 | 1.150 | 1.982 | 2.299 |
| R-13 | P-13 | 90 | Q-3 | 10 | 2.5 | MSL-3 | 100 | 1.093 | 1.093 | 3.279 |
| R-14 | P-14 | 90 | Q-1 | 10 | 2.5 | MSL-5 | 90 | 1.150 | 1.150 | 2.894 |
| R-15 | P-15 | 90 | Q-4 | 10 | 2.5 | MSL-1 | 100 | 1.088 | 2.176 | 2.176 |
| R-16 | P-16 | 90 | Q-1 | 10 | 2.5 | MSL-3 | 60 | 0.774 | 2.398 | 2.398 |
| R-17 | P-17 | 90 | Q-3 | 10 | 2.5 | MSL-6 | 80 | 1.022 | 2.686 | 2.044 |
| R-18 | P-18 | 90 | Q-2 | 10 | 2.5 | MSL-5 | 60 | 0.817 | 1.633 | 3.194 |
| R-19 | P-19 | 90 | Q-1 | 10 | 2.5 | MSL-6 | 50 | 0.645 | 2.310 | 2.428 |
| R-20 | P-20 | 90 | Q-4 | 10 | 2.5 | MSL-6 | 100 | 1.361 | 1.361 | 4.083 |
| R-21 | P-21 | 90 | Q-1 | 10 | 2.5 | MSL-1 | 50 | 0.546 | 2.030 | 3.123 |
| R-22 | P-22 | 90 | Q-3 | 10 | 2.5 | MSL-6 | 70 | 0.903 | 2.497 | 2.710 |
| R-23 | P-23 | 90 | Q-2 | 10 | 2.5 | MSL-1 | 80 | 0.914 | 0.914 | 3.017 |
| R-24 | P-24 | 90 | Q-1 | 10 | 2.5 | MSL-2 | 50 | 0.546 | 2.497 | 2.282 |
| R-25 | P-25 | 90 | Q-4 | 10 | 2.5 | MSL-2 | 100 | 1.143 | 2.286 | 3.429 |

TABLE 9

| | | | Acid diffusion | | | | | | | |
|---|---|---|---|---|---|---|---|---|---|---|
| | Resin | | control agent | | Solid-content | | | | | |
| Resist | | Content | | Content | concentration | | Cᵤₗ | C_{PAG} | C_{AC} | C_{DC} |
| composition | Type | (mass %) | Type | (mass %) | (mass %) | Solvent | (mass %) | (mmol/g) | (mmol/g) | (mmol/g) |
| R-26 | P-26 | 90 | Q-1 | 10 | 2.5 | MSL-4 | 70 | 0.894 | 2.112 | 3.006 |
| R-27 | P-27 | 90 | Q-3 | 10 | 2.5 | MSL-3 | 80 | 0.874 | 2.539 | 2.623 |
| R-28 | P-28 | 90 | Q-2 | 10 | 2.5 | MSL-4 | 80 | 0.871 | 1.741 | 2.930 |
| R-29 | P-29 | 90 | Q-4 | 10 | 2.5 | MSL-4 | 60 | 0.686 | 3.036 | 3.246 |
| R-30 | P-30 | 90 | Q-1 | 10 | 2.5 | SL-3 | 40 | 0.596 | 2.497 | 2.380 |
| R-31 | P-31 | 90 | Q-1 | 10 | 2.5 | MSL-2 | 40 | 0.549 | 2.497 | 2.332 |
| R-32 | P-32 | 90 | Q-1 | 10 | 2.5 | MSL-4 | 40 | 0.620 | 2.497 | 2.404 |
| R-33 | P-33 | 90 | Q-1 | 10 | 2.5 | MSL-4 | 40 | 0.449 | 2.497 | 2.232 |
| R-34 | P-34 | 90 | Q-1 | 10 | 2.5 | SL-3 | 40 | 0.480 | 2.497 | 2.263 |
| R-35 | P-35 | 90 | Q-1 | 10 | 2.5 | MSL-1 | 40 | 0.455 | 2.497 | 2.238 |
| R-36 | P-36 | 90 | Q-5 | 10 | 2.5 | MSL-6 | 40 | 0.507 | 2.497 | 2.290 |
| R-37 | P-37 | 90 | Q-6 | 10 | 2.5 | MSL-1 | 40 | 0.491 | 2.497 | 2.274 |
| R-38 | P-38 | 90 | Q-7 | 10 | 2.5 | SL-3 | 40 | 0.506 | 2.497 | 2.289 |
| R-39 | P-39 | 90 | Q-8 | 10 | 2.5 | MSL-3 | 40 | 0.460 | 2.497 | 2.243 |
| R-40 | P-40 | 90 | Q-9 | 10 | 2.5 | SL-3 | 40 | 0.449 | 2.497 | 2.232 |
| R-41 | P-41 | 90 | Q-10 | 10 | 2.5 | MSL-6 | 40 | 0.456 | 2.497 | 2.239 |
| R-42 | P-42 | 90 | Q-11 | 10 | 2.5 | MSL-3 | 40 | 0.439 | 2.497 | 2.661 |
| R-43 | P-43 | 90 | Q-12 | 10 | 2.5 | MSL-2 | 40 | 0.486 | 2.497 | 2.269 |
| R-44 | P-44 | 100 | — | 0 | 2.5 | MSL-4 | 50 | 0.679 | 2.030 | 2.709 |
| R-45 | P-1 | 100 | — | 0 | 2.5 | MSL-1 | 100 | 1.277 | 1.277 | 2.555 |
| R-46 | P-3/P-19 | 45/45 | Q1 | 10 | 2.5 | MSL-1 | 65 | 0.839 | 1.671 | 2.325 |
| R-47 | P-45 | 90 | Q-2 | 10 | 2.5 | MSL-3 | 37 | 0.563 | 2.225 | 2.045 |
| R-48 | P-46 | 90 | Q-2 | 10 | 2.5 | MSL-1 | 39 | 0.594 | 2.171 | 2.075 |
| R-49 | P-47 | 90 | Q-13 | 10 | 2.5 | MSL-4 | 50 | 0.819 | 1.665 | 1.783 |

### Pattern Formation by EUV Exposure

The underlayer film-forming composition AL412 (manufactured by Brewer Science, Inc.) was applied onto a silicon wafer having a diameter of 300 mm, and baked at 205° C. for 60 seconds to form an underlayer film having a film thickness of 20 nm. On the underlayer film, a resist composition described in Tables 10 and 11 below was applied, and subjected to post applied bake (Post Applied Bake; PAB) at 120° C. to form a resist film having a film thickness of 70 nm. Thus, the silicon wafer having the resist film was formed.

The silicon wafer having the resist film obtained by the above-described procedure was subjected to pattern irradiation using an EUV scanner NXE3400 (NA: 0.33) manufactured by ASML while changing the exposure dose. The reticle employed was a hexagonal-array contact hole mask (dark field mask) having a pitch of 36 nm and an opening portion size of 20 nm.

Subsequently, only when described, post exposure bake (Post Exposure Bake; PEB) was performed under conditions described in Tables 10 and 11 (PEB before flood exposure is also described as “PEB1”). Subsequently, the wafer was subjected to flood exposure (full surface exposure) using a UV exposure apparatus (light having wavelengths of 355 nm to 410 nm) at an exposure dose described in Tables 10 and 11, and, only when described, subjected to PEB under conditions described in Tables 10 and 11 (PEB after flood exposure is also described as “PEB2”). Subsequently, development was performed using a developer described in Tables 10 and 11 for 30 seconds, and only when described, the wafer was rinsed by pouring a rinse liquid described in Tables 10 and 11 for 10 seconds while rotating the wafer at a rotational rate of 1000 rpm; and then the wafer was rotated at a rotational rate of 4000 rpm for 30 seconds; in this way, positive-type contact hole patterns having a pitch of 36 nm were obtained.

### Evaluation (Sensitivity, LCDU, and Resolution)

When using the above mask, the exposure dose that resolved hole CDs (Critical Dimensions) of 18 nm on average was defined as sensitivity (unit: mJ/cm²). The smaller the value of the sensitivity, the better the sensitivity.

Using a critical dimension scanning electron microscope (SEM: Scanning Electron Microscope (manufactured by Hitachi High-Technologies Corporation, CG6300)), 2,000 arbitrary holes at each exposure dose were observed, and the standard deviation (6) of the hole CDs was determined. The variation in hole CDs was evaluated on the basis of 36, and the 36 value was defined as LCDU (unit: nm). The smaller the value of LCDU, the better the LCDU.

In addition, using a critical dimension scanning electron microscope (manufactured by Hitachi High-Technologies Corporation, CG6300), arbitrary 2000 holes at each exposure dose were observed, and the average hole diameter and the hole performance were evaluated. The minimum value (CDmin) of the average hole diameter at the exposure dose satisfying the condition that no unresolved hole was generated in the 2000 observed holes and the maximum value (CDmax) of the average hole diameter at the exposure dose satisfying the condition that no unresolved hole was generated in the 2000 observed holes were determined; the difference between CDmax and CDmin was determined and defined as the failure free latitude (FFL: Failure Free Latitude). The larger this value, the better the resolving power and the performance (resolution); thus, this value was defined as the index of resolution.

The results are described in Tables 10 and 11 below.

In Tables 10 and 11, the unit of “Sensitivity” is “mJ/cm²”, the unit of “LCDU” is “nm”, and the unit of “Resolution (FFL)” is “nm”.

TABLE 10

| | | Process conditions | | | | | Evaluation | | |
|---|---|---|---|---|---|---|---|---|---|
| | Resist | PEB1 | UV exposure | PEB2 | | Rinse | | | Resolution |
| | composition | (° C.) | dose (J/cm²) | (° C.) | Developer | liquid | Sensitivity | LCDU | (FFL) |
| Example 1 | R-1 | 70 | 1 | 110 | D-1 | D-2 | 57 | 3.0 | 3.0 |
| Example 2 | R-2 | 70 | 1 | 90 | D-1 | D-2 | 57 | 3.0 | 3.0 |
| Example 3 | R-3 | 70 | 1 | 110 | D-1 | D-2 | 63 | 3.2 | 2.8 |
| Example 4 | R-4 | 80 | 1 | 100 | D-1 | D-2 | 58 | 3.0 | 3.0 |
| Example 5 | R-5 | — | 1 | 100 | D-1 | D-2 | 63 | 3.2 | 2.8 |
| Example 6 | R-6 | — | 1 | 110 | D-1 | D-2 | 58 | 3.0 | 3.0 |
| Example 7 | R-7 | 80 | 1 | 100 | D-1 | D-2 | 63 | 3.3 | 2.7 |
| Example 8 | R-8 | 70 | 1 | 90 | D-1 | D-2 | 64 | 3.3 | 2.7 |
| Example 9 | R-9 | 70 | 1 | 100 | D-1 | D-2 | 63 | 3.2 | 2.8 |
| Example 10 | R-10 | 70 | 1 | 110 | D-1 | D-2 | 70 | 3.6 | 2.4 |
| Example 11 | R-11 | 70 | 1 | 90 | D-1 | D-2 | 57 | 3.0 | 3.0 |
| Example 12 | R-12 | — | 1 | 110 | D-1 | D-2 | 60 | 3.1 | 2.9 |
| Example 13 | R-13 | 80 | 1 | 100 | D-1 | D-2 | 57 | 3.0 | 3.0 |
| Example 14 | R-14 | 80 | 1 | 100 | D-1 | D-2 | 60 | 3.1 | 2.9 |
| Example 15 | R-15 | 70 | 1 | 110 | D-1 | D-2 | 57 | 3.0 | 3.0 |
| Example 16 | R-16 | — | 1 | 90 | D-1 | D-2 | 65 | 3.4 | 2.6 |
| Example 17 | R-17 | — | 1 | 100 | D-1 | D-2 | 61 | 3.2 | 2.8 |
| Example 18 | R-18 | — | 1 | 100 | D-1 | D-2 | 65 | 3.4 | 2.6 |
| Example 19 | R-19 | — | 1 | 110 | D-1 | D-2 | 68 | 3.5 | 2.5 |
| Example 20 | R-20 | — | 1 | 110 | D-1 | D-2 | 56 | 3.0 | 3.0 |
| Example 21 | R-21 | 70 | 1 | 110 | D-1 | D-2 | 67 | 3.5 | 2.5 |
| Example 22 | R-22 | — | 1 | 100 | D-1 | D-2 | 63 | 3.3 | 2.7 |
| Example 23 | R-23 | 80 | 1 | 90 | D-1 | D-2 | 62 | 3.2 | 2.8 |
| Example 24 | R-24 | — | 1 | 100 | D-1 | D-2 | 68 | 3.5 | 2.5 |
| Example 25 | R-25 | — | 1 | 110 | D-1 | D-2 | 55 | 3.0 | 3.0 |
| Example 26 | R-26 | — | 1 | 100 | D-1 | D-2 | 63 | 3.3 | 2.7 |

TABLE 11

| | | Process conditions | | | | | Evaluation | | |
|---|---|---|---|---|---|---|---|---|---|
| | Resist | PEB1 | UV exposure | PEB2 | | Rinse | | | Resolution |
| | composition | (° C.) | dose (J/cm²) | (° C.) | Developer | liquid | Sensitivity | LCDU | (FFL) |
| Example 27 | R-27 | 70 | 1 | 100 | D-1 | D-2 | 61 | 3.2 | 2.8 |
| Example 28 | R-28 | — | 1 | 90 | D-1 | D-2 | 61 | 3.2 | 2.8 |
| Example 29 | R-29 | 70 | 1 | 100 | D-1 | D-2 | 65 | 3.4 | 2.6 |
| Example 30 | R-30 | 80 | 1 | 110 | D-1 | D-2 | 70 | 3.6 | 2.4 |
| Example 31 | R-31 | — | 1 | 110 | D-1 | D-2 | 70 | 3.6 | 2.4 |
| Example 32 | R-32 | 70 | 1 | 100 | D-1 | D-2 | 70 | 3.6 | 2.4 |
| Example 33 | R-33 | — | 1 | 110 | D-1 | D-2 | 70 | 3.6 | 2.4 |
| Example 34 | R-34 | — | 1 | 110 | D-1 | D-2 | 70 | 3.6 | 2.4 |
| Example 35 | R-35 | — | 1 | 100 | D-1 | D-2 | 70 | 3.6 | 2.4 |
| Example 36 | R-36 | 70 | 1 | 110 | D-1 | D-2 | 70 | 3.6 | 2.4 |
| Example 37 | R-37 | 70 | 1 | 90 | D-1 | D-2 | 70 | 3.6 | 2.4 |
| Example 38 | R-38 | 80 | 1 | 90 | D-1 | D-2 | 80 | 3.8 | 2.2 |
| Example 39 | R-39 | 70 | 1 | 100 | D-1 | D-2 | 80 | 3.8 | 2.2 |
| Example 40 | R-40 | 80 | 1 | 100 | D-1 | D-2 | 80 | 3.8 | 2.2 |
| Example 41 | R-41 | 80 | 1 | 110 | D-1 | D-2 | 80 | 3.8 | 2.2 |
| Example 42 | R-42 | 80 | 1 | 90 | D-1 | D-2 | 80 | 3.8 | 2.2 |
| Example 43 | R-43 | 80 | 1 | 90 | D-1 | D-2 | 80 | 3.8 | 2.2 |
| Example 44 | R-44 | 80 | 1 | 110 | D-1 | D-2 | 68 | 3.5 | 2.5 |
| Example 45 | R-45 | — | 1 | — | D-1 | D-2 | 80 | 3.7 | 2.4 |
| Example 46 | R-46 | 70 | 1 | 110 | D-1 | D-2 | 66 | 3.8 | 2.3 |
| Example 47 | R-1 | 70 | 0.5 | 110 | D-1 | D-2 | 63 | 3.1 | 2.7 |
| Example 48 | R-1 | 70 | 2 | 110 | D-1 | D-2 | 56 | 3.1 | 2.7 |
| Example 49 | R-1 | 70 | 3 | 110 | D-1 | D-2 | 55 | 3.3 | 2.6 |
| Comparative | R-47 | 80 | 1 | 90 | D-1 | D-2 | 92 | 4.1 | 1.9 |
| Example 1 | | | | | | | | | |
| Comparative | R-48 | — | 1 | 110 | D-1 | D-2 | 92 | 4.1 | 1.9 |
| Example 2 | | | | | | | | | |
| Comparative | R-49 | — | 1 | 90 | D-1 | D-2 | 99 | 4.0 | 1.5 |
| Example 3 | | | | | | | | | |

### Integral Values of Absorbance Before and After Exposure and Calculation Method

For the Cation-1 to the Cation-12, the peak areas in the absorption spectra for light having wavelengths of 300 nm to 450 nm before and after the structural changes by the action of an acid were determined by TD-DFT calculation using Gaussian 16 as the electronic state calculation software provided by Gaussian, using B3LYP/6-31+G (d) and Acetonitrile solvent conditions using the IEFPCM method, and by UV-Vis spectrum calculation using the calculation software Gauss View under a condition of a half-width of 0.2 eV and with output wavelength intervals of 1 nm. The results are described in Table 12 below.

TABLE 12

| Cation | Before structural change | After structural change |
|---|---|---|
| Cation-1 | 265672 | 321178 |
| Cation-2 | 386713 | 686886 |
| Cation-3 | 391652 | 874800 |
| Cation-4 | 386963 | 908621 |
| Cation-5 | 390161 | 873291 |
| Cation-6 | 274017 | 321178 |
| Cation-7 | 288488 | 784623 |
| Cation-8 | 333141 | 1449838 |
| Cation-9 | 2083 | 637242 |
| Cation-10 | 560702 | 1477258 |
| Cation-11 | 3078 | 1078380 |
| Cation-12 | 238644 | 784623 |

### Examples 50 to 88 and Comparative Examples 4 to 6

### Preparation of Resist Compositions

Resist compositions were prepared in the same manner as in Example 1 described above except that the resins and the acid diffusion control agents described in Tables 13 and 14 below were mixed in the solvents described in Tables 13 and 14 so as to satisfy the solid-content concentrations described in Tables 13 and 14.

TABLE 13

| | | | Acid diffusion | | | | | | | |
|---|---|---|---|---|---|---|---|---|---|---|
| | Resin | | control agent | | | | | | | |
| Resist | | Content | | Content | Solid-content concentration | | Cul | CPAG | CAC | CDC |
| composition | Type | (mass %) | Type | (mass %) | (mass %) | Solvent | (mass %) | (mmol/g) | (mmol/g) | (mmol/g) |
| R-50 | P-48 | 90 | Q-1 | 10 | 1.3 | MSL-4 | 40 | 0.527 | 0.000 | 4.093 |
| R-51 | P-49 | 90 | Q-1 | 10 | 1.3 | MSL-4 | 55 | 0.710 | 0.710 | 3.385 |
| R-52 | P-50 | 90 | Q-1 | 10 | 1.3 | MSL-1 | 70 | 0.765 | 0.000 | 3.313 |
| R-53 | P-51 | 90 | Q-2 | 10 | 1.3 | SL-3 | 55 | 0.765 | 0.765 | 3.440 |
| R-54 | P-52 | 90 | Q-1 | 10 | 1.3 | SL-3 | 40 | 0.527 | 0.832 | 3.499 |
| R-55 | P-53 | 90 | Q-1 | 10 | 1.3 | MSL-6 | 70 | 0.894 | 0.894 | 3.571 |
| R-56 | P-54 | 90 | Q-2 | 10 | 1.3 | MSL-5 | 55 | 0.749 | 1.497 | 3.423 |
| R-57 | P-55 | 90 | Q-1 | 10 | 1.3 | MSL-4 | 40 | 0.516 | 1.765 | 3.191 |
| R-58 | P-56 | 90 | Q-1 | 10 | 1.3 | MSL-6 | 50 | 0.546 | 2.030 | 3.123 |
| R-59 | P-57 | 90 | Q-2 | 10 | 1.3 | MSL-6 | 65 | 0.743 | 0.743 | 3.566 |
| R-60 | P-58 | 90 | Q-1 | 10 | 1.3 | MSL-1 | 60 | 0.766 | 1.599 | 3.316 |
| R-61 | P-59 | 90 | Q-1 | 10 | 1.3 | SL-3 | 50 | 0.639 | 2.669 | 3.307 |
| R-62 | P-60 | 90 | Q-2 | 10 | 1.3 | SL-3 | 60 | 0.653 | 1.306 | 3.683 |
| R-63 | P-61 | 90 | Q-1 | 10 | 1.3 | MSL-4 | 60 | 0.766 | 1.599 | 3.316 |
| R-64 | P-62 | 90 | Q-1 | 10 | 1.3 | MSL-3 | 40 | 0.596 | 0.832 | 3.568 |
| R-65 | P-63 | 90 | Q-1 | 10 | 1.3 | MSL-6 | 40 | 0.549 | 0.832 | 3.521 |
| R-66 | P-64 | 90 | Q-1 | 10 | 1.3 | MSL-6 | 40 | 0.620 | 0.832 | 3.592 |

TABLE 14

| | | | Acid diffusion | | | | | | | |
|---|---|---|---|---|---|---|---|---|---|---|
| | Resin | | control agent | | | | | | | |
| Resist | | Content | | Content | Solid-content concentration | | Cᵤₗ | C_{PAG} | C_{AC} | C_{DC} |
| composition | Type | (mass %) | Type | (mass %) | (mass %) | Solvent | (mass %) | (mmol/g) | (mmol/g) | (mmol/g) |
| R-67 | P-65 | 90 | Q-1 | 10 | 1.3 | MSL-5 | 40 | 0.449 | 0.832 | 3.421 |
| R-68 | P-66 | 90 | Q-1 | 10 | 1.3 | MSL-6 | 40 | 0.480 | 0.832 | 3.452 |
| R-69 | P-67 | 90 | Q-1 | 10 | 1.3 | MSL-1 | 40 | 0.455 | 0.832 | 3.427 |
| R-70 | P-68 | 90 | Q-5 | 10 | 1.3 | SL-3 | 40 | 0.507 | 0.832 | 3.479 |
| R-71 | P-69 | 90 | Q-6 | 10 | 1.3 | MSL-1 | 40 | 0.491 | 0.832 | 3.463 |
| R-72 | P-70 | 90 | Q-7 | 10 | 1.3 | MSL-3 | 40 | 0.506 | 0.832 | 3.478 |
| R-73 | P-71 | 90 | Q-8 | 10 | 1.3 | SL-3 | 40 | 0.460 | 0.832 | 3.432 |
| R-74 | P-72 | 90 | Q-9 | 10 | 1.3 | MSL-4 | 40 | 0.449 | 0.832 | 3.421 |
| R-75 | P-73 | 90 | Q-10 | 10 | 1.3 | MSL-4 | 40 | 0.456 | 0.832 | 3.428 |
| R-76 | P-74 | 90 | Q-11 | 10 | 1.3 | MSL-3 | 40 | 0.439 | 0.832 | 3.850 |
| R-77 | P-75 | 90 | Q-12 | 10 | 1.3 | MSL-2 | 40 | 0.486 | 0.832 | 3.458 |
| R-78 | P-76 | 100 | — | 0 | 1.3 | MSL-1 | 50 | 0.679 | 0.000 | 3.651 |
| R-79 | P-48 | 100 | — | 0 | 1.3 | MSL-5 | 40 | 0.527 | 0.000 | 4.093 |
| R-80 | P-48/P-52 | 45/45 | Q-1 | 10 | 1.3 | MSL-5 | 40 | 0.527 | 0.416 | 3.796 |
| R-81 | P-77 | 90 | Q-2 | 10 | 1.3 | MSL-4 | 37 | 0.563 | 1.352 | 3.087 |
| R-82 | P-78 | 90 | Q-2 | 10 | 1.3 | MSL-1 | 39 | 0.594 | 1.298 | 3.118 |
| R-83 | P-79 | 90 | Q-13 | 10 | 1.3 | MSL-1 | 50 | 0.819 | 0.000 | 2.972 |

### Pattern Formation by EUV Exposure

An underlayer film-forming composition AL412 (manufactured by Brewer Science, Inc.) was applied onto a silicon wafer having a diameter of 300 mm, and baked at 205° C. for 60 seconds to form an underlayer film having a film thickness of 20 nm. On the underlayer film, a resist composition described in Tables 15 and 16 below was applied, and subjected to post applied bake (Post Applied Bake; PAB) at 120° C. to form a resist film having a film thickness of 35 nm. Thus, the silicon wafer having the resist film was formed.

The silicon wafer having the resist film obtained by the above-described procedure was subjected to pattern irradiation using an EUV scanner NXE3400 (NA: 0.33) manufactured by ASML while changing the exposure dose. The reticle employed was a hexagonal-array contact hole mask (dark field mask) having a pitch of 36 nm and an opening portion size of 20 nm. When using the above mask, the exposure dose that resolved pillar CDs (Critical Dimensions) of 18 nm on average was defined as the sensitivity.

Subsequently, only when described, post exposure bake (Post Exposure Bake; PEB) was performed under conditions described in Tables 15 and 16 (PEB before flood exposure is also described as “PEB1”). Subsequently, the wafer was subjected to flood exposure (full surface exposure) using a UV exposure apparatus (light having wavelengths of 355 nm to 410 nm) at an exposure dose described in Tables 15 and 16, and, only when described, subjected to PEB under conditions described in Tables 15 and 16 (PEB after flood exposure is also described as “PEB2”). Subsequently, development was performed using a developer described in Tables 15 and 16 for 30 seconds, and, only when described, the wafer was rinsed by pouring a rinse liquid described in Tables 15 and 16 for 10 seconds while rotating the wafer at a rotational rate of 1000 rpm, and then the wafer was rotated at a rotational rate of 4000 rpm for 30 seconds; in this way, negative-type pillar patterns having a pitch of 36 nm were obtained.

### Evaluation (Sensitivity, LCDU, and Resolution)

The sensitivity, the LCDU, and the resolution were evaluated in the same manner as in Example 1 and the like described above. The results are described in Tables 15 and 16 below.

In Tables 15 and 16, the unit of “Sensitivity” is “mJ/cm²”, the unit of “LCDU” is “nm”, and the unit of “Resolution (FFL)” is “nm”.

TABLE 15

| | | Process conditions | | | | | Evaluation | | |
|---|---|---|---|---|---|---|---|---|---|
| | Resist | PEB1 | UV exposure | PEB2 | | Rinse | | | Resolution |
| | composition | (° C.) | dose (J/cm²) | (° C.) | Developer | liquid | Sensitivity | LCDU | (FFL) |
| Example 50 | R-50 | 70 | 1 | 100 | MD-1 | — | 70 | 3.6 | 2.4 |
| Example 51 | R-51 | 80 | 1 | 90 | MD-1 | — | 67 | 3.4 | 2.6 |
| Example 52 | R-52 | 70 | 1 | 110 | MD-1 | — | 65 | 3.3 | 2.7 |
| Example 53 | R-53 | 80 | 1 | 100 | MD-1 | — | 67 | 3.4 | 2.6 |
| Example 54 | R-54 | 80 | 1 | 110 | MD-1 | — | 71 | 3.6 | 2.4 |
| Example 55 | R-55 | — | 1 | 100 | MD-1 | — | 64 | 3.3 | 2.7 |
| Example 56 | R-56 | — | 1 | 90 | MD-1 | — | 66 | 3.4 | 2.6 |
| Example 57 | R-57 | 80 | 1 | 100 | MD-1 | — | 70 | 3.6 | 2.4 |
| Example 58 | R-58 | — | 1 | 110 | MD-1 | — | 67 | 3.5 | 2.5 |
| Example 59 | R-59 | 70 | 1 | 110 | MD-1 | — | 65 | 3.3 | 2.7 |
| Example 60 | R-60 | — | 1 | 100 | MD-1 | — | 66 | 3.4 | 2.6 |
| Example 61 | R-61 | 70 | 1 | 100 | MD-1 | — | 66 | 3.5 | 2.5 |
| Example 62 | R-62 | 70 | 1 | 90 | MD-1 | — | 65 | 3.4 | 2.6 |
| Example 63 | R-63 | 80 | 1 | 110 | MD-1 | — | 66 | 3.4 | 2.6 |
| Example 64 | R-64 | 70 | 1 | 90 | MD-1 | — | 71 | 3.6 | 2.4 |
| Example 65 | R-65 | — | 1 | 110 | MD-1 | — | 71 | 3.6 | 2.4 |
| Example 66 | R-66 | — | 1 | 90 | MD-1 | — | 71 | 3.6 | 2.4 |
| Example 67 | R-67 | 80 | 1 | 90 | MD-1 | — | 71 | 3.6 | 2.4 |
| Example 68 | R-68 | 80 | 1 | 90 | MD-1 | — | 71 | 3.6 | 2.4 |
| Example 69 | R-69 | 70 | 1 | 90 | MD-1 | — | 71 | 3.6 | 2.4 |
| Example 70 | R-70 | 70 | 1 | 90 | MD-1 | — | 71 | 3.6 | 2.4 |

TABLE 16

| | | Process conditions | | | | | Evaluation | | |
|---|---|---|---|---|---|---|---|---|---|
| | Resist | PEB1 | UV exposure | PEB2 | | Rinse | | | Resolution |
| | composition | (° C.) | dose (J/cm²) | (° C.) | Developer | liquid | Sensitivity | LCDU | (FFL) |
| Example 71 | R-71 | 80 | 1 | 110 | MD-1 | — | 71 | 3.6 | 2.4 |
| Example 72 | R-72 | — | 1 | 100 | MD-1 | — | 81 | 3.8 | 2.2 |
| Example 73 | R-73 | — | 1 | 110 | MD-1 | — | 81 | 3.8 | 2.2 |
| Example 74 | R-74 | — | 1 | 110 | MD-1 | — | 81 | 3.8 | 2.2 |
| Example 75 | R-75 | — | 1 | 110 | MD-1 | — | 81 | 3.8 | 2.2 |
| Example 76 | R-76 | 70 | 1 | 110 | MD-1 | — | 81 | 3.8 | 2.2 |
| Example 77 | R-77 | 80 | 1 | 90 | MD-1 | — | 81 | 3.8 | 2.2 |
| Example 78 | R-78 | 80 | 1 | 100 | MD-1 | — | 69 | 3.5 | 2.5 |
| Example 79 | R-79 | — | 1 | — | MD-1 | — | 80 | 3.8 | 2.2 |
| Example 80 | R-80 | 70 | 1 | 110 | MD-1 | — | 71 | 3.8 | 2.3 |
| Example 81 | R-50 | 70 | 0.5 | 100 | MD-1 | — | 77 | 3.8 | 2.3 |
| Example 82 | R-50 | 70 | 2 | 100 | MD-1 | — | 69 | 3.7 | 2.3 |
| Example 83 | R-50 | 70 | 3 | 100 | MD-1 | — | 67 | 3.8 | 2.2 |
| Example 84 | R-50 | 70 | 1 | 100 | MD-2 | — | 66 | 3.7 | 2.4 |
| Example 85 | R-50 | 70 | 1 | 100 | MD-3 | — | 63 | 3.7 | 2.2 |
| Example 86 | R-50 | 70 | 1 | 100 | D-3 | MD-1 | 73 | 3.7 | 2.3 |
| Example 87 | R-50 | 70 | 1 | 100 | D-3 | MD-2 | 73 | 3.7 | 2.3 |
| Example 88 | R-50 | 70 | 1 | 100 | D-3 | MD-3 | 73 | 3.7 | 2.2 |
| Comparative | R-81 | 80 | 1 | 90 | MD-1 | — | 92 | 4.1 | 1.9 |
| Example 4 | | | | | | | | | |
| Comparative | R-82 | 70 | 1 | 110 | MD-1 | — | 92 | 4.1 | 1.9 |
| Example 5 | | | | | | | | | |
| Comparative | R-83 | 70 | 1 | 90 | MD-1 | — | 98 | 4.0 | 1.5 |
| Example 6 | | | | | | | | | |

### Examples 89 to 129 and Comparative Examples 7 to 9

### Preparation of Resist Compositions

Resist compositions were prepared in the same manner as in Example 1 described above except that the resins and the acid diffusion control agents described in Tables 17 and 18 below were mixed in the solvents described in Tables 17 and 18 so as to satisfy the solid-content concentrations described in Tables 17 and 18.

TABLE 17

| | | | Acid diffusion | | | | | | | |
|---|---|---|---|---|---|---|---|---|---|---|
| | Resin | | control agent | | Solid-content | | | | | |
| Resist | | Content | | Content | concentration | | Cᵤₗ | C_{PAG} | C_{AC} | C_{DC} |
| composition | Type | (mass %) | Type | (mass %) | (mass %) | Solvent | (mass %) | (mmol/g) | (mmol/g) | (mmol/g) |
| R-84 | P-48 | 90 | Q-1 | 10 | 2.5 | MSL-4 | 40 | 0.527 | 0.000 | 4.093 |
| R-85 | P-49 | 90 | Q-1 | 10 | 2.5 | MSL-4 | 55 | 0.710 | 0.710 | 3.385 |
| R-86 | P-50 | 90 | Q-1 | 10 | 2.5 | MSL-1 | 70 | 0.765 | 0.000 | 3.313 |
| R-87 | P-51 | 90 | Q-2 | 10 | 2.5 | SL-3 | 55 | 0.765 | 0.765 | 3.440 |
| R-88 | P-52 | 90 | Q-1 | 10 | 2.5 | SL-3 | 40 | 0.527 | 0.832 | 3.499 |
| R-89 | P-53 | 90 | Q-1 | 10 | 2.5 | MSL-6 | 70 | 0.894 | 0.894 | 3.571 |
| R-90 | P-54 | 90 | Q-2 | 10 | 2.5 | MSL-5 | 55 | 0.749 | 1.497 | 3.423 |
| R-91 | P-55 | 90 | Q-1 | 10 | 2.5 | MSL-4 | 40 | 0.516 | 1.765 | 3.191 |
| R-92 | P-56 | 90 | Q-1 | 10 | 2.5 | MSL-6 | 50 | 0.546 | 2.030 | 3.123 |
| R-93 | P-57 | 90 | Q-2 | 10 | 2.5 | MSL-6 | 65 | 0.743 | 0.743 | 3.566 |
| R-94 | P-58 | 90 | Q-1 | 10 | 2.5 | MSL-1 | 60 | 0.766 | 1.599 | 3.316 |
| R-95 | P-59 | 90 | Q-1 | 10 | 2.5 | SL-3 | 50 | 0.639 | 2.669 | 3.307 |
| R-96 | P-60 | 90 | Q-2 | 10 | 2.5 | SL-3 | 60 | 0.653 | 1.306 | 3.683 |
| R-97 | P-61 | 90 | Q-1 | 10 | 2.5 | MSL-4 | 60 | 0.766 | 1.599 | 3.316 |
| R-98 | P-62 | 90 | Q-1 | 10 | 2.5 | MSL-3 | 40 | 0.596 | 0.832 | 3.568 |
| R-99 | P-63 | 90 | Q-1 | 10 | 2.5 | MSL-6 | 40 | 0.549 | 0.832 | 3.521 |
| R-100 | P-64 | 90 | Q-1 | 10 | 2.5 | MSL-6 | 40 | 0.620 | 0.832 | 3.592 |

TABLE 18

| | | | Acid diffusion | | | | | | | |
|---|---|---|---|---|---|---|---|---|---|---|
| | Resin | | control agent | | Solid-content | | | | | |
| Resist | | Content | | Content | concentration | | Cᵤₗ | C_{PAG} | C_{AC} | C_{DC} |
| composition | Type | (mass %) | Type | (mass %) | (mass %) | Solvent | (mass %) | (mmol/g) | (mmol/g) | (mmol/g) |
| R-101 | P-65 | 90 | Q-1 | 10 | 2.5 | MSL-5 | 40 | 0.449 | 0.832 | 3.421 |
| R-102 | P-66 | 90 | Q-1 | 10 | 2.5 | MSL-6 | 40 | 0.480 | 0.832 | 3.452 |
| R-103 | P-67 | 90 | Q-1 | 10 | 2.5 | MSL-1 | 40 | 0.455 | 0.832 | 3.427 |
| R-104 | P-68 | 90 | Q-5 | 10 | 2.5 | SL-3 | 40 | 0.507 | 0.832 | 3.479 |
| R-105 | P-69 | 90 | Q-6 | 10 | 2.5 | MSL-1 | 40 | 0.491 | 0.832 | 3.463 |
| R-106 | P-70 | 90 | Q-7 | 10 | 2.5 | MSL-3 | 40 | 0.506 | 0.832 | 3.478 |
| R-107 | P-71 | 90 | Q-8 | 10 | 2.5 | SL-3 | 40 | 0.460 | 0.832 | 3.432 |
| R-108 | P-72 | 90 | Q-9 | 10 | 2.5 | MSL-4 | 40 | 0.449 | 0.832 | 3.421 |
| R-109 | P-73 | 90 | Q-10 | 10 | 2.5 | MSL-4 | 40 | 0.456 | 0.832 | 3.428 |
| R-110 | P-74 | 90 | Q-11 | 10 | 2.5 | MSL-3 | 40 | 0.439 | 0.832 | 3.850 |
| R-111 | P-75 | 90 | Q-12 | 10 | 2.5 | MSL-2 | 40 | 0.486 | 0.832 | 3.458 |
| R-112 | P-76 | 100 | — | 0 | 2.5 | MSL-1 | 50 | 0.679 | 0.000 | 3.651 |
| R-113 | P-48 | 100 | — | 0 | 2.5 | MSL-5 | 40 | 0.527 | 0.000 | 4.093 |
| R-114 | P-48/P-52 | 45/45 | Q-1 | 10 | 2.5 | MSL-5 | 40 | 0.527 | 0.416 | 3.796 |
| R-115 | P-77 | 90 | Q-2 | 10 | 2.5 | MSL-4 | 37 | 0.563 | 1.352 | 3.087 |
| R-116 | P-78 | 90 | Q-2 | 10 | 2.5 | MSL-1 | 39 | 0.594 | 1.298 | 3.118 |
| R-117 | P-79 | 90 | Q-13 | 10 | 2.5 | MSL-1 | 50 | 0.819 | 0.000 | 2.972 |

### Pattern Formation by EUV Exposure

The underlayer film-forming composition AL412 (manufactured by Brewer Science, Inc.) was applied onto a silicon wafer having a diameter of 300 mm, and baked at 205° C. for 60 seconds to form an underlayer film having a film thickness of 20 nm. On the underlayer film, a resist composition described in Tables 19 and 20 below was applied, and subjected to post applied bake (Post Applied Bake; PAB) at 120° C. to form a resist film having a film thickness of 70 nm. Thus, the silicon wafer having the resist film was formed.

The silicon wafer having the resist film obtained by the above-described procedure was subjected to pattern irradiation using an EUV scanner NXE3400 (NA: 0.33) manufactured by ASML while changing the exposure dose. The reticle employed was a hexagonal-array contact hole mask (bright field mask) having a pitch of 36 nm and an opening portion size of 20 nm. When using the above mask, the exposure dose that resolved hole CDs (Critical Dimensions) of 18 nm on average was defined as the sensitivity.

Subsequently, only when described, post exposure bake (Post Exposure Bake; PEB) was performed under the conditions described in Tables 19 and 20 (PEB before flood exposure is also described as “PEB1”). Subsequently, the wafer was subjected to flood exposure (full surface exposure) using a UV exposure apparatus (light having wavelengths of 355 nm to 410 nm) at an exposure dose described in Tables 19 and 20, and, only when described, subjected to PEB under conditions described in Tables 19 and 20 (PEB after flood exposure is also described as “PEB2”). Subsequently, development was performed using a developer described in Tables 19 and 20 for 30 seconds, and only when described, the wafer was rinsed by pouring a rinse liquid described in Tables 19 and 20 for 10 seconds while rotating the wafer at a rotational rate of 1000 rpm; and then the wafer was rotated at a rotational rate of 4000 rpm for 30 seconds; in this way, negative-type contact hole patterns having a pitch of 36 nm were obtained.

### Evaluation (Sensitivity, LCDU, and Resolution)

The LCDU and the FFL were evaluated in the same manner as in Example 1 and the like described above. The results are described in Tables 19 and 20 below.

In Tables 19 and 20, the unit of “Sensitivity” is “mJ/cm²”, the unit of “LCDU” is “nm”, and the unit of “Resolution (FFL)” is “nm”.

TABLE 19

| | | Process conditions | | | | | Evaluation | | |
|---|---|---|---|---|---|---|---|---|---|
| | Resist | PEB1 | UV exposure | PEB2 | | Rinse | | | Resolution |
| | composition | (° C.) | dose (J/cm²) | (C) | Developer | liquid | Sensitivity | LCDU | (FFL) |
| Example 89 | R-84 | 70 | 1 | 100 | MD-1 | — | 30 | 4.1 | 1.9 |
| Example 90 | R-85 | 80 | 1 | 90 | MD-1 | — | 27 | 3.9 | 2.1 |
| Example 91 | R-86 | 70 | 1 | 110 | MD-1 | — | 25 | 3.8 | 2.2 |
| Example 92 | R-87 | 80 | 1 | 100 | MD-1 | — | 27 | 3.9 | 2.1 |
| Example 93 | R-88 | 80 | 1 | 110 | MD-1 | — | 31 | 4.1 | 1.9 |
| Example 94 | R-89 | — | 1 | 100 | MD-1 | — | 24 | 3.8 | 2.2 |
| Example 95 | R-90 | — | 1 | 90 | MD-1 | — | 26 | 3.9 | 2.1 |
| Example 96 | R-91 | 80 | 1 | 100 | MD-1 | — | 30 | 4.1 | 1.9 |
| Example 97 | R-92 | — | 1 | 110 | MD-1 | — | 27 | 4.0 | 2.0 |
| Example 98 | R-93 | 70 | 1 | 110 | MD-1 | — | 25 | 3.8 | 2.2 |
| Example 99 | R-94 | — | 1 | 100 | MD-1 | — | 26 | 3.9 | 2.1 |
| Example 100 | R-95 | 70 | 1 | 100 | MD-1 | — | 26 | 4.0 | 2.0 |
| Example 101 | R-96 | 70 | 1 | 90 | MD-1 | — | 25 | 3.9 | 2.1 |
| Example 102 | R-97 | 80 | 1 | 110 | MD-1 | — | 26 | 3.9 | 2.1 |
| Example 103 | R-98 | 70 | 1 | 90 | MD-1 | — | 31 | 4.1 | 1.9 |
| Example 104 | R-99 | — | 1 | 110 | MD-1 | — | 31 | 4.1 | 1.9 |
| Example 105 | R-100 | — | 1 | 90 | MD-1 | — | 31 | 4.1 | 1.9 |
| Example 106 | R-101 | 80 | 1 | 90 | MD-1 | — | 31 | 4.1 | 1.9 |
| Example 107 | R-102 | 80 | 1 | 90 | MD-1 | — | 31 | 4.1 | 1.9 |
| Example 108 | R-103 | 70 | 1 | 90 | MD-1 | — | 31 | 4.1 | 1.9 |
| Example 109 | R-104 | 70 | 1 | 90 | MD-1 | — | 31 | 4.1 | 1.9 |

TABLE 20

| | | Process conditions | | | | | Evaluation | | |
|---|---|---|---|---|---|---|---|---|---|
| | Resist | PEB1 | UV exposure | PEB2 | | Rinse | | | Resolution |
| | composition | (° C.) | dose (J/cm²) | (C) | Developer | liquid | Sensitivity | LCDU | (FFL) |
| Example 110 | R-105 | 80 | 1 | 110 | MD-1 | — | 31 | 4.1 | 1.9 |
| Example 111 | R-106 | — | 1 | 100 | MD-1 | — | 41 | 4.3 | 1.7 |
| Example 112 | R-107 | — | 1 | 110 | MD-1 | — | 41 | 4.3 | 1.7 |
| Example 113 | R-108 | — | 1 | 110 | MD-1 | — | 41 | 4.3 | 1.7 |
| Example 114 | R-109 | — | 1 | 110 | MD-1 | — | 41 | 4.3 | 1.7 |
| Example 115 | R-110 | 70 | 1 | 110 | MD-1 | — | 41 | 4.3 | 1.7 |
| Example 116 | R-111 | 80 | 1 | 90 | MD-1 | — | 41 | 4.3 | 1.7 |
| Example 117 | R-112 | 80 | 1 | 100 | MD-1 | — | 29 | 4.0 | 2.0 |
| Example 118 | R-113 | — | 1 | — | MD-1 | — | 34 | 4.3 | 1.7 |
| Example 119 | R-114 | 70 | 1 | 110 | MD-1 | — | 31 | 4.3 | 1.8 |
| Example 120 | R-84 | 70 | 0.5 | 100 | MD-1 | — | 33 | 4.3 | 1.8 |
| Example 121 | R-84 | 70 | 2 | 100 | MD-1 | — | 29 | 4.2 | 1.8 |
| Example 122 | R-84 | 70 | 3 | 100 | MD-1 | — | 29 | 4.3 | 1.7 |
| Example 123 | R-84 | 70 | 1 | 100 | D-3 | — | 31 | 4.2 | 1.9 |
| Example 124 | R-84 | 70 | 1 | 100 | MD-2 | — | 28 | 4.2 | 1.9 |
| Example 125 | R-84 | 70 | 1 | 100 | D-5 | — | 31 | 4.2 | 1.9 |
| Example 126 | R-84 | 70 | 1 | 100 | MD-3 | — | 27 | 4.2 | 1.7 |
| Example 127 | R-84 | 70 | 1 | 100 | D-3 | MD-1 | 31 | 4.2 | 1.8 |
| Example 128 | R-84 | 70 | 1 | 100 | D-3 | MD-2 | 31 | 4.2 | 1.8 |
| Example 129 | R-84 | 70 | 1 | 100 | D-3 | MD-3 | 31 | 4.2 | 1.7 |
| Comparative | R-115 | 80 | 1 | 90 | MD-1 | — | 52 | 4.6 | 1.4 |
| Example 7 | | | | | | | | | |
| Comparative | R-116 | 70 | 1 | 110 | MD-1 | — | 52 | 4.6 | 1.4 |
| Example 8 | | | | | | | | | |
| Comparative | R-117 | 70 | 1 | 90 | MD-1 | — | 58 | 4.5 | 1.0 |
| Example 9 | | | | | | | | | |

The above-described results have demonstrated that the resist compositions used in Examples provide high sensitivity, high LCDU, and high resolution.

The present invention can provide an actinic ray-sensitive or radiation-sensitive resin composition that provides high sensitivity, high LCDU, and high resolution.

The present invention can also provide a resist film, a pattern forming method, and a method for producing an electronic device that use the above-described actinic ray-sensitive or radiation-sensitive resin composition.

The present invention has been described in detail and with reference to specific embodiments thereof; however, it would be apparent to those skilled in the art that various changes and modifications can be made therein without departing from the spirit and scope of the present invention.

This application is based on a Japanese patent application (JP2023-170175) filed on Sep. 29, 2023, the contents of which are incorporated herein by reference.

What is claimed is:

1. An actinic ray-sensitive or radiation-sensitive resin composition comprising a resin (X) having a repeating unit (u1), and a solvent,
wherein the repeating unit (u1) includes at least one cation selected from the group consisting of a cation represented by the following formula (CT-1) and a cation represented by the following formula (CT-2), and an anion bonded to a molecular chain of the resin (X),
a content of the repeating unit (u1) relative to a total content of resins contained in the actinic ray-sensitive or radiation-sensitive resin composition is 40 mass % or more, 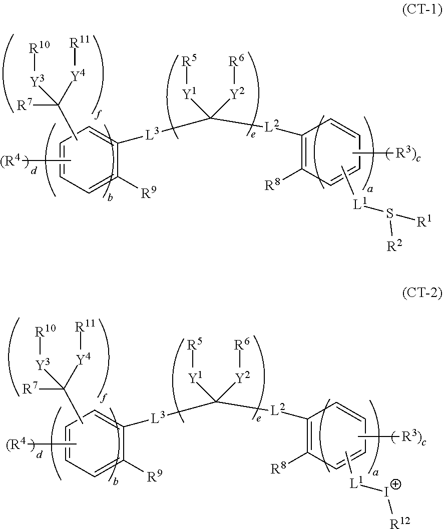
wherein, in the formula (CT-1) and the formula (CT-2),
R³ and R⁴ each independently represent an organic group, a hydroxy group, a mercapto group, an amino group, a nitro group, a phosphino group, a silyl group, or a halogen atom; when a plurality of R³ are present, the plurality of R³ may be bonded together, directly by a single bond or via a linking group, to form a ring; when a plurality of R⁴ are present, the plurality of R⁴ may be bonded together, directly by a single bond or via a linking group, to form a ring,
R⁵ and R⁶ each independently represent an alkyl group, a cycloalkyl group, an alkenyl group, a cycloalkenyl group, an aryl group, or a heteroaryl group; when R⁵ and R⁶ include a methylene group, at least one of the methylene groups may be substituted with a divalent heteroatom-containing group; R⁵ and R⁶ may be bonded together, directly by a single bond or via any one selected from the group consisting of an oxygen atom, a sulfur atom, and an alkylene group, to form a ring,
R⁷ represents a hydrogen atom, an alkyl group, a cycloalkyl group, an alkenyl group, a cycloalkenyl group, an aryl group, or a heteroaryl group,
R⁸ and R⁹ each independently represent a hydrogen atom, an organic group, a hydroxy group, a mercapto group, an amino group, a nitro group, a phosphino group, a silyl group, or a halogen atom, or R⁸ and R⁹ are bonded together to represent a single bond or a divalent linking group,
R¹⁰ and R¹¹ each independently represent an alkyl group, a cycloalkyl group, an alkenyl group, a cycloalkenyl group, an aryl group, or a heteroaryl group; when R¹⁰ and R¹¹ include a methylene group, at least one of the methylene groups may be substituted with a divalent heteroatom-containing group; R¹⁰ and R¹¹ may be bonded together, directly by a single bond or via any one selected from the group consisting of an oxygen atom, a sulfur atom, and an alkylene group, to form a ring,
Y¹, Y², Y³, and Y⁴ each independently represent an oxygen atom or a sulfur atom,
L¹ represents an alkylene group, a cycloalkylene group, an alkenylene group, a cycloalkenylene group, an arylene group, a heteroarylene group, a linking group in which at least two groups selected from the group consisting of an alkylene group, a cycloalkylene group, an alkenylene group, a cycloalkenylene group, an arylene group, and a heteroarylene group are bonded together via at least one selected from the group consisting of a single bond, an oxygen atom, a sulfur atom, and a nitrogen atom-containing group, or a single bond,
L² and L³ each independently represent a single bond, an alkenylene group having 2 carbon atoms, an alkynylene group having 2 carbon atoms, a carbonyl group, a sulfinyl group, or a sulfonyl group,
a and b each independently represent an integer of 1 to 3,
when a represents 1, c represents an integer of 0 to 3,
when a represents 2, c represents an integer of 0 to 5,
when a represents 3, c represents an integer of 0 to 7,
when b represents 1, d represents an integer of 0 to 4, provided that d+f is an integer of 0 to 4,
when b represents 2, d represents an integer of 0 to 6, provided that d+f is an integer of 0 to 6,
when b represents 3, d represents an integer of 0 to 8, provided that d+f is an integer of 0 to 8,
e represents 0 or 1, f represents an integer of 0 to 4, provided that e+f is an integer of 1 to 4,
in the formula (CT-1),
R¹ and R² each independently represent an alkyl group, a cycloalkyl group, an alkenyl group, a cycloalkenyl group, an aryl group, or a heteroaryl group; when R¹ and R² include a methylene group, at least one of the methylene groups may be substituted with a divalent heteroatom-containing group,
at least two of R¹, R², and the aromatic ring to which L¹ is bonded may be bonded together, directly by a single bond or via any one selected from the group consisting of an oxygen atom, a sulfur atom, a nitrogen atom-containing group, and a methylene group, to form a ring,
in the formula (CT-2),
R¹² represents an aryl group or a heteroaryl group, and
R¹² and the aromatic ring to which L¹ is bonded may be bonded together, directly by a single bond or via any one selected from the group consisting of an oxygen atom, a sulfur atom, a nitrogen atom-containing group, and a methylene group, to form a ring.

2. An actinic ray-sensitive or radiation-sensitive resin composition comprising a resin (X) having a repeating unit (u1), and a solvent,
wherein the repeating unit (u1) includes at least one cation and an anion that is bonded to a molecular chain of the resin (X),
the cation undergoes a structural change by action of an acid, and a structure of the cation after the structural change has a larger peak area in an absorption spectrum for light having wavelengths of 300 nm to 450 nm than a peak area in an absorption spectrum of the structure of the cation before the structural change for light having wavelengths of 300 nm to 450 nm, and
a content of the repeating unit (u1) relative to a total content of resins contained in the actinic ray-sensitive or radiation-sensitive resin composition is 40 mass % or more.

3. An actinic ray-sensitive or radiation-sensitive resin composition comprising a resin (X) having a repeating unit (u1), and a solvent,
wherein the repeating unit (u1) includes at least one cation and an anion that is bonded to a molecular chain of the resin (X),
the cation undergoes a structural change by action of an acid to generate a ketone group, and
a content of the repeating unit (u1) relative to a total content of resins contained in the actinic ray-sensitive or radiation-sensitive resin composition is 40 mass % or more.

4. The actinic ray-sensitive or radiation-sensitive resin composition according to claim 1, wherein the repeating unit (u1) is a repeating unit that generates an acid upon irradiation with an actinic ray or a radiation.

5. The actinic ray-sensitive or radiation-sensitive resin composition according to claim 1, satisfying at least one of the following condition (i) or the following condition (ii):
Condition (i): the actinic ray-sensitive or radiation-sensitive resin composition contains an acid diffusion control agent that is a compound different from the resin (X), and
Condition (ii): the resin (X) has a repeating unit having acid diffusion control ability.

6. The actinic ray-sensitive or radiation-sensitive resin composition according to claim 1, wherein the content of the repeating unit (u1) relative to the total content of resins contained in the actinic ray-sensitive or radiation-sensitive resin composition is 60 mass % or more.

7. The actinic ray-sensitive or radiation-sensitive resin composition according to claim 1, wherein the content of the repeating unit (u1) relative to the total content of resins contained in the actinic ray-sensitive or radiation-sensitive resin composition is 80 mass % or more.

8. A resist film formed with the actinic ray-sensitive or radiation-sensitive resin composition according to claim 1.

9. A pattern forming method comprising: forming, on a substrate, a resist film with the actinic ray-sensitive or radiation-sensitive resin composition according to claim 1; irradiating the resist film with a first actinic ray or radiation; irradiating, with a second actinic ray or radiation, the resist film after the irradiating with the first actinic ray or radiation; and developing, with a developer, the resist film after the irradiating with the second actinic ray or radiation.

10. The pattern forming method according to claim 9, wherein a wavelength of the first actinic ray or radiation is shorter than a wavelength of the second actinic ray or radiation.

11. The pattern forming method according to claim 10, wherein the first actinic ray or radiation is an electron beam or extreme ultraviolet rays.

12. The pattern forming method according to claim 9, wherein the irradiating with the first actinic ray or radiation generates a first active species in the resist film, the first active species causes a structural change of the cation, and the irradiating with the second actinic ray or radiation generates a second active species from the cation having undergone the structural change.

13. The pattern forming method according to claim 9, wherein the developer is an alkaline aqueous solution.

14. The pattern forming method according to claim 9, wherein the developer is an organic solvent.

15. A method for producing an electronic device, the method comprising the pattern forming method according to claim 9.
